(19) United States
(12) Patent Application Publication
(10) Pub. No.: US 2015/0014666 A1
(43) Pub. Date: Jan. 15, 2015

(54) AROMATIC AMINE DERIVATIVE AND ORGANIC ELECTROLUMINESCENT ELEMENT USING SAME

(71) Applicant: IDEMITSU KOSAN CO., LTD, Tokyo (JP)

(72) Inventors: Yumiko Mizuki, Sodegaura-shi (JP); Hirokatsu Ito, Sodegaura-shi (JP)

(73) Assignee: IDEMITSU KOSAN CO., LTD., Tokyo (JP)

(21) Appl. No.: 14/344,993

(22) PCT Filed: Sep. 21, 2012
(86) PCT No.: PCT/JP2012/074232

§ 371 Date: Mar. 14, 2014

(30) Foreign Application Priority Data
Sep. 22, 2011 (JP) 2011-208004

(51) Int. Cl. H01L 51/00

(52) U.S. Cl. CPC H01L 51/0054; H01L 51/006; H01L 51/0061; H01L 51/0073; H01L 51/0072; H01L 51/0067; H01L 51/0094; H01L 51/0074; H01L 51/0058; H01L 51/0071; H01L 51/5056
USPC 257/40; 549/460; 546/160; 546/284.1; 549/214; 544/331; 549/43; 549/456; 549/41; 549/31; 548/418

(57) ABSTRACT

An aromatic amine derivative is represented by a formula (1) below. In the formula (1), R₂, R₃, R₄, R₅, R₇, R₈, R₉ and R₁₀ each independently represent a hydrogen atom and a substituent. In the formula (1), R₁ and R₆ are represented by a formula (2) below, and L₁ to L₂ are each independently a single bond, a divalent residue of an aryl group, and the like. L₃ is a divalent residue of an aryl group and the like. In the formula (2); Ar₁ is a monovalent substituent having a partial structure represented by the following formula (3); X represents an oxygen atom or a sulfur atom; and A and B represent a six-membered ring. In the formula (2), Ar₂ is an aryl group, a monovalent substituent having a partial structure represented by the formula (3), and the like.

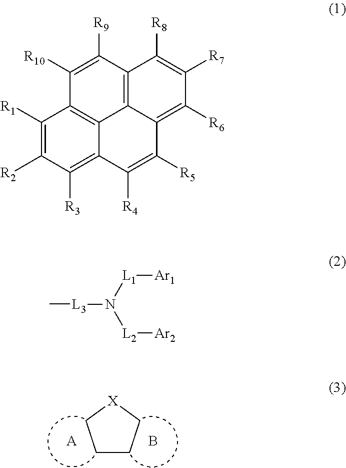

### TECHNICAL FIELD

The present invention relates to an aromatic amine derivative and an organic electroluminescence device using the aromatic amine derivative.

### BACKGROUND ART

An organic electroluminescence device (hereinafter, occasionally abbreviated as an organic EL device) using an organic substance is a promising component of a solid-emitting-type full-color display device of a low cost and a large area. Accordingly, various developments of the organic EL device have been made. Typically, an organic EL device is provided with an emitting layer and a pair of opposing electrodes between which the emitting layer is interposed. When an electrical field is applied to the opposing electrodes, electrons are injected from a cathode and holes are injected from an anode. Further, the injected electrons are recombined with the holes in the emitting layer to form an excited state. Energy generated when the excited state are returned to a ground state is irradiated as light.

A typical organic EL device exhibits a higher drive voltage and lower luminescence intensity and lower luminous efficiency than those of an inorganic light-emitting diode. Moreover, since properties of the organic EL device are considerably deteriorated, the organic EL device is not in practical use. Although the organic EL device has been gradually improved in recent years, further higher luminous efficiency, longer lifetime, improvement in color reproduction and the like have been demanded.

Performance of the organic EL device has been gradually enhanced by improving an organic-EL luminescent material. Particularly, improvement in color purity of a blue-emitting organic EL device (i.e., shifting emission wavelength into short wavelength) is an important technique leading to improvement in color reproduction of a display. Patent Literature 1 discloses a luminescent material having dibenzofuran as an example of a material used in an emitting layer. Although blue emission (i.e., emission in short wavelength) is obtained, further improvement has been demanded in view of a low luminous efficiency.

Patent literatures 4 and 5 disclose a diaminopyrene derivative. Patent Literature 2 discloses a combination of an anthracene host and arylamine. Patent Literatures 3 to 5 disclose a combination of an anthracene host having a specific structure and a diaminopyrene dopant. Patent Literatures 6 to 8 disclose an anthracene host material.

Improvement in luminescence property is recognized in any materials and any combinations, but is not sufficient. A luminescent material exhibiting a high luminous efficiency and realizing short-wavelength emission has been demanded.

Patent Literature 9 discloses that an aromatic amine derivative including an arylene group at the center and a dibenzofuran ring bonded to a nitrogen atom is used as a hole transporting material. Patent Literature 10 discloses a use of an aromatic amine derivative as a hole transporting material, in which a dibenzofuran ring, dibenzothiophene ring, benzofuran ring, benzothiophene ring or the like is bonded to a nitrogen atom through an arylene group. However, Patent Literature 10 does not disclose a use of the aromatic amine derivative as a luminescent material.

Patent Literatures 11 to 13 disclose an aromatic amine derivative in which amino groups are respectively bonded to positions 1 and 6 of pyrene. In the aromatic amine derivatives of Patent Literatures 11 and 12, a dibenzofuran ring or a dibenzothiophene ring is bonded to a nitrogen atom of the amino group. Although these aromatic amine derivatives are used as a blue-emitting luminescent material, color purity and luminous efficiency needs to be further improved for practical use.

### CITATION LIST

### Patent Literature(s)

Patent Literature 1: WO2006/128800
Patent Literature 2: WO2004/018588
Patent Literature 3: WO2004/018587
Patent Literature 4: JP-A-2004-204238
Patent Literature 5: WO2005/108348
Patent Literature 6: WO2005/054162
Patent Literature 7: WO2005/061656
Patent Literature 8: WO2002/038524
Patent Literature 9: JP-A-11-35532
Patent Literature 10: WO2007/125714
Patent Literature 11: International Publication No. WO2010/122810
Patent Literature 12: International Publication No. WO2009/084512
Patent Literature 13: Korean Patent Publication No. 10-2011-0076376

### SUMMARY OF THE INVENTION

### Problems to be Solved by the Invention

An object of the invention is to provide an organic EL device capable of providing blue emission and an aromatic amine derivative effectively usable in an organic thin-film layer of the organic EL device.

### Means for Solving the Problems

According to the invention, an aromatic amine derivative and an organic EL device described below are provided.

[1] An aromatic amine derivative according to an aspect of the invention is represented by a formula (1).

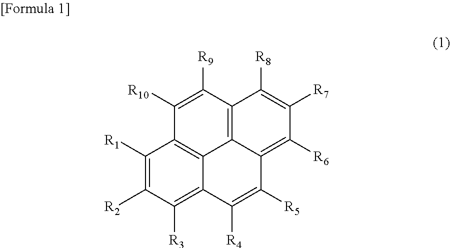

In the formula (1), R₂, R₃, R₄, R₅, R₇, R₈, R₉ and R₁₀ each independently represent a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

However, in the formula (1), R₁ and R₆ are represented by a formula (2) below.

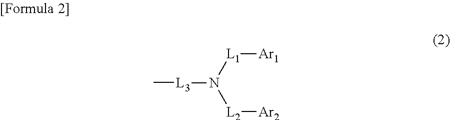

In the formula (2), L₁ and L₂ each independently represent a single bond, a divalent residue of a substituted or unsubstituted aryl group having 6 to 30 ring carbon atoms, or a divalent residue of a substituted or unsubstituted heterocyclic group having 5 to 30 ring atoms.

In the formula (2), L₃ represents a divalent residue of a substituted or unsubstituted aryl group having 6 to 30 ring carbon atoms, or a divalent residue of a substituted or unsubstituted heterocyclic group having 5 to 30 ring atoms.

In the formula (2), Ar₁ is a monovalent substituent having a partial structure represented by a formula (3) below.

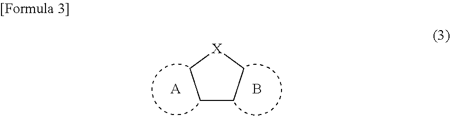

In the formula (3), X represents an oxygen atom or a sulfur atom. In the formula (3), A and B represent a six-membered ring. The six-membered ring represented by A and B may be fused with another ring.

In the formula (2), Ar² represents a substituted or unsubstituted aryl group having 6 to 30 ring carbon atoms, a substituted or unsubstituted heterocyclic group having 5 to 30 ring atoms, or a monovalent substituent having a partial structure represented by the formula (3).

[2] In the aromatic amine derivative according to the above aspect of the invention, the monovalent substituent having the partial structure represented by the formula (3) is a monovalent residue represented by a formula (4) below.

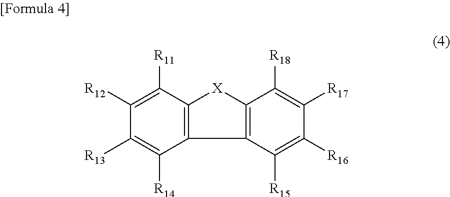

In the formula (4), X represents an oxygen atom or a sulfur atom.

In the formula (4), R₁₁ to R₁₈ each independently represent a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms. However, when Ar₁ is a monovalent residue of the formula (4), one of R₁₁ to R₁₈ is a single bond to be bonded to L₁; and when Ar₂ is a monovalent residue of the formula (4), one of R₁₁ to R₁₈ is a single bond to be bonded to L₂.

In the formula (4), at least one combination of R₁₁ and R₁₂, R₁₂ and R₁₃, R₁₃ and R₁₄, R₁₅ and R₁₆, R₁₆ and R₁₇, and R₁₇ and R₁₈ may form a saturated or unsaturated ring.

[3] In the aromatic amine derivative according to the above aspect of the invention, the monovalent substituent having the partial structure represented by the formula (3) is any one of monovalent residues represented by formulae (5) to (10) below.

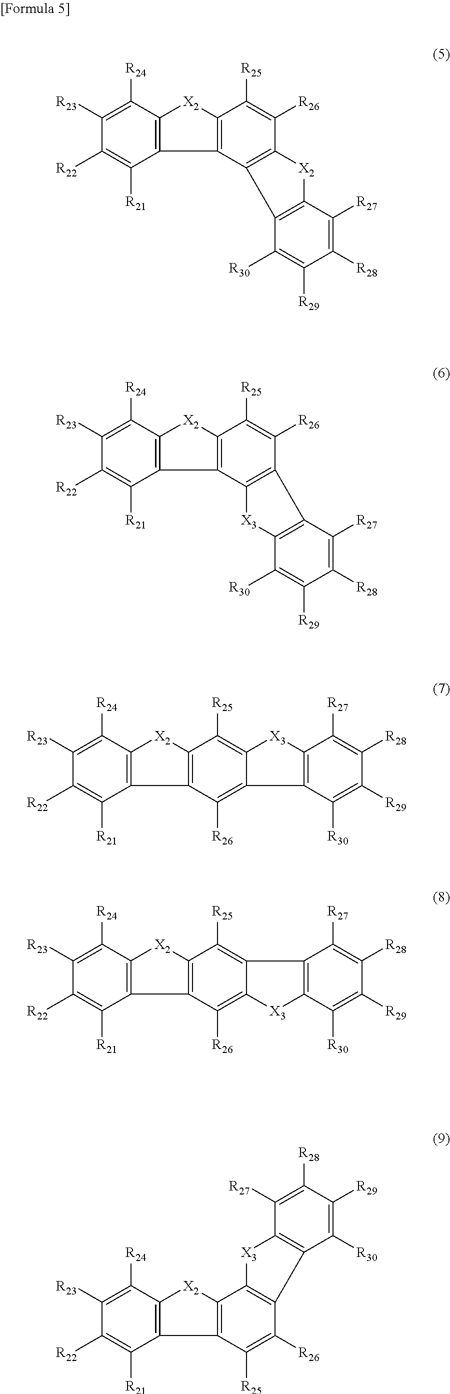

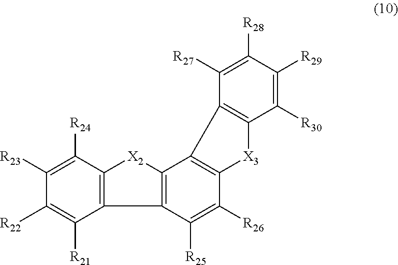

In the formulae (5) to (10), X₂ represents an oxygen atom or a sulfur atom.

In the formulae (5) to (10), X₃ represents an oxygen atom, a sulfur atom, NR₃₁ or CR₃₂R₃₃.

In the formulae (5) to (10), R₂₁ to R₃₀ each independently represent a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms,

a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms. However, in the formula (2), when Ar₁ is one of the monovalent residues of the formulae (5) to (10), one of R₂₁ to R₃₀ is a single bond to be bonded to L₁; and when Ar₂ is one of the monovalent residues of the formulae (5) to (10), one of R₂₁ to R₃₀ is a single bond to be bonded to L₂.

In the formulae (5) to (10), R₃₁, R₃₂ and R₃₃ each independently represent a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms.

In the formulae (5) to (10), at least one combination of R₂₁ and R₂₂, R₂₂ and R₂₃, R₂₃ and R₂₄, R₂₅ and R₂₆, R₂₇ and R₂₈, R₂₈ and R₂₉, and R₂₉ and R₃₀ may form a saturated or unsaturated ring. However, in the formulae (7) and (8), R₂₅ and R₂₆ do not form a ring.

[4] An organic electroluminescence device according to another aspect of the invention includes: a cathode; an anode; and an organic compound layer between the cathode and the anode, in which the organic compound layer includes the aromatic amine derivative according to the above aspect of the invention.

[5] In the organic electroluminescence device according to the above aspect of the invention, the organic compound layer includes a plurality of organic thin-film layers including an emitting layer, and at least one of the plurality of organic thin-film layers includes the aromatic amine derivative according to the above aspect of the invention.

[6] In the organic electroluminescence device according to the above aspect of the invention, at least one of the plurality of organic thin-film layers includes the aromatic amine derivative according to the above aspect of the invention and an anthracene derivative represented by a formula (20) below.

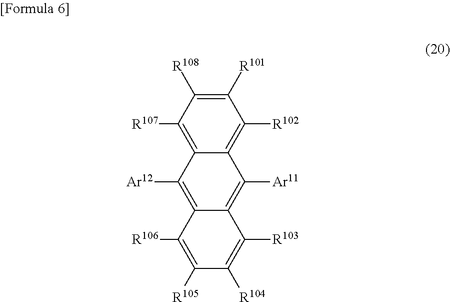

In the formula (20), Ar¹¹ and Ar¹² each independently represent a substituted or unsubstituted monocyclic group having 5 to 30 ring atoms, a substituted or unsubstituted fused ring group having 10 to 30 ring atoms, or a group provided by combining the monocyclic group and the fused ring group.

In the formula (20), R¹⁰¹ to R¹⁰⁸ each independently represent a hydrogen atom, a halogen atom, a cyano group, a substituted or unsubstituted monocyclic group having 5 to 30 ring atoms, a substituted or unsubstituted fused ring group having 10 to 30 ring atoms, a group provided by combining the monocyclic group and the fused ring group, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aralkyl group having 7 to 30 carbon atoms, a substituted or unsubstituted aryloxy group having 6 to 30 ring carbon atoms, or a substituted or unsubstituted silyl group.

[7] In the organic electroluminescence device according to the above aspect of the invention, Ar¹¹ and Ar¹² in the formula (20) are each independently a substituted or unsubstituted fused ring group having 10 to 30 ring atoms.

[8] In the organic electroluminescence device according to the above aspect of the invention, in the formula (20), one of Ar¹¹ and Ar¹² is a substituted or unsubstituted monocyclic group having 5 to 30 ring atoms, and the other of Ar¹¹ and Ar¹² is a substituted or unsubstituted fused ring group having 10 to 30 ring atoms.

[9] In the organic electroluminescence device according to the above aspect of the invention, in the formula (20), Ar¹² is selected from a naphthyl group, phenanthryl group, benzoanthryl group and dibenzofuranyl group, and Ar¹¹ is an unsubstituted phenyl group or a phenyl group substituted by at least one of the monocyclic group and the fused ring group.

[10] In the organic electroluminescence device according to the above aspect of the invention, in the formula (20), Ar¹² is a substituted or unsubstituted fused ring group having 10 to 30 ring atoms and Ar¹¹ is an unsubstituted phenyl group.

[11] In the organic electroluminescence device according to the above aspect of the invention, Ar¹¹ and Ar¹² in the formula (20) are each independently a substituted or unsubstituted monocyclic group having 5 to 30 ring atoms.

[12] In the organic electroluminescence device according to the above aspect of the invention, Ar¹¹ and Ar¹² in the formula (20) are each independently a substituted or unsubstituted phenyl group.

[13] In the organic electroluminescence device according to the above aspect of the invention, in the formula (20), Ar¹¹ is an unsubstituted phenyl group and Ar¹² is a phenyl group having at least one of the monocyclic group and the fused ring group as a substituent.

[14] In the organic electroluminescence device according to the above aspect of the invention, in the formula (20), Ar¹¹ and Ar¹² are each independently a phenyl group having at least one of the monocyclic group and the fused ring group as a substituent.

The above aspects of the invention enable to provide an organic EL device capable of providing blue emission and an aromatic amine derivative effectively usable in an organic thin-film layer of the organic EL device.

### BRIEF DESCRIPTION OF DRAWING

FIG. 1 schematically shows an exemplary arrangement of an organic electroluminescence device according to an exemplary embodiment of the invention.

### DESCRIPTION OF EMBODIMENT(S)

### Aromatic Amine Derivative

An aromatic amine derivative according to an exemplary embodiment of the invention is represented by the formula (1).

R₂, R₃, R₄, R₅, R₇, R₈, R₉ and R₁₀ in the formula (1) will be described below.

Examples of the aryl group having 6 to 30 ring carbon atoms in the formula (1) are a phenyl group, 1-naphthyl group, 2-naphthyl group, 1-anthryl group, 2-anthryl group, 9-anthryl group, benzanthryl group, 1-phenanthryl group, 2-phenanthryl group, 3-phenanthryl group, 4-phenanthryl group, 9-phenanthryl group, pyrenyl group, 1-chrysenyl group, 2-chrysenyl group, 3-chrysenyl group, 4-chrysenyl group, 5-chrysenyl group, 6-chrysenyl group, benzo[c]phenanthryl group, benzo[g]chrysenyl group, 1-triphenylenyl group, 2-triphenylenyl group, 1-fluorenyl group, 2-fluorenyl group, 3-fluorenyl group, 4-fluorenyl group, 9-fluorenyl group, benzofluorenyl group, dibenzofluorenyl group, 2-biphenyl group, 3-biphenyl group, 4-biphenyl group, o-terphenyl-4-yl group, o-terphenyl-3-yl group, o-terphenyl-2-yl group, m-terphenyl-4-yl group, m-terphenyl-3-yl group, m-terphenyl-2-yl group, p-terphenyl-4-yl group, p-terphenyl-3-yl group, p-terphenyl-2-yl group, m-quarterphenyl group, 3-fluoranthenyl group, 8-fluoranthenyl group, 7-fluoranthenyl group, and benzofluoranthenyl group.

The aryl group in the formula (1) preferably has 6 to 20 ring carbon atoms, more preferably 6 to 12 ring carbon atoms. Among the aryl group, a phenyl group, biphenyl group, naphthyl group, phenanthryl group, terphenyl group and fluorenyl group are particularly preferable. In a 1-fluorenyl group, 2-fluorenyl group, 3-fluorenyl group and 4-fluorenyl group, a carbon atom at a position 9 is preferably substituted by a substituted or unsubstituted alkyl group having 1 to 30 carbon atoms in the formula (1).

Examples of the heterocyclic group having 5 to 30 ring carbon atoms in the formula (1) are a pyrrolyl group, pyrazinyl group, pyridyl group, pyrimidinyl group, triazinyl group, pyridazinyl group, indolyl group, isoindolyl group, imidazolyl group, pyrazolyl group, triazolyl group, benzimidazolyl group, indazolyl group, imidazopyridinyl group, benzotriazolyl group, furyl group, benzofuranyl group, isobenzofuranyl group, dibenzofuranyl group, thienyl group, benzothiophenyl group, dibenzothiophenyl group, quinolyl group, isoquinolyl group, quinoxalinyl group, quinazolinyl group, carbazolyl group, phenantridinyl group, acridinyl group, phenanthrolinyl group, phenazinyl group, phenothiazinyl group, phenoxazinyl group, oxazolyl group, isoxazolyl group, oxadiazolyl group, benzooxazolyl group, thiazolyl group, thiadiazolyl group, isothiazolyl group, benzothiazolyl group, furazanyl group, and a group formed from a pyridine ring, pyrazine ring, pyrimidine ring, pyridazine ring, triazine ring, indole ring, quinoline ring, isoquinoline ring, quinoxaline ring, quinazoline ring, acridine ring, pirrolidine ring, dioxane ring, piperidine ring, morpholine ring, piperadine ring, carbazole ring, furan ring, thiophene ring, oxazole ring, isoxazole ring, oxadiazole ring, benzoxazole ring, thiazole ring, isothiazole ring, thiadiazole ring, benzothiazole ring, triazole ring, imidazole ring, benzimidazole ring, pyrazole ring, indazole ring, imidazopyridine ring, pyrane ring, benzofuran ring, dibenzofuran ring, benzothiophene ring and dibenzothiophene ring.

Specific examples of the heterocyclic group having 5 to 30 ring atoms are a 1-pyrrolyl group, 2-pyrrolyl group, 3-pyrrolyl group, pyrazinyl group, 2-pyridinyl group, 2-pyrimidinyl group, 4-pyrimidinyl group, 5-pyrimidinyl group, 6-pyrimidinyl group, 1,2,3-triazine-4-yl group, 1,2,4-triazine-3-yl group, 1,3,5-triazine-2-yl group, 1-imidazolyl group, 2-imidazolyl group, 1-pyrazolyl group, 1-indolidinyl group, 2-indolidinyl group, 3-indolidinyl group, 5-indolidinyl group, 6-indolidinyl group, 7-indolidinyl group, 8-indolidinyl group, 2-imidazopyridinyl group, 3-imidazopyridinyl group, 5-imidazopyridinyl group, 6-imidazopyridinyl group, 7-imidazopyridinyl group, 8-imidazopyridinyl group, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 9-carbazolyl group, azacarbazolyl-1-yl group, azacarbazolyl-2-yl group, azacarbazolyl-3-yl group, azacarbazolyl-4-yl group, azacarbazolyl-5-yl group, azacarbazolyl-6-yl group, azacarbazolyl-7-yl group, azacarbazolyl-8-yl group, azacarbazolyl-9-yl group, 1-phenanthrydinyl group, 2-phenanthrydinyl group, 3-phenanthrydinyl group, 4-phenanthrydinyl group, 6-phenanthrydinyl group, 7-phenanthrydinyl group, 8-phenanthrydinyl group, 9-phenanthrydinyl group, 10-phenanthrydinyl group, 1-acridinyl group, 2-acridinyl group, 3-acridinyl group, 4-acridinyl group, 9-acridinyl group, 1,7-phenanthroline-2-yl group, 1,7-phenanthroline-3-yl group, 1,7-phenanthroline-4-yl group, 1,7-phenanthroline-5-yl group, 1,7-phenanthroline-6-yl group, 1,7-phenanthroline-8-yl group, 1,7-phenanthroline-9-yl group, 1,7-phenanthroline-10-yl group, 1,8-phenanthroline-2-yl group, 1,8-phenanthroline-3-yl group, 1,8-phenanthroline-4-yl group, 1,8-phenanthroline-5-yl group, 1,8-phenanthroline-6-yl group, 1,8-phenanthroline-7-yl group, 1,8-phenanthroline-9-yl group, 1,8-phenanthroline-10-yl group, 1,9-phenanthroline-2-yl group, 1,9-phenanthroline-3-yl group, 1,9-phenanthroline-4-yl group, 1,9-phenanthroline-5-yl group, 1,9-phenanthroline-6-yl group, 1,9-phenanthroline-7-yl group, 1,9-phenanthroline-8-yl group, 1,9-phenanthroline-10-yl group, 1,10-phenanthroline-2-yl group, 1,10-phenanthroline-3-yl group, 1,10-phenanthroline-4-yl group, 1,10-phenanthroline-5-yl group, 2,9-phenanthroline-1-yl group, 2,9-phenanthroline-3-yl group, 2,9-phenanthroline-4-yl group, 2,9-phenanthroline-5-yl group, 2,9-phenanthroline-6-yl group, 2,9-phenanthroline-7-yl group, 2,9-phenanthroline-8-yl group, 2,9-phenanthroline-10-yl group, 2,8-phenanthroline-1-yl group, 2,8-phenanthroline-3-yl group, 2,8-phenanthroline-4-yl group, 2,8-phenanthroline-5-yl group, 2,8-phenanthroline-6-yl group, 2,8-phenanthroline-7-yl group, 2,8-phenanthroline-9-yl group, 2,8-phenanthroline-10-yl group, 2,7-phenanthroline-1-yl group, 2,7-phenanthroline-3-yl group, 2,7-phenanthroline-4-yl group, 2,7-phenanthroline-5-yl group, 2,7-phenanthroline-6-yl group, 2,7-phenanthroline-8-yl group, 2,7-phenanthroline-9-yl group, 2,7-phenanthroline-10-yl group, 1-phenazinyl group, 2-phenazinyl group, 1-phenothiazinyl group, 2-phenothiazinyl group, 3-phenothiazinyl group, 4-phenothiazinyl group, 10-phenothiazinyl group, 1-phenoxazinyl group, 2-phenoxazinyl group, 3-phenoxazinyl group, 4-phenoxazinyl group, 10-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrole-1-yl group, 2-methylpyrrole-3-yl group, 2-methylpyrrole-4-yl group, 2-methylpyrrole-5-yl group, 3-methylpyrrole-1-yl group, 3-methylpyrrole-2-yl group, 3-methylpyrrole-4-yl group, 3-methylpyrrole-5-yl group, 2-t-butylpyrrole-4-yl group, 3-(2-phenylpropyl)pyrrole-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, 4-t-butyl-3-indolyl group, 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-silafluorenyl group, 2-silafluorenyl group, 3-silafluorenyl group, 4-silafluorenyl group, 1-germafluorenyl group, 2-germafluorenyl group, 3-germafluorenyl group and 4-germafluorenyl group.

The heterocyclic group in the formula (1) preferably has 5 to 20 ring atoms, more preferably 5 to 14 ring atoms. Among the above heterocyclic group, a 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-carbazolyl group, 2-carbazolyl group, 3-carbazolyl group, 4-carbazolyl group, and 9-carbazolyl group are preferable. In 1-carbazolyl group, 2-carbazolyl group, 3-carbazolyl group and 4-carbazolyl group, a nitrogen atom at the position 9 is preferably substituted by a substituted or unsubstituted aryl group having 6 to 30 ring carbon atoms or a substituted or unsubstituted heterocyclic group having 5 to 30 ring atoms in the formula (1).

The alkyl group having 1 to 30 carbon atoms in the formula (1) may be linear, branched or cyclic. Examples of the linear or branched alkyl group are a methyl group, ethyl group, propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neopentyl group, 1-methylpentyl group, 2-methylpentyl group, 1-pentylhexyl group, 1-butylpentyl group, 1-heptyloctyl group, 3-methylpentyl group, hydroxymethyl group, 1-hydroxyethyl group, 2-hydroxyethyl group, 2-hydroxyisobutyl group, 1,2-dihydroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 1,2-dinitroethyl group, 2,3-dinitro-t-butyl group, and 1,2,3-trinitropropyl group.

Examples of the cyclic alkyl group (cycloalkyl group) are a cyclopropyl group, cyclobutyl group, cyclopentyl group, cyclohexyl group, 4-methylcyclohexyl group, 1-adamantyl group, 2-adamantyl group, 1-norbornyl group and 2-norbornyl group.

The linear or branched alkyl group in the formula (1) preferably has 1 to 10 carbon atoms, more preferably 1 to 6 carbon atoms. Among the linear or branched alkyl group, a methyl group, ethyl group, propyl group, isopropyl group, n-butyl group, s-butyl group, isobutyl group, t-butyl group, n-pentyl group and n-hexyl group are preferable.

The cycloalkyl group in the formula (1) preferably has 3 to 10 ring carbon atoms, more preferably 5 to 8 ring carbon atoms. Among the cycloalkyl group, a cyclopentyl group and a cyclohexyl group are preferable.

A halogenated alkyl group provided by substituting the alkyl group with a halogen atom is exemplified by a halogenated alkyl group provided by substituting the alkyl group having 1 to 30 carbon atoms with one or more halogen groups. Specific examples of the halogenated alkyl group are a fluoromethyl group, difluoromethyl group, trifluoromethyl group, fluoroethyl group and trifluoromethylmethyl group.

The alkenyl group having 2 to 30 carbon atoms in the formula (1) may be linear, branched or cyclic. Examples of the alkenyl group are vinyl, propenyl, butenyl, oleyl, eicosapentaenyl, docosahexaenyl, styryl, 2,2-diphenylvinyl, 1,2,2-triphenylvinyl and 2-phenyl-2-propenyl, among which a vinyl group is preferable.

The alkynyl group having 2 to 30 carbon atoms in the formula (1) may be linear, branched or cyclic. Examples of the alkynyl group are ethynyl, propynyl and 2-phenylethynyl, among which an ethynyl group is preferable.

The alkylsilyl group having 3 to 30 carbon atoms in the formula (1) is exemplified by a trialkylsilyl group having the examples of the alkyl group having 1 to 30 carbon atoms. Specific examples of the alkylsilyl group are a trimethylsilyl group, triethylsilyl group, tri-n-butylsilyl group, tri-n-octylsilyl group, triisobutylsilyl group, dimethylethylsilyl group, dimethylisopropylsilyl group, dimethyl-n-propylsilyl group, dimethyl-n-butylsilyl group, dimethyl-t-butylsilyl group, diethylisopropylsilyl group, vinyldimethylsilyl group, propyldimethylsilyl group and triisopropylsilyl group. Three alkyl groups in the trialkylsilyl group may be the same or different.

Examples of the arylsilyl group having 6 to 30 ring carbon atoms in the formula (1) are a dialkylarylsilyl group, alkyldiarylsilyl group and triarylsilyl group.

The dialkylarylsilyl group is exemplified by a dialkylarylsilyl group having two of the examples of the alkyl group having 1 to 30 carbon atoms and one of the aryl group having 6 to 30 ring carbon atoms. The dialkylarylsilyl group preferably has 8 to 30 carbon atoms. Two alkyl groups may be the same or different.

The alkyldiarylsilyl group is exemplified by an alkyldiarylsilyl group having one of the examples of the alkyl group having 1 to 30 carbon atoms and two of the aryl group having 6 to 30 ring carbon atoms. The dialkylarylsilyl group preferably has 13 to 30 carbon atoms. Two aryl groups may be the same or different.

The triarylsilyl group is exemplified by a triarylsilyl group having three of the aryl group having 6 to 30 ring carbon atoms. The triarylsilyl group preferably has 18 to 30 carbon atoms. Three aryl groups may be the same or different.

The alkoxy group having 1 to 30 carbon atoms in the formula (1) is represented by —OY. Y is exemplified by the alkyl group having 1 to 30 carbon atoms. Examples of the alkoxy group are a methoxy group, ethoxy group, propoxy group, butoxy group, pentyloxy group and hexyloxy group.

A halogenated alkoxy group provided by substituting the alkoxy group with a halogen atom is exemplified by a halogenated alkoxy group provided by substituting the alkoxy group having 1 to 30 carbon atoms with one or more halogen groups.

The aralkyl group having 6 to 30 ring carbon atoms in the formula (1) is represented by —Y—Z. Y is exemplified by an alkylene group corresponding to the alkyl group having 1 to 30 carbon atoms. Z is exemplified by the examples of the above aryl group having 6 to 30 ring carbon atoms. This aralkyl group is preferably an aralkyl group having 7 to 30 carbon atoms, in which an aryl moiety has 6 to 30 carbon atoms, preferably 6 to 20 carbon atoms, more preferably 6 to 12 carbon atoms, and an alkyl moiety has 1 to 30 carbon atoms, preferably 1 to 20 carbon atoms, more preferably 1 to 10 carbon atoms, further preferably 1 to 6 carbon atoms. Examples of the aralkyl group are a benzyl group, 2-phenylpropane-2-yl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, 2-β-naphthylisopropyl group, 1-pyrrolylmethyl group, 2-(1-pyrrolyl)ethyl group, p-methylbenzyl group, m-methylbenzyl group, o-methylbenzyl group, p-chlorobenzyl group, m-chlorobenzyl group, o-chlorobenzyl group, p-bromobenzyl group, m-bromobenzyl group, o-bromobenzyl group, p-iodobenzyl group, m-iodobenzyl group, o-iodobenzyl group, p-hydroxybenzyl group, m-hydroxybenzyl group, o-hydroxybenzyl group, p-aminobenzyl group, m-aminobenzyl group, o-aminobenzyl group, p-nitrobenzyl group, m-nitrobenzyl group, o-nitrobenzyl group, p-cyanobenzyl group, m-cyanobenzyl group, o-cyanobenzyl group, 1-hydroxy-2-phenylisopropyl group, and 1-chloro-2-phenylisopropyl group.

The aryloxy group having 6 to 30 ring carbon atoms in the formula (1) is represented by —OZ. Z is exemplified by the aryl group having 6 to 30 ring carbon atoms or later-described monocyclic group and fused cyclic group. The aryloxy group is exemplified by a phenoxy group.

Examples of the halogen atom in the formula (1) are fluorine, chlorine, bromine and iodine, among which fluorine is preferable.

In the invention, “carbon atoms forming a ring (ring carbon atoms)” mean carbon atoms forming a saturated ring, unsaturated ring, or aromatic ring. “Atoms forming a ring (ring atoms)” mean carbon atoms and hetero atoms forming a hetero ring including a saturated ring, unsaturated ring, or aromatic ring.

Examples of the substituent meant by “substituted or unsubstituted” are a hydroxyl group, nitro group and carboxy group in addition to the above-described aryl group, heterocyclic group, alkyl group (linear or branched alkyl group, cycloalkyl group and halogenated alkyl group), alkenyl group, alkynyl group, alkylsilyl group, arylsilyl group, alkoxy group, halogenated alkoxy group, aralkyl group, aryloxy group, halogen atom, deuterium atom, cyano group. In the above-described substituents, the aryl group, heterocyclic group, alkyl group, halogen atom, alkylsilyl group, arylsilyl group, cyano group and deuterium atom are preferable. The preferable ones of the specific examples of each substituent are further preferable.

The phrase “unsubstituted” in “substituted or unsubstituted” means that a group is substituted by a hydrogen atom.

In a compound or a partial structure described below thereof, the same is applied to the description of “substituted or unsubstituted.”

In the formula (1), R₁ and R₆ are represented by a formula (2) below.

In the formula (2), L₁ and L₂ each independently represent a single bond, a divalent residue of a substituted or unsubstituted aryl group having 6 to 30 ring carbon atoms, or a divalent residue of a substituted or unsubstituted heterocyclic group having 5 to 30 ring atoms. L₃ represents a divalent residue of a substituted or unsubstituted aryl group having 6 to 30 ring carbon atoms, or a divalent residue of a substituted or unsubstituted heterocyclic group having 5 to 30 ring atoms.

The divalent residue of the aryl group having 6 to 30 ring carbon atoms is exemplified by a divalent residue derived from an aryl group having 6 to 30 ring carbon atoms for R₂, R₃, R₄, R₅, R₇, R₈, R₉ and R₁₀ in the formula (1).

The divalent residue of the heterocyclic group having 5 to 30 ring atoms is exemplified by a divalent residue derived from the heterocyclic group having 5 to 30 ring atoms for R₂, R₃, R₄, R₅, R₇, R₈, R₉ and R₁₀ in the formula (1).

In the formula (2), Ar₁ is a monovalent substituent having a partial structure represented by the formula (3).

In the formula (3), X represents an oxygen atom or a sulfur atom. In the formula (3), A and B represent a six-membered ring. The six-membered ring represented by A and B may be fused with another ring.

In the formula (2), Ar₂ is a substituted or unsubstituted aryl group having 6 to 30 ring carbon atoms, a substituted or unsubstituted heterocyclic group having 5 to 30 ring atoms, or a monovalent substituent having a partial structure represented by the formula (3). The aryl group and heterocyclic group for Ar₂ is the same as those in the description of R₁ to R₁₀ in the formula (1).

In the aromatic amine derivative according to the exemplary embodiment, the monovalent substituent having the partial structure represented by the formula (3) is preferably a monovalent residue represented by the formula (4).

In the formula (4), X represents an oxygen atom or a sulfur atom.

In the formula (4), R₁₁ to R₁₈ each independently represent the same as R₂, R₃, R₄, R₅, R₇, R₈, R₉ and R₁₀ in the formula (1). However, in the formula (2); when Ar₁ is a monovalent residue of the formula (4), one of R₁₁ to R₁₈ is a single bond to be bonded to L₁; and when Ar₂ is a monovalent residue of the formula (4), one of R₁₁ to R₁₈ is a single bond to be bonded to L₂. Thus, the structure of the formula (4) in which one of R₁₁ to R₁₈ is a single bond is exemplarily represented by the following formulae (4A) to (4D). Herein, the formula (4A) describes that R₁₁ in the formula (4) is a single bond, not a methyl group. The same explanation applies to the other formulae (4B) to (4D). Among these formulae, the formula (4A) in which R₁₁ is a single bond and the formula (4C) in which R₁₃ is a single bond are preferable.

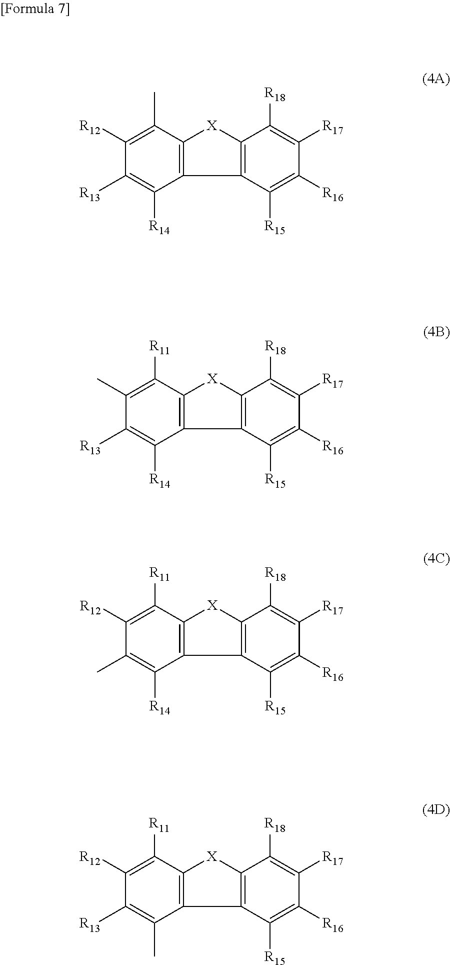

In the formula (4), at least one combination of R₁₁ and R₁₂, R₁₂ and R₁₃, R₁₃ and R₁₄, R₁₅ and R₁₆, R₁₆ and R₁₇, and R₁₇ and R₁₈ may form a saturated or unsaturated ring. An instance where such a ring may be formed in the formula (4) is exemplarily represented by the following formulae (4E), (4F) and (4G). R₁₁ to R₂₀ in the formulae (4E), (4F) and (4G) each independently represent the same as R₂ to R₅ and R₇ to R₁₀ in the formula (1).

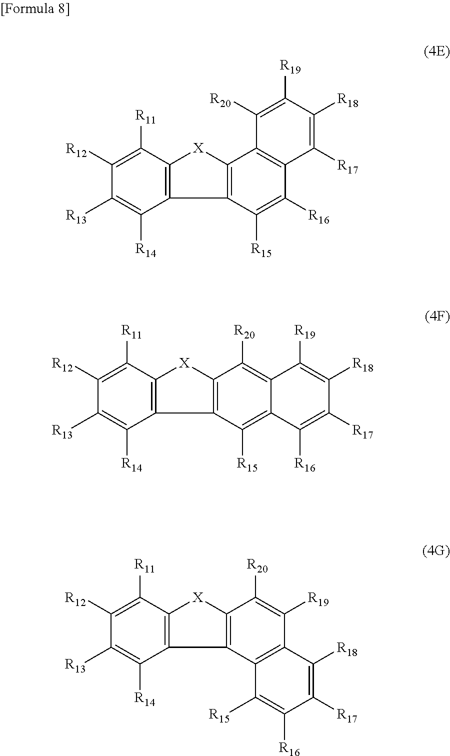

In the aromatic amine derivative according to the exemplary embodiment, the monovalent substituent having the partial structure represented by the formula (3) is preferably one of the monovalent residues represented by the formulae (5) to (10).

In the formulae (5) to (10), X₂ represents an oxygen atom or a sulfur atom.

In the formulae (5) to (10), X₃ represents an oxygen atom, a sulfur atom, NR₃₁ or CR₃₂R₃₃.

NR₃₁ is provided by bonding R₃₁ to a nitrogen atom (N).

CR₃₂R₃₃ is provided by bonding R₃₂ and R₃₃ to a carbon atom (C).

In the formulae (5) to (10), R₂₁ to R₃₀ each independently represent the substituents and a hydrogen atom described for R₂, R₃, R₄, R₅, R₇, R₈, R₉ and R₁₀ in the formula (1). However, in the formula (2), when Ar₁ is one of the monovalent residues of the formulae (5) to (10), one of R₂₁ to R₃₀ is a single bond to be bonded to L₁; and when Ar₂ is one of the monovalent residues of the formulae (5) to (10), one of R₂₁ to R₃₀ is a single bond to be bonded to L₁. When one of R₂₁ to R₃₀ is a single bond, structures of the formulae (5) to (10) are those of the following formulae (5A) to (5J), the following formulae (6A) to (6J), the following formulae (7A) to (7J), the following formulae (8A) to (8J), the following formulae (9A) to (9J), and the following formulae (10A) to (10J). Herein, the formula (5A) describes that R₂₁ in the formula (5) is a single bond, not a methyl group. The same explanation applies to the formulae (5B) to (5J), the formulae (6A) to (6J), the formulae (7A) to (7J), the formulae (8A) to (8J), the formulae (9A) to (9J), and the formulae (10A) to (10J).

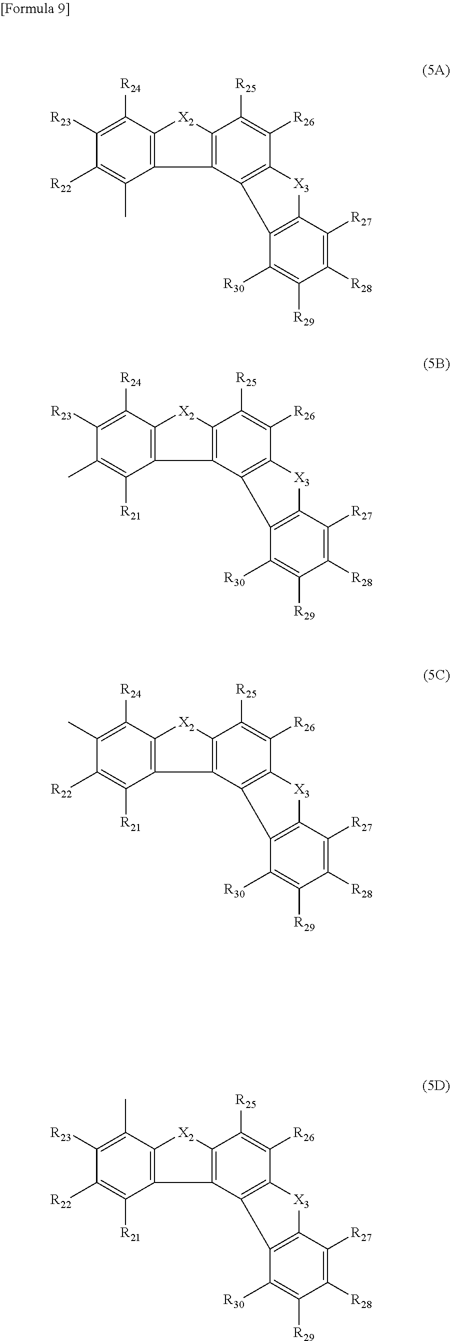

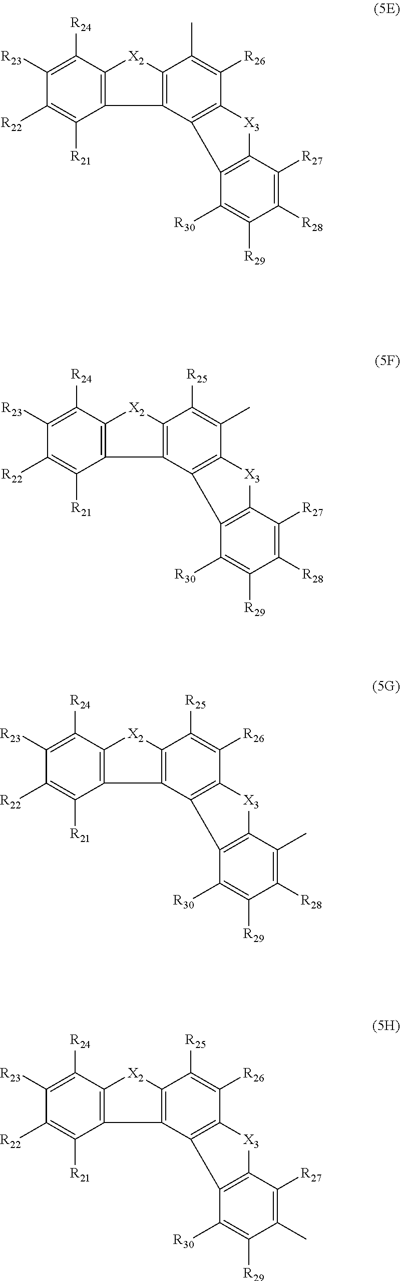

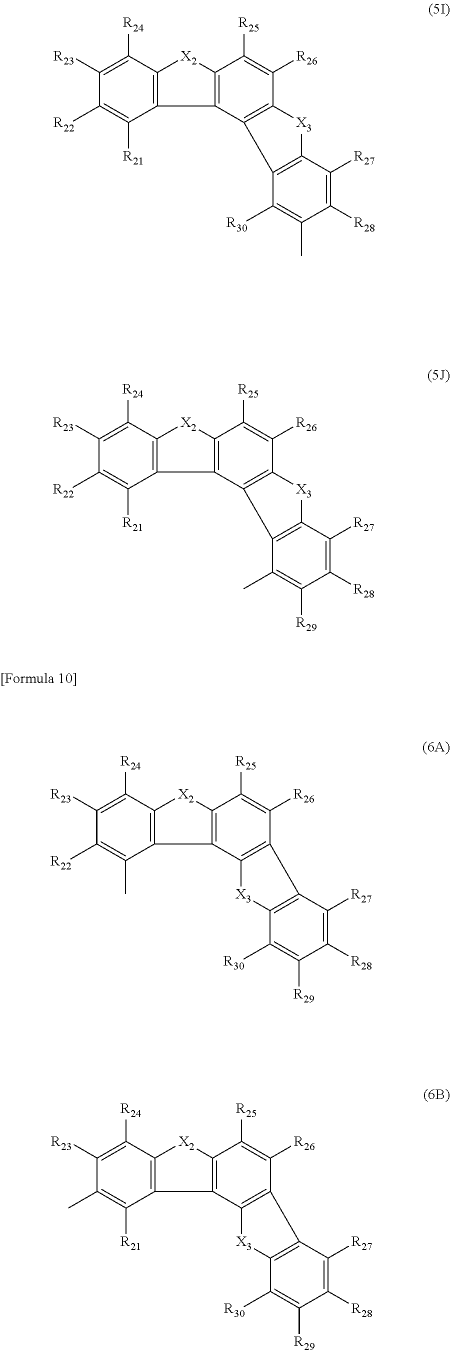

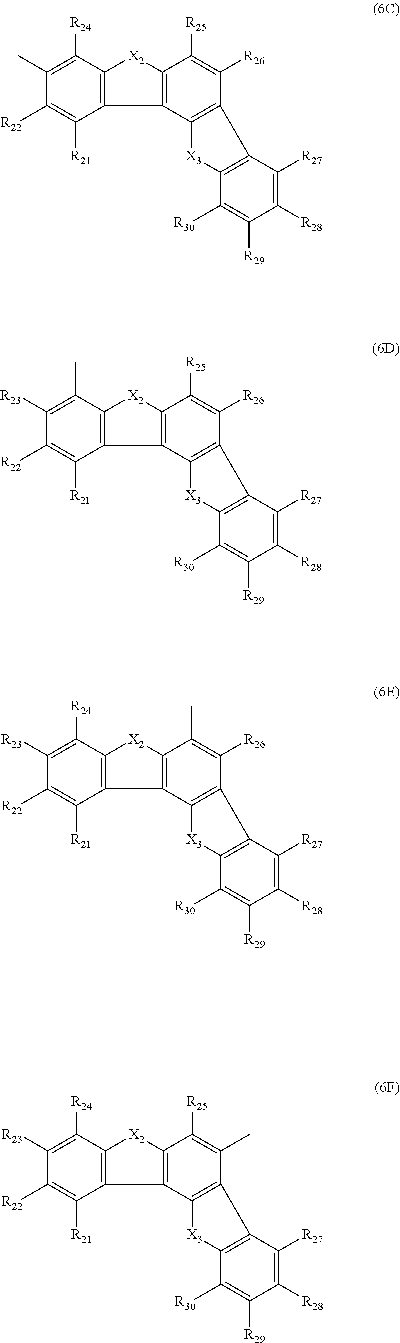

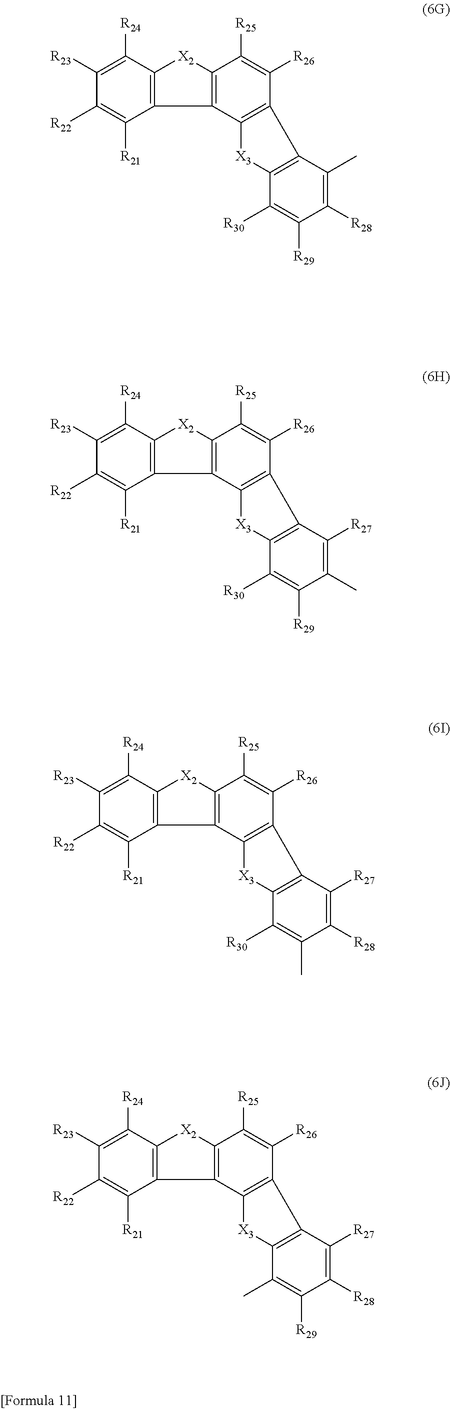

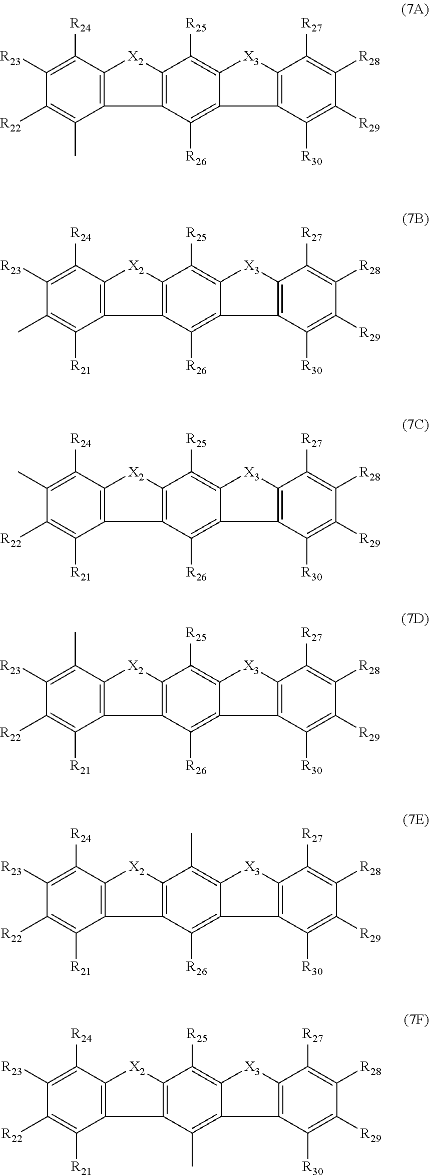

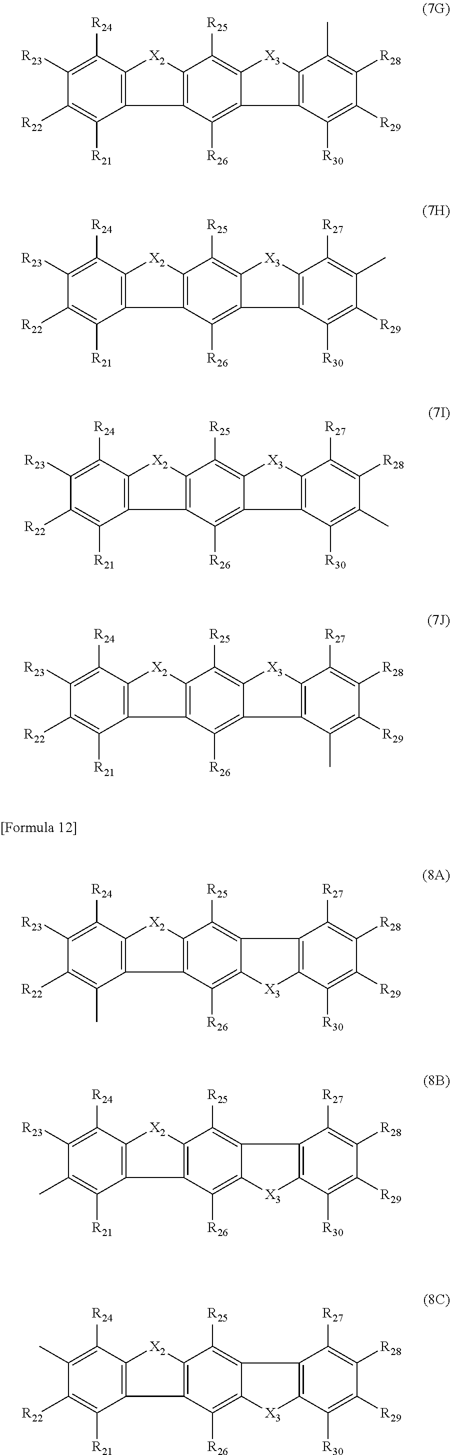

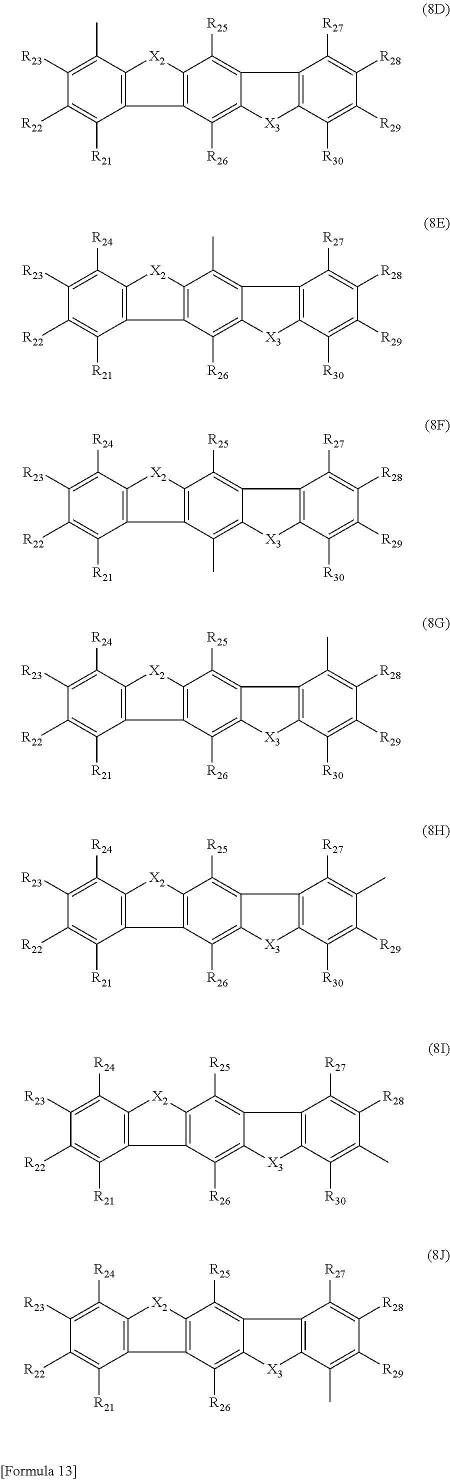

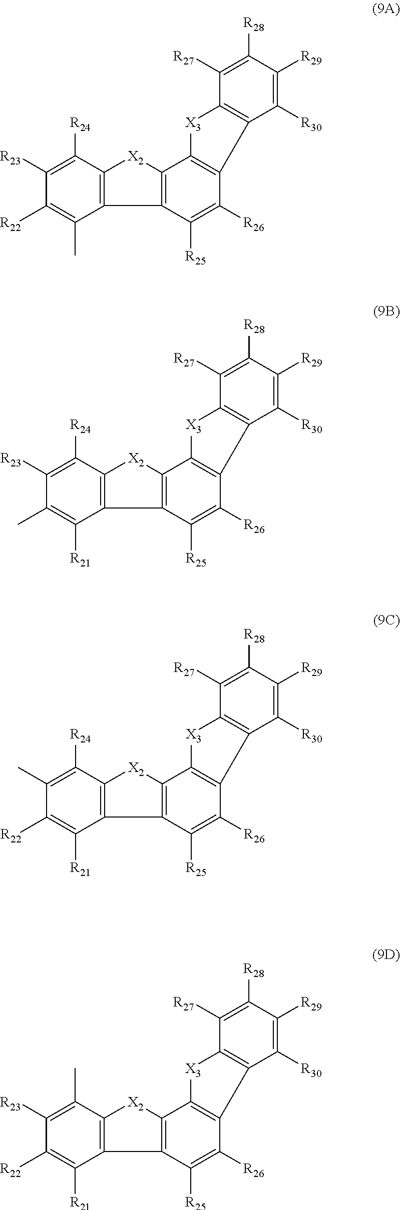

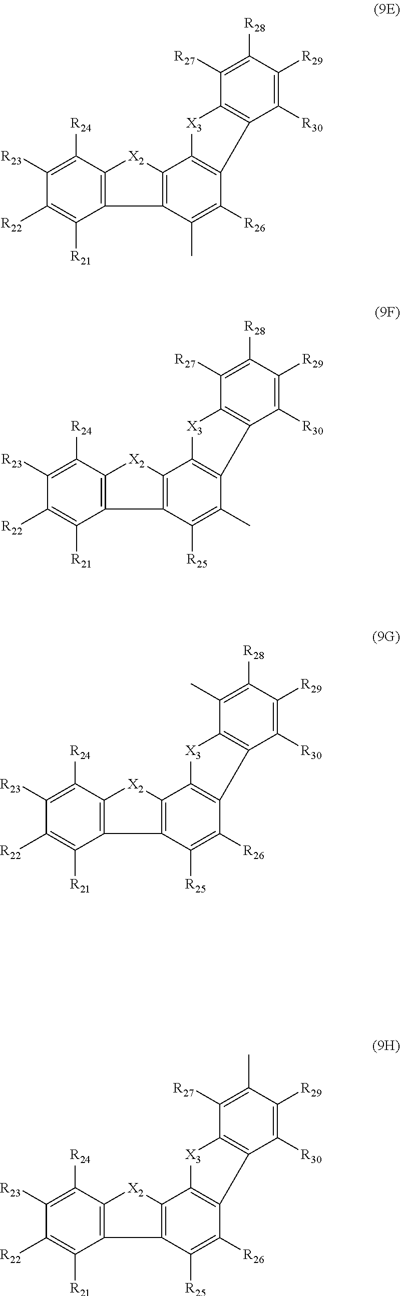

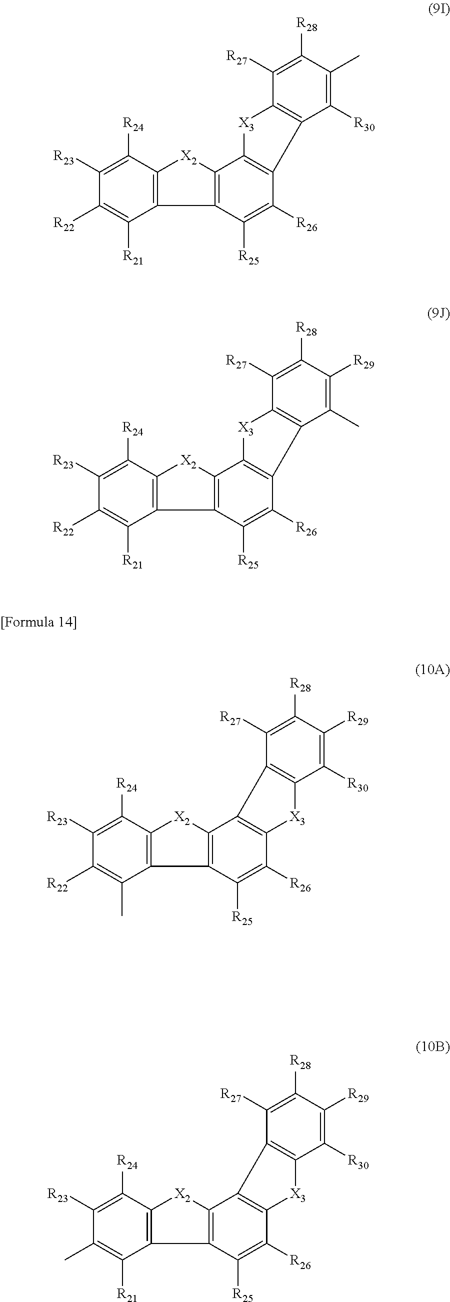

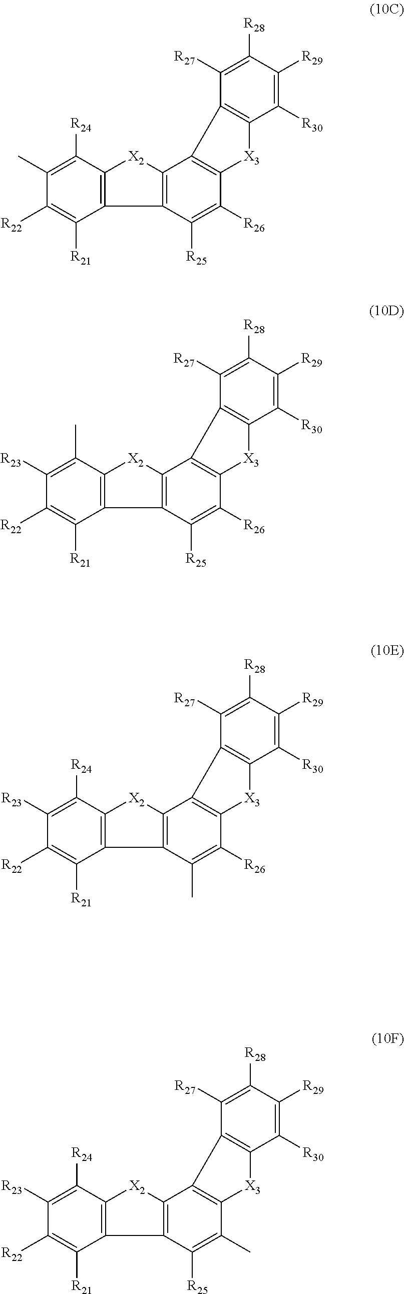

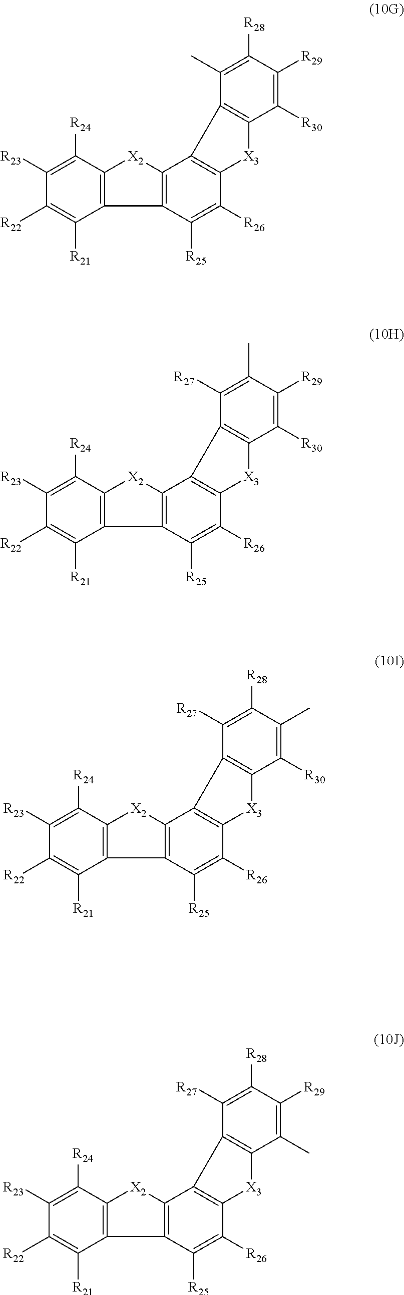

In the formulae (5) to (10), R₃₁, R₃₂ and R₃₃ each independently represent a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms. The aryl group, the heterocyclic group and the alkyl group for R₃₁, R₃₂ and R₃₃ represent the same as R₂, R₃, R₄, R₅, R₇, R₈, R₉ and R₁₀ in the formula (1).

In the formulae (5) to (10), at least one combination of R₂₁ and R₂₂, R₂₂ and R₂₃, R₂₃ and R₂₄, R₂₅ and R₂₆, R₂₇ and R₂₈, R₂₈ and R₂₉, and R₂₉ and R₃₀ may form a saturated or unsaturated ring. However, in the formulae (7) and (8), R₂₅ and R₂₆ do not form a ring.

Examples of the aromatic amine derivative according to the exemplary embodiment of the invention are as follows. However, the invention is not limited to the aromatic amine derivatives having the structures.

In the aromatic amine derivative according to the exemplary embodiment, R₁ and R₆ in the formula (1) are preferably represented by the formula (2). In this instance, the aromatic amine derivative has a structure represented by a formula (1A) below.

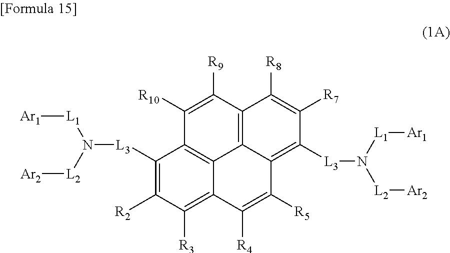

Specific examples of the aromatic amine derivative according to the exemplary embodiment are aromatic amine derivatives described in Tables 1 to 22 for R₂, R₃, R₄, R₅, R₇, R₈, R₉ and R₁₀, L₁ to L₃, and Ar₁ to Ar₂ in the formula (1A). Note that “—” in L₁ to L₃ of the tables represents a single bond. Moreover, in L₁ to L₃ and Ar₁ to Ar₂ in the tables, a line extending outward from the cyclic structure and having no chemical formula (e.g., CH₃, Ph, CN, benzene ring) at an end of the line represents a single bond, not a methyl group. For instance, L₃ in a compound 1 below represents a 1,4-phenylene group. Likewise, Ar₁ represents a single bond at a position 4 of a dibenzofuran ring. In short, Ar₁ represents a 4-dibenzofuranyl group. Likewise, Ar₂ represents a phenyl group.

TABLE 1

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 1 | H | H | H | H | H | H | H | H | — | — | 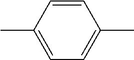 | 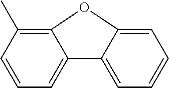 | 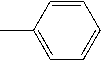 |
| 2 | H | H | H | H | H | H | H | H | — | — | 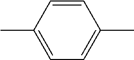 | 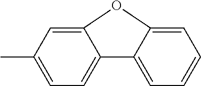 | 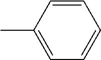 |
| 3 | H | H | H | H | H | H | H | H | — | — | 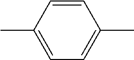 | 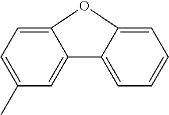 | 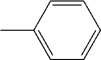 |
| 4 | H | H | H | H | H | H | H | H | — | — | 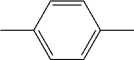 | 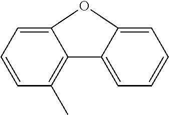 | 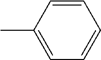 |
| 5 | H | H | H | H | H | H | H | H | — | — | 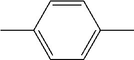 | 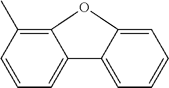 | 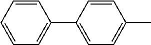 |
| 6 | H | H | H | H | H | H | H | H | — | — | 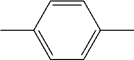 | 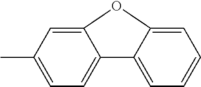 | 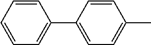 |
| 7 | H | H | H | H | H | H | H | H | — | — | 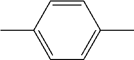 | 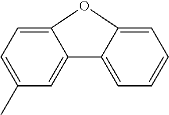 | 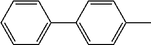 |
| 8 | H | H | H | H | H | H | H | H | — | — | 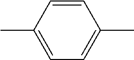 | 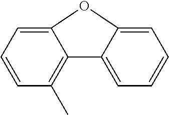 | 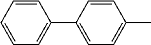 |
| 9 | H | H | H | H | H | H | H | H | — | — | 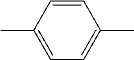 | 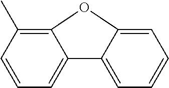 | 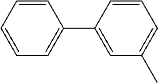 |
| 10 | H | H | H | H | H | H | H | H | — | — | 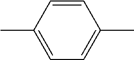 | 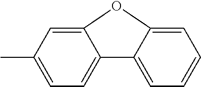 | 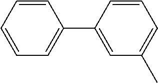 |
| 11 | H | H | H | H | H | H | H | H | — | — | 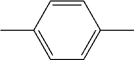 | 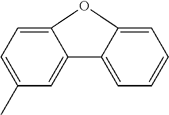 | 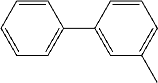 |
| 12 | H | H | H | H | H | H | H | H | — | — | 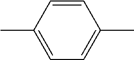 | 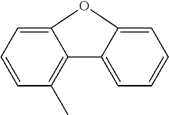 | 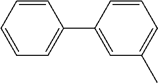 |
| 13 | H | H | H | H | H | H | H | H | — | — | 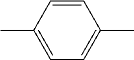 | 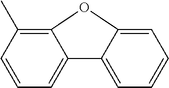 | 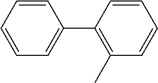 |

TABLE 2

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 14 | H | H | H | H | H | H | H | H | — | — | 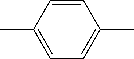 | 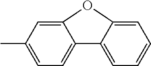 | 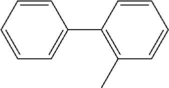 |
| 15 | H | H | H | H | H | H | H | H | — | — | 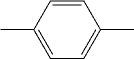 | 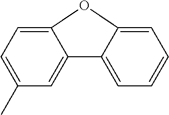 | 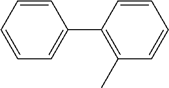 |
| 16 | H | H | H | H | H | H | H | H | — | — | 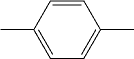 | 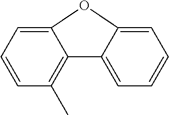 | 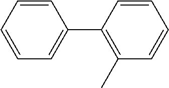 |
| 17 | H | H | H | H | H | H | H | H | — | — | 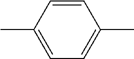 | 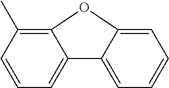 | 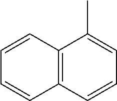 |
| 18 | H | H | H | H | H | H | H | H | — | — | 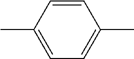 | 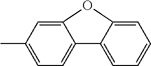 | 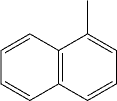 |
| 19 | H | H | H | H | H | H | H | H | — | — | 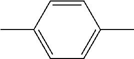 | 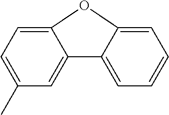 | 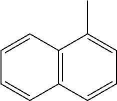 |
| 20 | H | H | H | H | H | H | H | H | — | — | 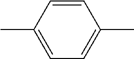 | 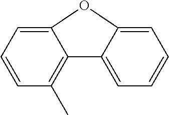 | 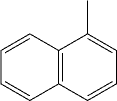 |
| 21 | H | H | H | H | H | H | H | H | — | — | 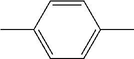 | 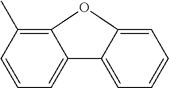 | 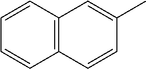 |
| 22 | H | H | H | H | H | H | H | H | — | — | 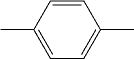 | 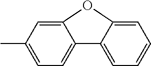 | 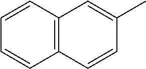 |
| 23 | H | H | H | H | H | H | H | H | — | — | 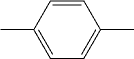 | 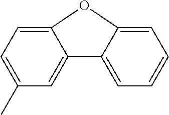 | 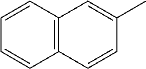 |
| 24 | H | H | H | H | H | H | H | H | — | — | 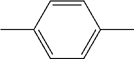 | 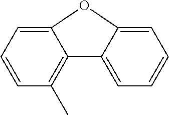 | 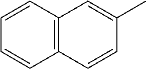 |
| 25 | H | H | H | H | H | H | H | H | — | — | 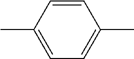 | 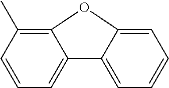 | 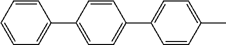 |
| 26 | H | H | H | H | H | H | H | H | — | — | 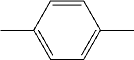 | 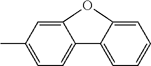 | 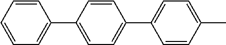 |
| 27 | H | H | H | H | H | H | H | H | — | — | 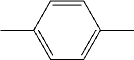 | 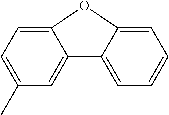 | 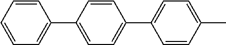 |

TABLE 3

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 28 | H | H | H | H | H | H | H | H | — | — | 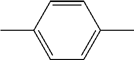 | 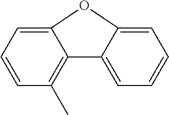 | 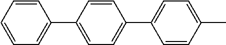 |
| 29 | H | H | H | H | H | H | H | H | — | — | 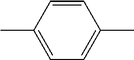 | 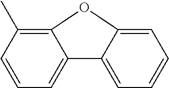 | 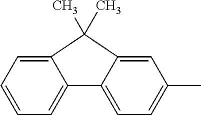 |
| 30 | H | H | H | H | H | H | H | H | — | — | 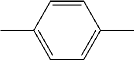 | 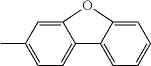 | 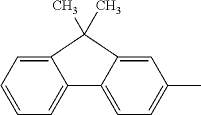 |
| 31 | H | H | H | H | H | H | H | H | — | — | 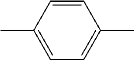 | 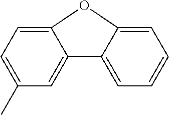 | 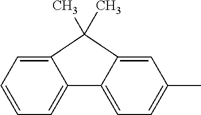 |
| 32 | H | H | H | H | H | H | H | H | — | — | 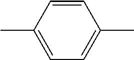 | 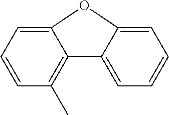 | 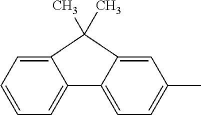 |
| 33 | H | H | H | H | H | H | H | H | — | — | 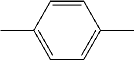 | 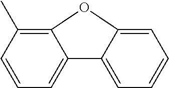 | 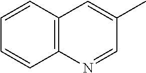 |
| 34 | H | H | H | H | H | H | H | H | — | — | 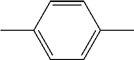 | 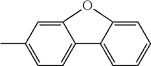 | 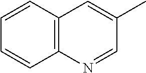 |
| 35 | H | H | H | H | H | H | H | H | — | — | 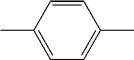 | 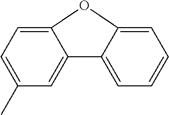 | 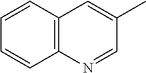 |
| 36 | H | H | H | H | H | H | H | H | — | — | 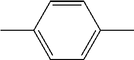 | 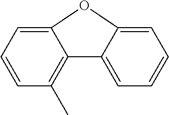 | 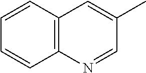 |
| 37 | H | H | H | H | H | H | H | H | — | — | 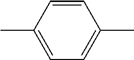 | 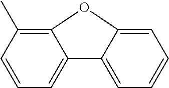 | 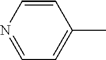 |
| 38 | H | H | H | H | H | H | H | H | — | — | 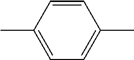 | 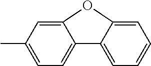 | 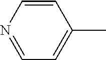 |
| 39 | H | H | H | H | H | H | H | H | — | — | 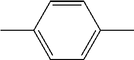 | 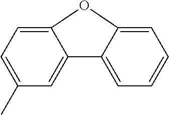 | 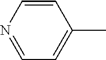 |

TABLE 4

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 40 | H | H | H | H | H | H | H | H | — | — | 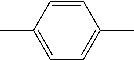 | 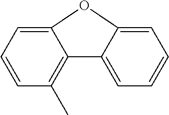 | 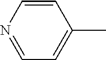 |
| 41 | H | H | H | H | H | H | H | H | — | — | 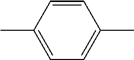 | 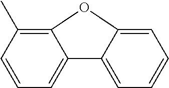 | 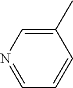 |
| 42 | H | H | H | H | H | H | H | H | — | — | 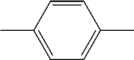 | 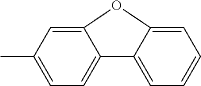 | 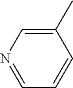 |
| 43 | H | H | H | H | H | H | H | H | — | — | 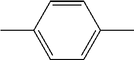 | 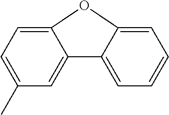 | 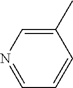 |
| 44 | H | H | H | H | H | H | H | H | — | — | 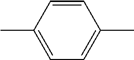 | 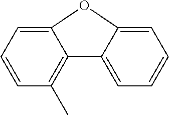 | 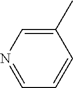 |
| 45 | H | H | H | H | H | H | H | H | — | — | 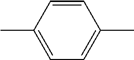 | 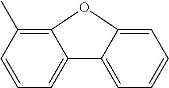 | 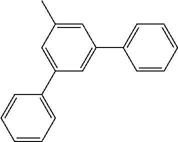 |
| 46 | H | H | H | H | H | H | H | H | — | — | 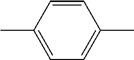 | 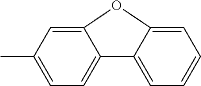 | 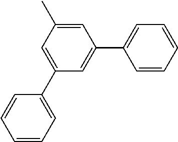 |
| 47 | H | H | H | H | H | H | H | H | — | — | 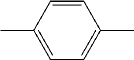 | 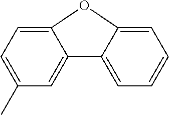 | 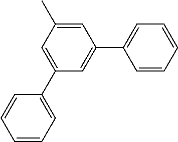 |
| 48 | H | H | H | H | H | H | H | H | — | — | 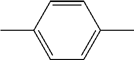 | 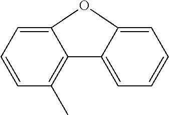 | 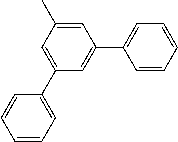 |
| 49 | H | H | H | H | H | H | H | H | — | — | 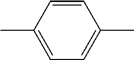 | 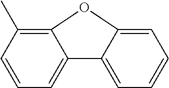 | 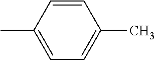 |
| 50 | H | H | H | H | H | H | H | H | — | — | 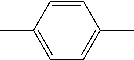 | 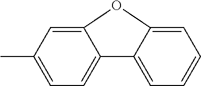 | 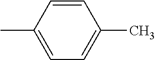 |
| 51 | H | H | H | H | H | H | H | H | — | — | 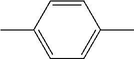 | 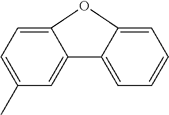 | 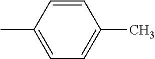 |
| 52 | H | H | H | H | H | H | H | H | — | — | 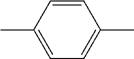 | 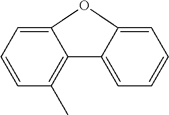 | 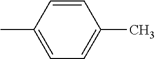 |

TABLE 5

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 53 | H | H | H | H | H | H | H | H | — | — | 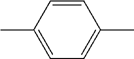 | 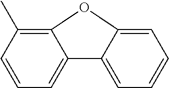 | 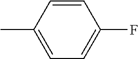 |
| 54 | H | H | H | H | H | H | H | H | — | — | 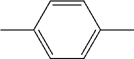 | 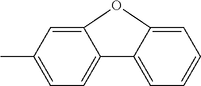 | 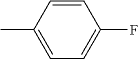 |
| 55 | H | H | H | H | H | H | H | H | — | — | 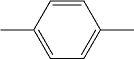 | 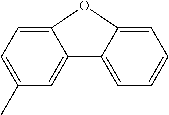 | 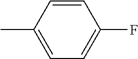 |
| 56 | H | H | H | H | H | H | H | H | — | — | 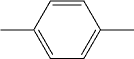 | 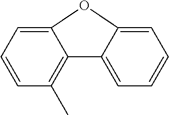 | 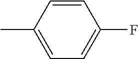 |
| 57 | H | H | H | H | H | H | H | H | — | — | 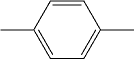 | 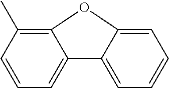 | 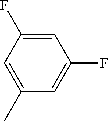 |
| 58 | H | H | H | H | H | H | H | H | — | — | 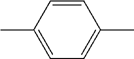 | 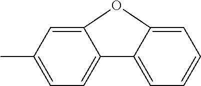 | 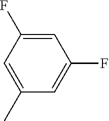 |
| 59 | H | H | H | H | H | H | H | H | — | — | 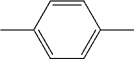 | 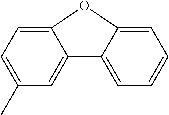 | 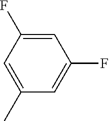 |
| 60 | H | H | H | H | H | H | H | H | — | — | 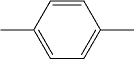 | 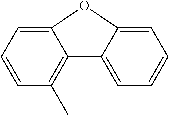 | 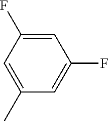 |
| 61 | H | H | H | H | H | H | H | H | — | — | 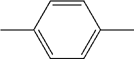 | 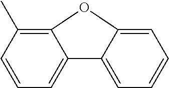 | 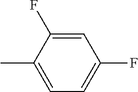 |
| 62 | H | H | H | H | H | H | H | H | — | — | 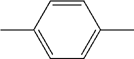 | 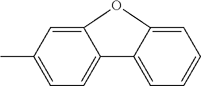 | 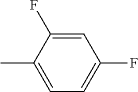 |
| 63 | H | H | H | H | H | H | H | H | — | — | 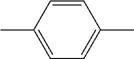 | 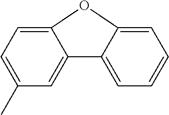 | 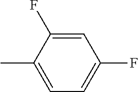 |
| 64 | H | H | H | H | H | H | H | H | — | — | 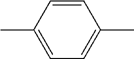 | 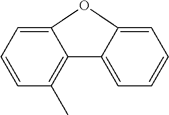 | 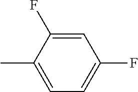 |

TABLE 6

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 65 | H | H | H | H | H | H | H | H | — | — | 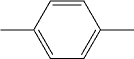 | 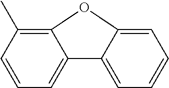 | 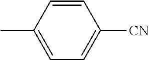 |
| 66 | H | H | H | H | H | H | H | H | — | — | 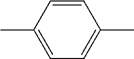 | 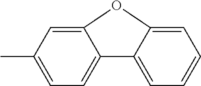 | 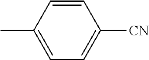 |
| 67 | H | H | H | H | H | H | H | H | — | — | 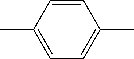 | 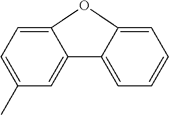 | 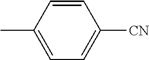 |
| 68 | H | H | H | H | H | H | H | H | — | — | 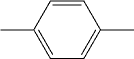 | 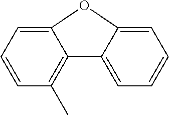 | 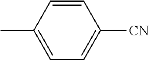 |
| 69 | H | H | H | H | H | H | H | H | — | — | 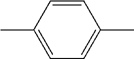 | 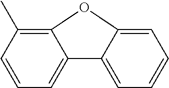 | 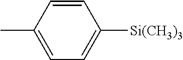 |
| 70 | H | H | H | H | H | H | H | H | — | — | 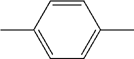 | 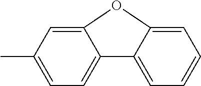 | 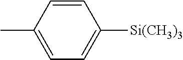 |
| 71 | H | H | H | H | H | H | H | H | — | — | 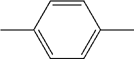 | 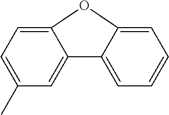 | 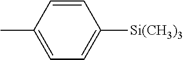 |
| 72 | H | H | H | H | H | H | H | H | — | — | 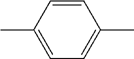 | 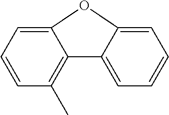 | 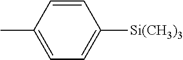 |
| 73 | H | H | H | H | H | H | H | H | — | — | 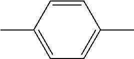 | 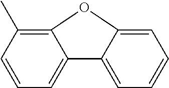 | 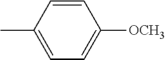 |
| 74 | H | H | H | H | H | H | H | H | — | — | 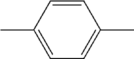 | 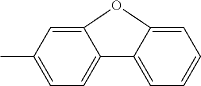 | 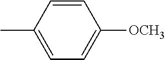 |
| 75 | H | H | H | H | H | H | H | H | — | — | 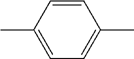 | 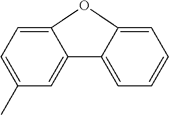 | 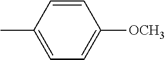 |
| 76 | H | H | H | H | H | H | H | H | — | — | 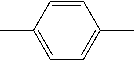 | 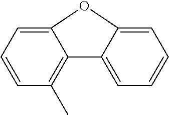 | 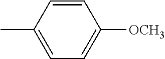 |
| 77 | H | H | H | H | H | H | H | H | — | — | 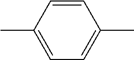 | 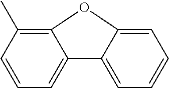 | 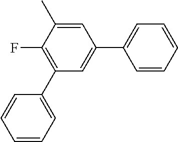 |

TABLE 7

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 78 | H | H | H | H | H | H | H | H | — | — | 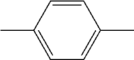 | 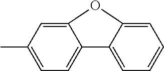 | 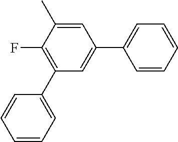 |
| 79 | H | H | H | H | H | H | H | H | — | — | 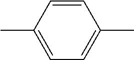 | 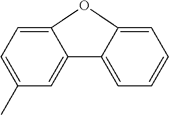 | 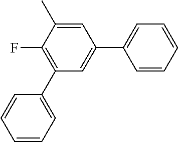 |
| 80 | H | H | H | H | H | H | H | H | — | — | 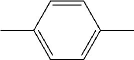 | 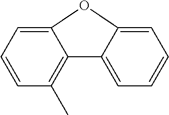 | 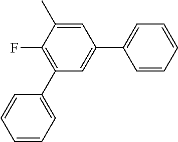 |
| 81 | H | H | H | H | H | H | H | H | — | — | 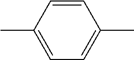 | 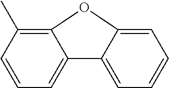 | 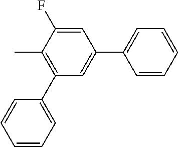 |
| 82 | H | H | H | H | H | H | H | H | — | — | 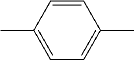 | 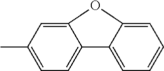 | 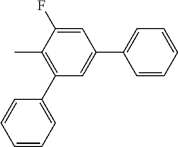 |
| 83 | H | H | H | H | H | H | H | H | — | — | 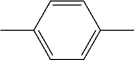 | 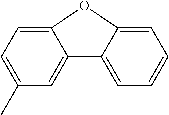 | 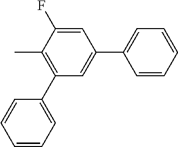 |
| 84 | H | H | H | H | H | H | H | H | — | — | 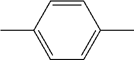 | 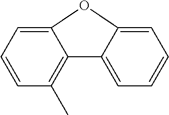 | 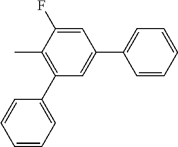 |
| 85 | H | H | H | H | H | H | H | H | — | — | 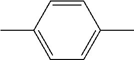 | 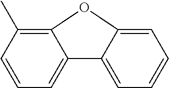 | 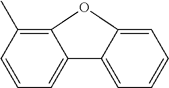 |
| 86 | H | H | H | H | H | H | H | H | — | — | 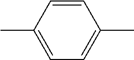 | 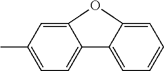 | 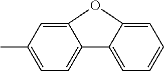 |
| 87 | H | H | H | H | H | H | H | H | — | — | 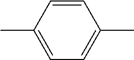 | 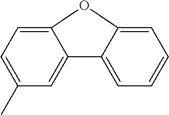 | 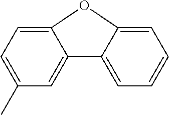 |
| 88 | H | H | H | H | H | H | H | H | — | — | 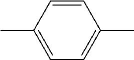 | 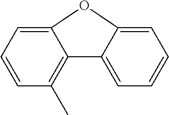 | 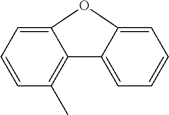 |

TABLE 8

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 89 | H | H | H | H | H | H | H | H | — | — | 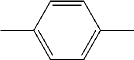 | 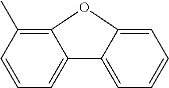 | 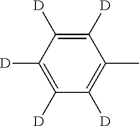 |
| 90 | H | H | H | H | H | H | H | H | — | — | 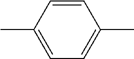 | 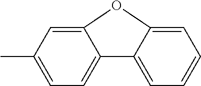 | 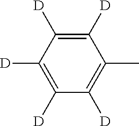 |
| 91 | H | H | H | H | H | H | H | H | — | — | 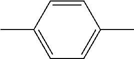 | 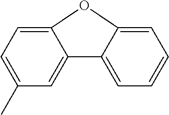 | 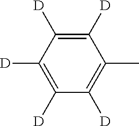 |
| 92 | H | H | H | H | H | H | H | H | — | — | 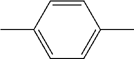 | 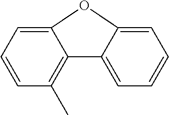 | 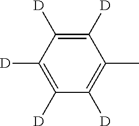 |
| 93 | H | H | H | H | H | H | H | H | — | — | 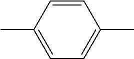 | 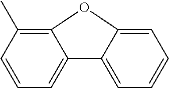 | 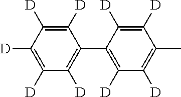 |
| 94 | H | H | H | H | H | H | H | H | — | — | 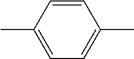 | 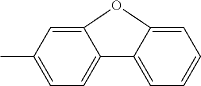 | 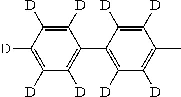 |
| 95 | H | H | H | H | H | H | H | H | — | — | 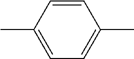 | 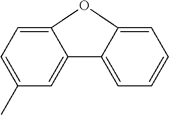 | 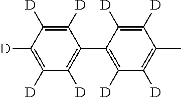 |
| 96 | H | H | H | H | H | H | H | H | — | — | 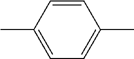 | 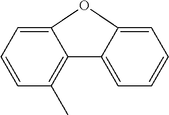 | 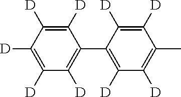 |
| 97 | H | H | H | H | H | H | H | H | — | — | 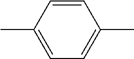 | 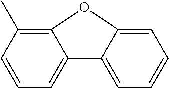 | 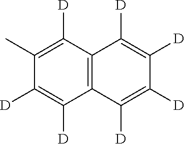 |
| 98 | H | H | H | H | H | H | H | H | — | — | 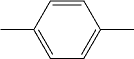 | 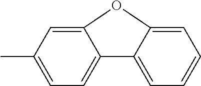 | 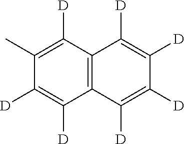 |
| 99 | H | H | H | H | H | H | H | H | — | — | 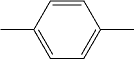 | 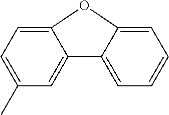 | 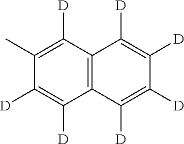 |
| 100 | H | H | H | H | H | H | H | H | — | — | 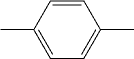 | 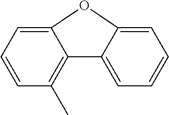 | 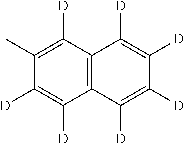 |

TABLE 9

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 101 | H | H | H | H | H | H | H | H | — | — | 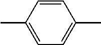 | 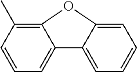 | 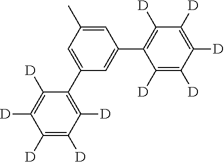 |
| 102 | H | H | H | H | H | H | H | H | — | — | 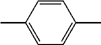 | 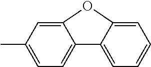 | 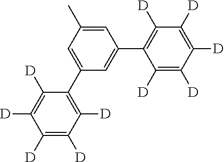 |
| 103 | H | H | H | H | H | H | H | H | — | — | 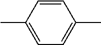 | 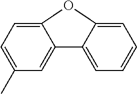 | 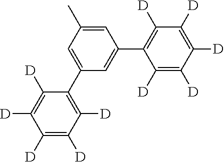 |
| 104 | H | H | H | H | H | H | H | H | — | — | 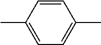 | 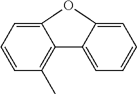 | 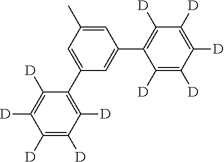 |
| 105 | H | H | H | H | H | H | H | H | — | — | 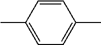 | 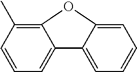 | 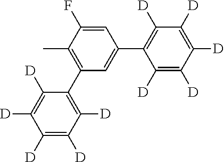 |
| 106 | H | H | H | H | H | H | H | H | — | — | 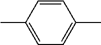 | 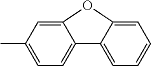 | 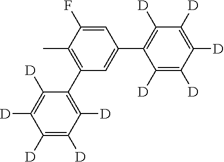 |
| 107 | H | H | H | H | H | H | H | H | — | — | 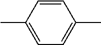 | 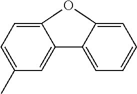 | 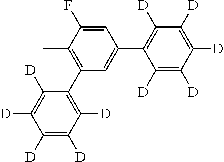 |
| 108 | H | H | H | H | H | H | H | H | — | — | 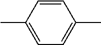 | 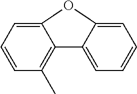 | 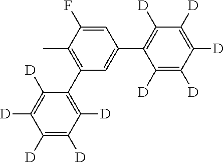 |
| 109 | H | H | H | H | H | H | H | H | — | — | 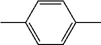 | 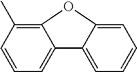 | 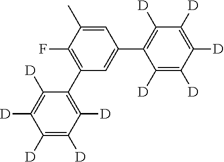 |
| 110 | H | H | H | H | H | H | H | H | — | — | 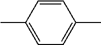 | 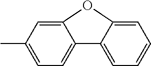 | 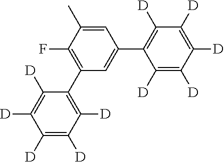 |

TABLE 10

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 111 | H | H | H | H | H | H | H | H | — | — | 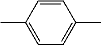 | 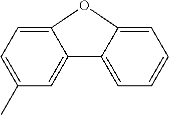 | 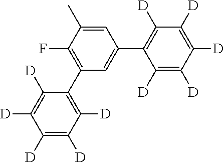 |
| 112 | H | H | H | H | H | H | H | H | — | — | 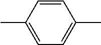 | 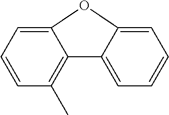 | 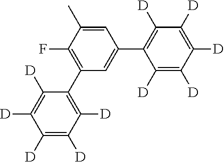 |
| 113 | H | H | H | H | H | H | H | H | — | — | 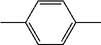 | 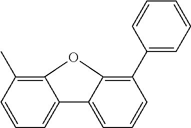 | 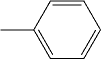 |
| 114 | H | H | H | H | H | H | H | H | — | — | 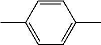 | 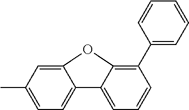 | 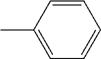 |
| 115 | H | H | H | H | H | H | H | H | — | — | 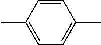 | 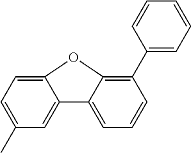 | 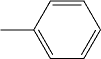 |
| 116 | H | H | H | H | H | H | H | H | — | — | 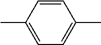 | 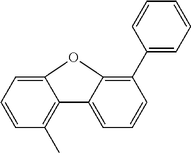 | 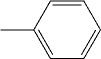 |
| 117 | H | H | H | H | H | H | H | H | — | — | 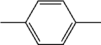 | 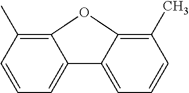 | 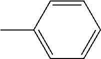 |
| 118 | H | H | H | H | H | H | H | H | — | — | 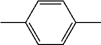 | 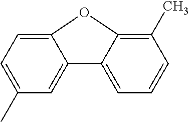 | 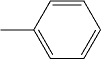 |
| 119 | H | H | H | H | H | H | H | H | — | — | 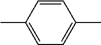 | 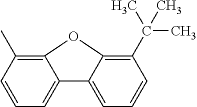 | 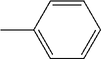 |
| 120 | H | H | H | H | H | H | H | H | — | — | 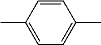 | 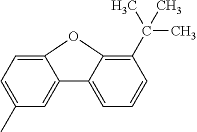 | 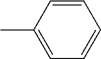 |
| 121 | H | H | H | H | H | H | H | H | — | — | 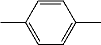 | 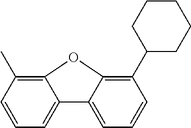 | 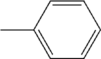 |
| 122 | H | H | H | H | H | H | H | H | — | — | 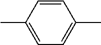 | 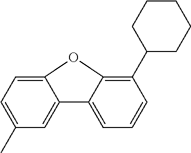 | 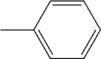 |

TABLE 11

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 123 | H | H | H | H | H | H | H | H | — | — | 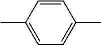 | 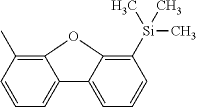 | 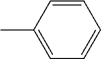 |
| 124 | H | H | H | H | H | H | H | H | — | — | 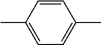 | 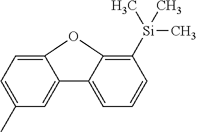 | 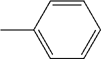 |
| 125 | H | H | H | H | H | H | H | H | — | — | 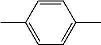 | 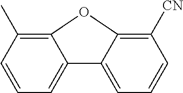 | 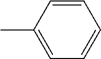 |
| 126 | H | H | H | H | H | H | H | H | — | — | 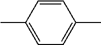 | 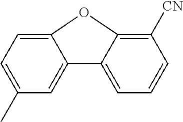 | 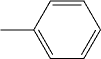 |
| 127 | H | H | H | H | H | H | H | H | — | — | 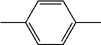 | 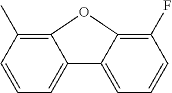 | 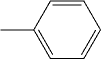 |
| 128 | H | H | H | H | H | H | H | H | — | — | 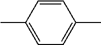 | 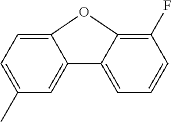 | 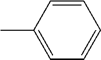 |
| 129 | H | H | H | H | H | H | H | H | — | — | 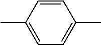 | 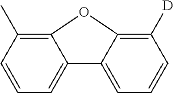 | 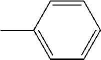 |
| 130 | H | H | H | H | H | H | H | H | — | — | 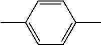 | 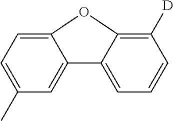 | 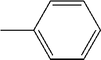 |
| 131 | H | H | H | H | H | H | H | H | 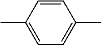 | — | 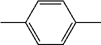 | 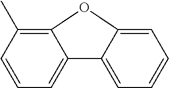 | 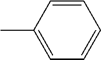 |
| 132 | H | H | H | H | H | H | H | H | 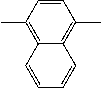 | — | 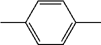 | 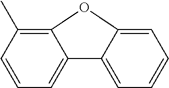 | 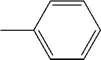 |
| 133 | H | H | H | H | H | H | H | H | 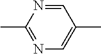 | — | 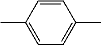 | 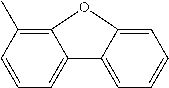 | 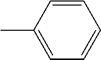 |

TABLE 12

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 134 | H | H | H | H | H | H | H | H | 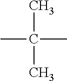 | — | 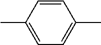 | 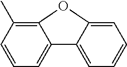 | 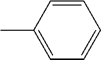 |
| 135 | H | H | H | H | H | H | H | H | — | — | 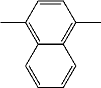 | 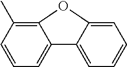 | 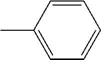 |
| 136 | H | H | H | H | H | H | H | H | — | — | 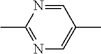 | 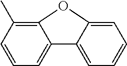 | 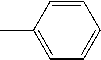 |
| 137 | H | H | H | H | H | H | H | H | 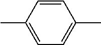 | 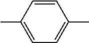 | 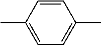 | 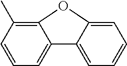 | 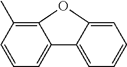 |
| 138 | H | H | H | H | H | H | H | H | 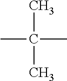 | 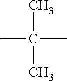 | 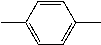 | 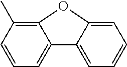 | 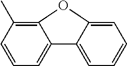 |
| 139 | H | H | H | H | H | H | H | H | — | — | 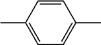 | 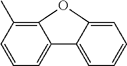 | 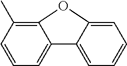 |
| 140 | H | H | H | H | H | H | H | H | — | — | 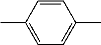 | 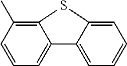 | 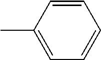 |
| 141 | H | H | H | H | H | H | H | H | — | — | 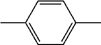 | 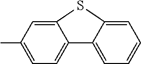 | 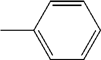 |
| 142 | H | H | H | H | H | H | H | H | — | — | 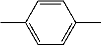 | 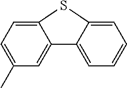 | 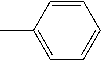 |
| 143 | H | H | H | H | H | H | H | H | — | — | 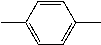 | 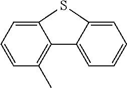 | 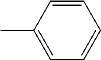 |
| 144 | H | H | H | H | H | H | H | H | — | — | 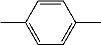 | 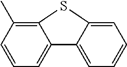 | 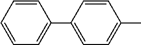 |
| 145 | H | H | H | H | H | H | H | H | — | — | 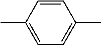 | 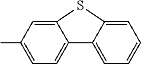 | 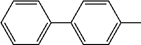 |
| 146 | H | H | H | H | H | H | H | H | — | — | 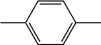 | 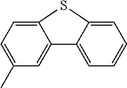 | 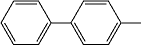 |

TABLE 13

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 147 | H | H | H | H | H | H | H | H | — | — | 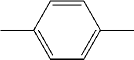 | 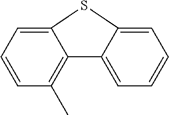 | 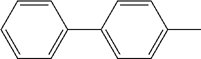 |
| 148 | H | H | H | H | H | H | H | H | — | — | 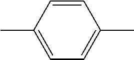 | 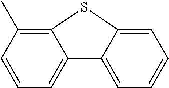 | 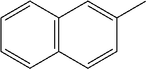 |
| 149 | H | H | H | H | H | H | H | H | — | — | 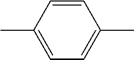 | 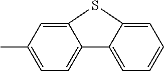 | 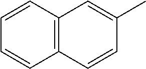 |
| 150 | H | H | H | H | H | H | H | H | — | — | 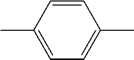 | 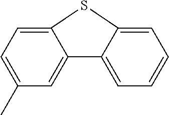 | 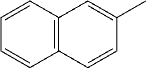 |
| 151 | H | H | H | H | H | H | H | H | — | — | 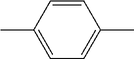 | 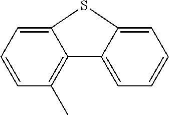 | 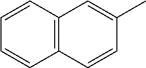 |
| 152 | H | H | H | H | H | H | H | H | — | — | 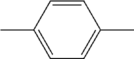 | 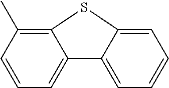 | 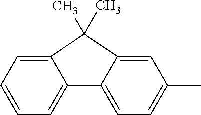 |
| 153 | H | H | H | H | H | H | H | H | — | — | 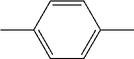 | 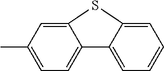 | 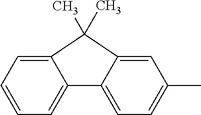 |
| 154 | H | H | H | H | H | H | H | H | — | — | 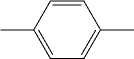 | 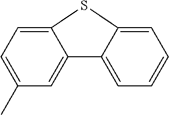 | 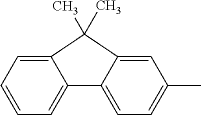 |
| 155 | H | H | H | H | H | H | H | H | — | — | 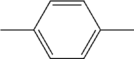 | 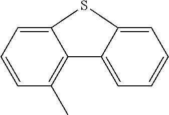 | 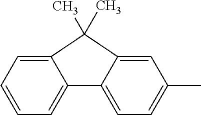 |
| 156 | H | H | H | H | H | H | H | H | — | — | 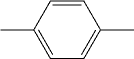 | 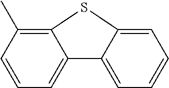 | 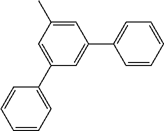 |
| 157 | H | H | H | H | H | H | H | H | — | — | 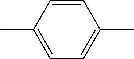 | 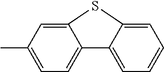 | 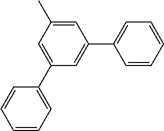 |
| 158 | H | H | H | H | H | H | H | H | — | — | 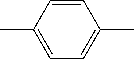 | 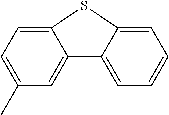 | 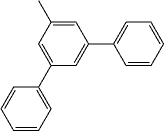 |
| 159 | H | H | H | H | H | H | H | H | — | — | 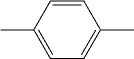 | 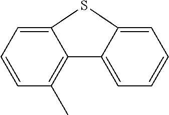 | 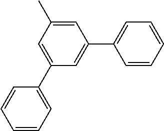 |

TABLE 14

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 160 | H | H | H | H | H | H | H | H | — | — | 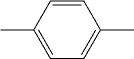 | 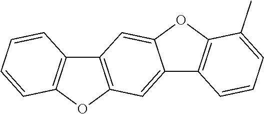 | 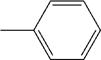 |
| 161 | H | H | H | H | H | H | H | H | — | — | 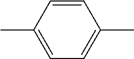 | 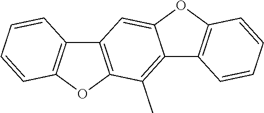 | 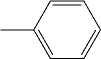 |
| 162 | H | H | H | H | H | H | H | H | — | — | 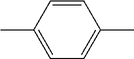 | 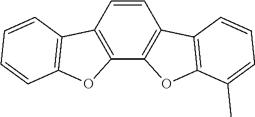 | 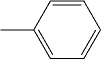 |
| 163 | H | H | H | H | H | H | H | H | — | — | 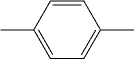 | 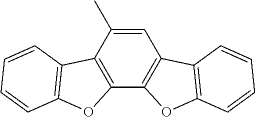 | 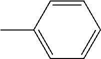 |
| 164 | H | H | H | H | H | H | H | H | — | — | 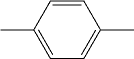 | 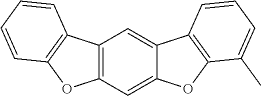 | 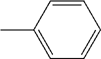 |
| 165 | H | H | H | H | H | H | H | H | — | — | 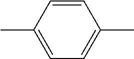 | 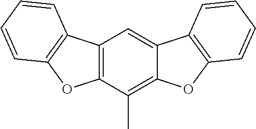 | 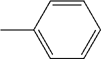 |

TABLE 15

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 166 | H | H | H | H | H | H | H | H | — | — | 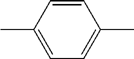 | 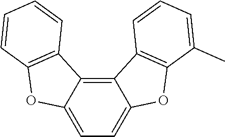 | 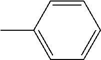 |
| 167 | H | H | H | H | H | H | H | H | — | — | 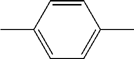 | 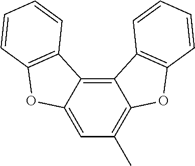 | 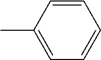 |
| 168 | H | H | H | H | H | H | H | H | — | — | 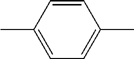 | 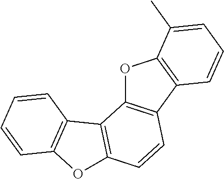 | 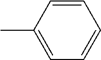 |
| 169 | H | H | H | H | H | H | H | H | — | — | 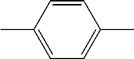 | 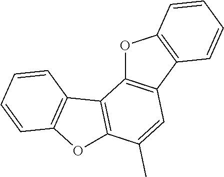 | 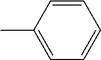 |
| 170 | H | H | H | H | H | H | H | H | — | — | 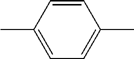 | 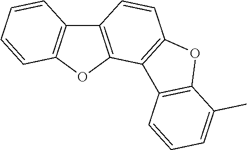 | 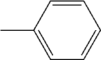 |
| 171 | H | H | H | H | H | H | H | H | — | — | 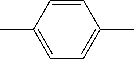 | 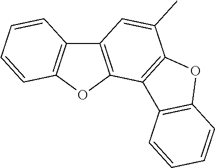 | 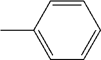 |
| 172 | H | H | H | H | H | H | H | H | — | — | 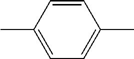 | 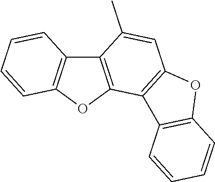 | 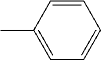 |

TABLE 16

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 173 | H | H | H | H | H | H | H | H | — | — | 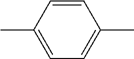 | 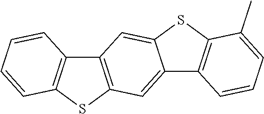 | 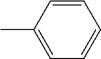 |
| 174 | H | H | H | H | H | H | H | H | — | — | 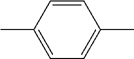 | 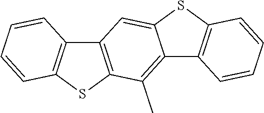 | 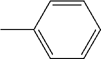 |
| 175 | H | H | H | H | H | H | H | H | — | — | 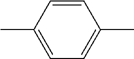 | 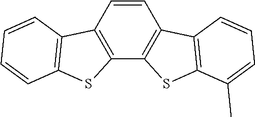 | 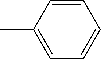 |
| 176 | H | H | H | H | H | H | H | H | — | — | 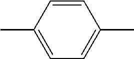 | 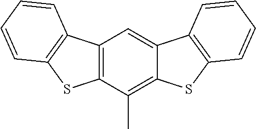 | 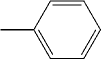 |
| 177 | H | H | H | H | H | H | H | H | — | — | 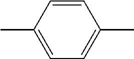 | 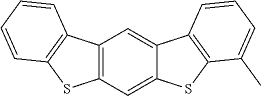 | 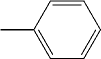 |

TABLE 17

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 178 | H | H | H | H | H | H | H | H | — | — | 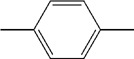 | 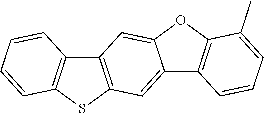 | 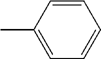 |
| 179 | H | H | H | H | H | H | H | H | — | — | 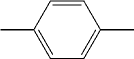 | 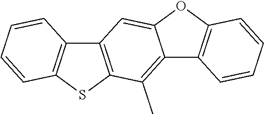 | 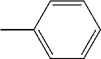 |
| 180 | H | H | H | H | H | H | H | H | — | — | 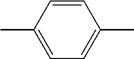 | 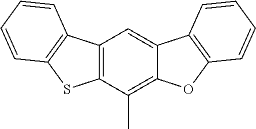 | 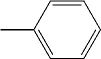 |
| 181 | H | H | H | H | H | H | H | H | — | — | 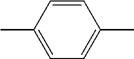 | 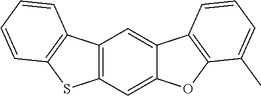 | 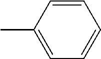 |
| 182 | H | H | H | H | H | H | H | H | — | — | 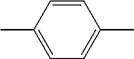 | 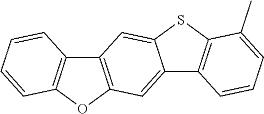 | 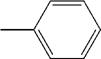 |
| 183 | H | H | H | H | H | H | H | H | — | — | 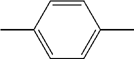 | 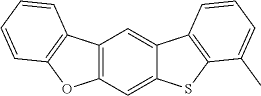 | 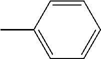 |

TABLE 18

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 184 | H | H | H | H | H | H | H | H | — | — | 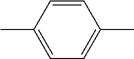 | 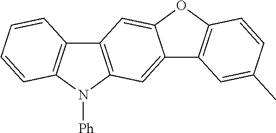 | 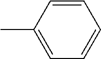 |
| 185 | H | H | H | H | H | H | H | H | — | — | 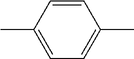 | 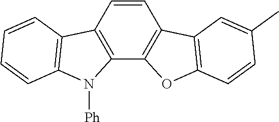 | 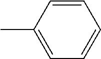 |
| 186 | H | H | H | H | H | H | H | H | — | — | 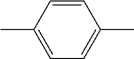 | 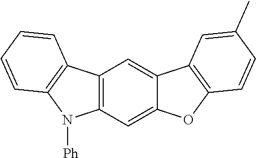 | 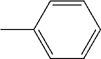 |
| 187 | H | H | H | H | H | H | H | H | — | — | 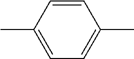 | 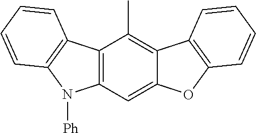 | 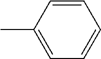 |
| 188 | H | H | H | H | H | H | H | H | — | — | 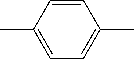 | 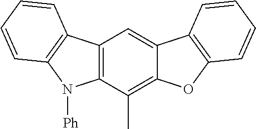 | 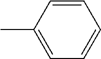 |
| 189 | H | H | H | H | H | H | H | H | — | — | 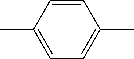 | 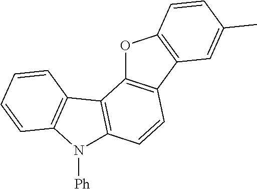 | 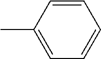 |
| 190 | H | H | H | H | H | H | H | H | — | — | 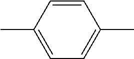 | 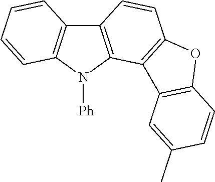 | 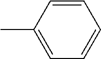 |

TABLE 19

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 191 | H | H | H | H | H | H | H | H | — | — | 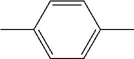 | 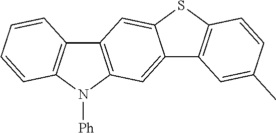 | 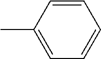 |
| 192 | H | H | H | H | H | H | H | H | — | — | 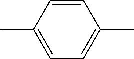 | 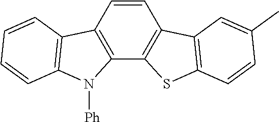 | 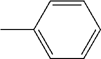 |
| 193 | H | H | H | H | H | H | H | H | — | — | 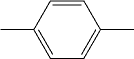 | 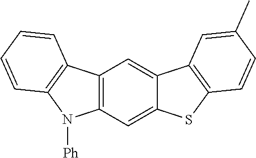 | 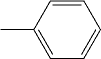 |
| 194 | H | H | H | H | H | H | H | H | — | — | 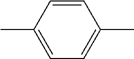 | 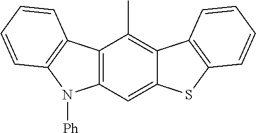 | 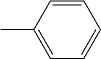 |
| 195 | H | H | H | H | H | H | H | H | — | — | 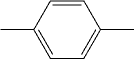 | 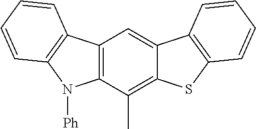 | 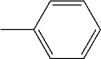 |
| 196 | H | H | H | H | H | H | H | H | — | — | 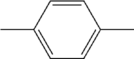 | 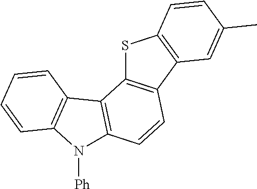 | 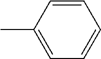 |
| 197 | H | H | H | H | H | H | H | H | — | — | 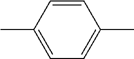 | 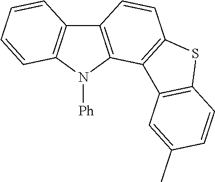 | 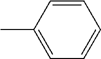 |

TABLE 20

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 198 | H | H | H | H | H | H | H | H | — | — | 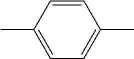 | 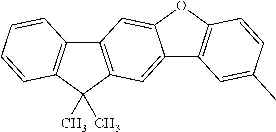 | 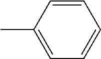 |
| 199 | H | H | H | H | H | H | H | H | — | — | 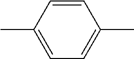 | 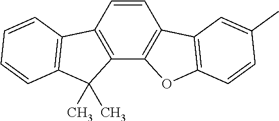 | 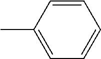 |
| 200 | H | H | H | H | H | H | H | H | — | — | 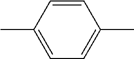 | 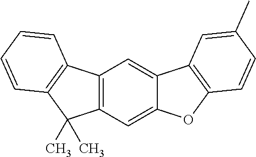 | 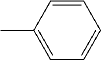 |
| 201 | H | H | H | H | H | H | H | H | — | — | 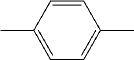 | 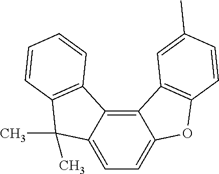 | 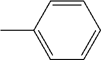 |
| 202 | H | H | H | H | H | H | H | H | — | — | 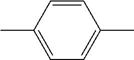 | 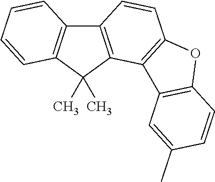 | 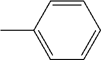 |
| 203 | H | H | H | H | H | H | H | H | — | — | 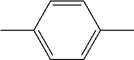 | 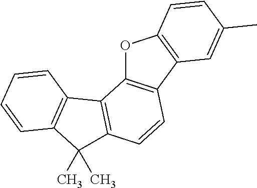 | 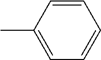 |

TABLE 21

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 204 | H | 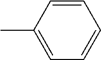 | H | H | H | 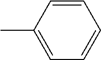 | H | H | — | — | 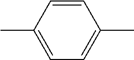 | 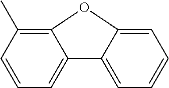 | 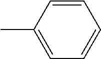 |
| 205 | H | 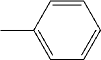 | H | H | H | 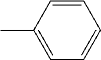 | H | H | — | — | 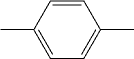 | 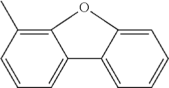 | 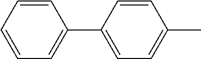 |
| 206 | H | 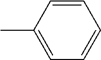 | H | H | H | 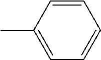 | H | H | — | — | 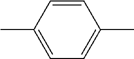 | 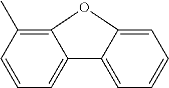 | 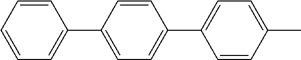 |
| 207 | H | 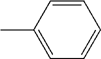 | H | H | H | 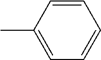 | H | H | — | — | 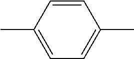 | 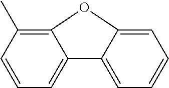 | 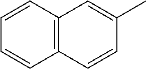 |
| 208 | H | 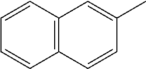 | H | H | H | 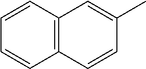 | H | H | — | — | 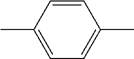 | 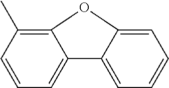 | 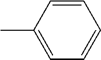 |
| 209 | H | 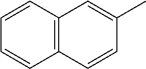 | H | H | H | 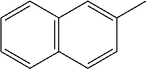 | H | H | — | — | 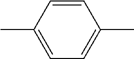 | 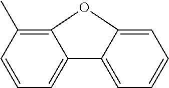 | 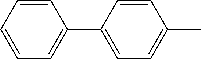 |
| 210 | H | 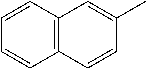 | H | H | H | 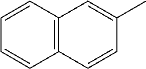 | H | H | — | — | 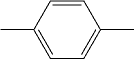 | 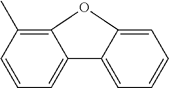 | 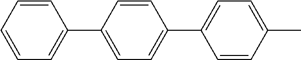 |
| 211 | H | 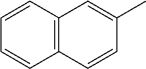 | H | H | H | 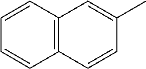 | H | H | — | — | 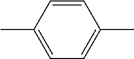 | 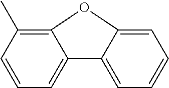 | 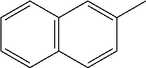 |

TABLE 22

| com- | | | | | | | | | | | | | |
|---|---|---|---|---|---|---|---|---|---|---|---|---|---|
| pound | R₂ | R₃ | R₄ | R₅ | R₇ | R₈ | R₉ | R₁₀ | L₁ | L₂ | L₃ | Ar₁ | Ar₂ |
| 212 | H | H | H | H | H | H | H | H | — | — | 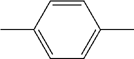 | 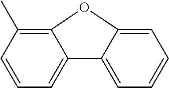 | 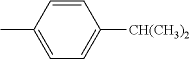 |
| 213 | H | H | H | H | H | H | H | H | — | — | 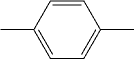 | 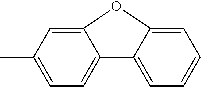 | 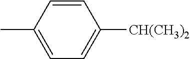 |
| 214 | H | H | H | H | H | H | H | H | — | — | 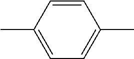 | 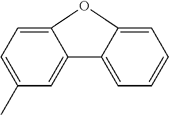 | 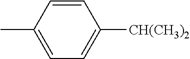 |
| 215 | H | H | H | H | H | H | H | H | — | — | 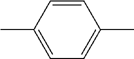 | 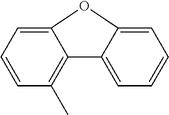 | 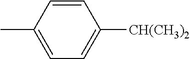 |
| 216 | H | H | H | H | H | H | H | H | — | — | 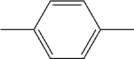 | 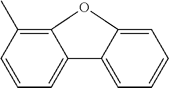 | 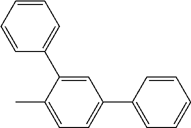 |
| 217 | H | H | H | H | H | H | H | H | — | — | 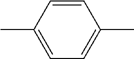 | 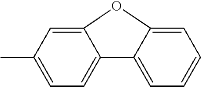 | 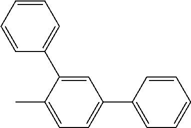 |
| 218 | H | H | H | H | H | H | H | H | — | — | 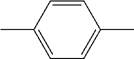 | 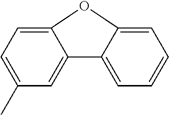 | 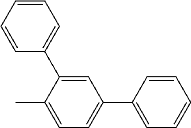 |
| 219 | H | H | H | H | H | H | H | H | — | — | 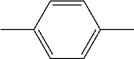 | 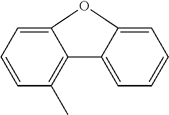 | 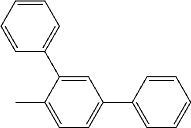 |

The specific examples of the aromatic amine derivative are the compounds having R₁ and R₆ in the same structure represented by the formula (2), however, not limited thereto. The aromatic amine derivative may be a compound having R₁ and R₆ in different structures.

### Organic-EL-Device Material

The aromatic amine derivative according to the exemplary embodiment is usable as an organic-EL-device material. The organic-EL-device material according to the exemplary embodiment may be composed solely of the aromatic amine derivative according to the above exemplary embodiment, or alternatively, may contain another compound(s) in addition to the aromatic amine derivative according to the above exemplary embodiment. The organic-EL-device material containing the aromatic amine derivative according to the exemplary embodiment is exemplarily usable as a dopant material.

The organic-EL-device material containing the aromatic amine derivative according to the exemplary embodiment and another compound is exemplified by an organic-EL-device material containing the aromatic amine derivative according to the exemplary embodiment and an anthracene derivative represented by the formula (20).

Moreover, an organic-EL-device material containing the aromatic amine derivative according to the exemplary embodiment and a pyrene derivative represented by the following formula (30) in place of the anthracene derivative is usable as the organic-EL-device material according to the exemplary embodiment.

Furthermore, an organic-EL-device material containing the aromatic amine derivative according to the exemplary embodiment, the anthracene derivative represented by the formula (20) and the pyrene derivative represented by the following formula (30) is usable as the organic-EL-device material according to the exemplary embodiment.

### Organic EL Device

The organic EL device according to this exemplary embodiment includes an organic compound layer between a cathode and an anode.

The aromatic amine derivative according to the exemplary embodiment is contained in the organic compound layer. The organic compound layer is formed using the organic-EL-device material containing the aromatic amine derivative according to the exemplary embodiment.

The organic compound layer has at least one layer of an organic thin-film layer formed of an organic compound. At least one layer of the organic thin-film layer(s) contains the aromatic amine derivative according to the exemplary embodiment singularly or as a component of a mixture. The organic thin-film layer may contain an inorganic compound.

At least one layer of the organic thin-film layer is an emitting layer. Accordingly, the organic compound layer may be provided by a single emitting layer. Alternatively, the organic compound layer may be provided by layers applied in a known organic EL device such as a hole injecting layer, a hole transporting layer, an electron injecting layer, an electron transporting layer, a hole blocking layer and an electron blocking layer. When the organic thin-film layer is provided by plural layers, the aromatic amine derivative according to the exemplary embodiment is contained singularly or as a component of a mixture in at least one of the layers.

The emitting layer preferably contains the aromatic amine derivative according to the exemplary embodiment. In this arrangement, the emitting layer may be formed of the aromatic amine derivative alone. Alternatively, the emitting layer may contain the aromatic amine derivative as a host material or a dopant material.

Representative arrangement examples of the organic EL device are as follows:

(a) anode/emitting layer/cathode;

(b) anode/hole injecting•transporting layer/emitting layer/cathode;

(c) anode/emitting layer/electron injecting•transporting layer/cathode;

(d) anode/hole injecting•transporting layer/emitting layer/electron injecting•transporting layer/cathode; and

(e) anode/hole injecting•transporting layer/emitting layer/blocking layer/electron injecting•transporting layer/cathode.

While the arrangement (d) is preferably used among the above arrangements, the arrangement of the invention is not limited to the above arrangements.

It should be noted that the aforementioned “emitting layer” is an organic layer having an emission function and, when a doping system is applied, including a host material and a dopant material. Herein, the host material has a function of mainly promoting recombination of electrons and holes and trapping excitons in the emitting layer while the dopant material has a function of making the excitons obtained in the recombination efficiently emit.

The “hole injecting/transporting layer” (or hole injecting•transporting layer) means “at least one of a hole injecting layer and a hole transporting layer” while the “electron injecting/transporting layer” (or electron injecting•transporting layer) means “at least one of an electron injecting layer and an electron transporting layer.” Herein, when the hole injecting layer and the hole transporting layer are provided, the hole injecting layer is preferably adjacent to the anode. When the electron injecting layer and the electron transporting layer are provided, the electron injecting layer is preferably adjacent to the cathode. The hole injecting layer, the emitting layer and the electron injecting layer may respectively be formed in a layered structure having two or more layers. As for the hole injecting layer in such an arrangement, a layer that injects holes from the electrode is referred to as a hole injecting layer while a layer that receives the holes from the hole injecting layer and transports the holes to the emitting layer is referred to as a hole transporting layer. Similarly, as for the electron injecting layer, a layer that injects electrons from the electrode is referred to as an electron injecting layer while a layer that receives the electrons from the hole injecting layer and transports the electrons to the emitting layer is referred to as an electron transporting layer.

When the organic EL device is in a multi-layered structure of the organic thin-film layers, decrease in luminance intensity and lifetime caused by quenching effects can be prevented. If necessary, the luminescent material, doping material, hole injecting material and electron injecting material may be combined in use. The luminescence intensity and luminous efficiency are occasionally improved by the doping material.

Each of the organic thin-film layers is selected in use according to factors such as an energy level, heat resistance, and adhesiveness to the organic layer or metal electrode of the material.

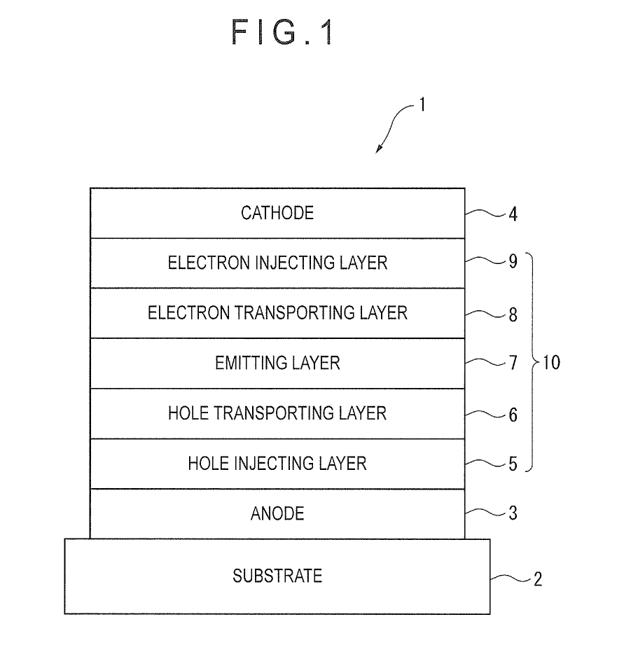

FIG. 1 schematically shows an exemplary arrangement of an organic EL device according to an exemplary embodiment of the invention.

An organic EL device 1 includes a transparent substrate 2, an anode 3, a cathode 4 and an organic compound layer 10 interposed between the anode 3 and the cathode 4.

The organic compound layer 10 sequentially includes a hole injecting layer 5, a hole transporting layer 6, an emitting layer 7, an electron transporting layer 8 and an electron injection layer 9 on the anode 3.

### Emitting Layer

The emitting layer of the organic EL device has a function for providing conditions for recombination of electrons and holes to emit light.

In the organic EL device according to the exemplary embodiment, at least one layer of the organic thin-film layers preferably includes the aromatic amine derivative according to the exemplary embodiment, and at least one of the anthracene derivative represented by the formula (20) and the pyrene derivative represented by the formula (30). In particular, the emitting layer preferably includes the aromatic amine derivative according to the exemplary embodiment as the dopant material and the anthracene derivative represented by the formula (20) as the host material.

### Anthracene Derivative

The anthracene derivative that may be included in the emitting layer as the host material is represented by the formula (20).

In the formula (20), Ar¹¹ and Ar¹² each independently represent a substituted or unsubstituted monocyclic group having 5 to 30 ring carbon atoms, a substituted or unsubstituted fused ring group having 10 to 30 ring atoms, or a group formed by combining the monocyclic group and the fused ring group.

The monocyclic group in the formula (20) is a group that is composed only of cyclic structures having no fused structure.

The monocyclic group has 5 to 30 ring atoms, preferably 5 to 20 ring atoms. Examples of the monocyclic group include: an aromatic group such as a phenyl group, biphenyl group, terphenyl group and quarter phenyl group; and a heterocyclic group such as a pyridyl group, pyrazyl group, pyrimidyl group, triazinyl group, furyl group and thienyl group. Among the above groups, a phenyl group, biphenyl group and terphenyl group are preferable.

The fused ring group in the formula (20) is a group that is formed by fusing two or more cyclic structures.

The fused ring group has 10 to 30 ring atoms, preferably 10 to 20 ring atoms. Examples of the fused ring group include: a fused aromatic cyclic group such as a naphthyl group, phenanthryl group, anthryl group, chrysenyl group, benzoanthryl group, benzophenanthryl group, triphenylenyl group, benzochrysenyl group, indenyl group, fluorenyl group, 9,9-dimethylfluorenyl group, benzofluorenyl group, dibenzofluorenyl group fluoranthenyl group, and benzofluoranthenyl group; and a fused heterocyclic group such as a benzofuranyl group, benzothiophenyl group, indolyl group, dibenzofuranyl group, dibenzothiophenyl group, carbazolyl group, quinolyl group and phenanthrolinyl group. Among the fused ring groups, a naphthyl group, phenanthryl group, anthryl group, 9,9-dimethylfluorenyl group, fluoranthenyl group, benzoanthryl group, dibenzothiophenyl group, dibenzofuranyl group and carbazolyl group are preferable.

The group formed by combining the monocyclic group and the fused ring group in the formula (20) is exemplified by a group formed by sequentially combining a phenyl group, naphthyl group and phenyl group to the anthracene ring (see the following compound EM50, etc.).

Examples of the alkyl group, silyl group, alkoxy group, aryloxy group, aralkyl group and halogen atom for R¹⁰¹ to R¹⁰⁸ in the formula (20) are the same as those for R₂, R₃, R₄, R₅, R₇, R₈, R₉ and R₁₀ in the formula (1-1) or (1-2). Examples of the cycloalkyl group are the same as the above examples. Moreover, examples of “substituted or unsubstituted” ones of the above groups are the same as those in the above description.

Preferable specific examples in the formula (20) will be shown below.

Preferable examples of the “substituted or unsubstituted” substituents for Ar¹¹, Ar¹² and R¹⁰¹ to R¹⁰⁸ in the formula (20) are a monocyclic group, fused ring group, alkyl group, cycloalkyl group, silyl group, alkoxy group, cyano group and halogen atom (particularly, fluorine). The monocyclic ring and the fused ring group are particularly preferable. Preferable specific examples of the substituents are the same as those of the groups in the formula (20) and those of the groups in the formula (1).

The anthracene derivative represented by the formula (20) is preferably one of the following anthracene derivatives (A), (B) and (C) and is selected according to an arrangement and a desired property of an organic EL device to which the anthracene derivative is applied.

### Anthracene Derivative (A)

An anthracene derivative (A) is an anthracene derivative of the formula (20) in which Ar¹¹ and Ar¹² are a substituted or unsubstituted fused ring group having 10 to 30 ring atoms. The anthracene derivative (A) is classified into an anthracene derivative in which Ar¹¹ and Ar¹² are substituted or unsubstituted fused ring groups the same as each other, and an anthracene derivative in which Ar¹¹ and Ar¹² are substituted or unsubstituted fused ring groups different from each other. The instance where Ar¹¹ and Ar¹² are different from each other also includes an instance where substitution positions of Ar¹¹ and Ar¹² are different from each other.

The anthracene derivative (A) is particularly preferably the anthracene derivative of the formula (20) in which Ar¹¹ and Ar¹² are substituted or unsubstituted fused ring groups different from each other.

In the anthracene derivative (A), preferable specific examples of the fused ring group for Ar¹¹ and Ar¹² in the formula (20) are the same as described above. Among the fused ring groups, a naphthyl group, phenanthryl group, benzoanthryl group, 9,9-dimethylfluorenyl group and dibenzofuranyl group are preferable.

### Anthracene Derivative (B)

The anthracene derivatives (B) is an anthracene derivative of the formula (20) in which one of Ar¹¹ and Ar¹² is a substituted or unsubstituted monocyclic group having 5 to 30 ring atoms and the other of Ar¹¹ and Ar¹² is a substituted or unsubstituted fused ring group having 10 to 30 ring atoms.

The anthracene derivative (B) is preferably exemplified by an anthracene derivative in which Ar¹² is selected from a naphthyl group, phenanthryl group, benzoanthryl group, 9,9-dimethylfluorenyl group and dibenzofuranyl group, and Ar¹¹ is an unsubstituted phenyl group or a phenyl group substituted by at least one of the monocyclic group and the fused ring group

In the anthracene derivative (B), preferable specific examples of the monocyclic group and the fused ring group are the same as described above.

Another preferable example of the anthracene derivative (B) is an anthracene derivative in which Ar¹² is a substituted or unsubstituted fused ring group having 10 to 30 ring atoms, and Ar¹¹ is an unsubstituted phenyl group. In this arrangement, a phenanthryl group, 9,9-dimethylfluorenyl group, dibenzofuranyl group and benzoanthryl group are particularly preferable as the fused ring groups.

### Anthracene Derivative (C)

An anthracene derivative (C) is an anthracene derivative of the formula (20) in which Ar¹¹ and Ar¹² each independently represent a substituted or unsubstituted monocyclic ring group having 5 to 30 ring atoms.

A preferable example of the anthracene derivative (C) is an anthracene derivative in which Ar¹¹ and Ar¹² are each independently a substituted or unsubstituted phenyl group.

The anthracene derivative (C) is more preferably an anthracene derivative in which Ar¹¹ is an unsubstituted phenyl group and Ar¹² is a phenyl group having at least one of the monocyclic group and the fused ring group as a substituent, and anthracene derivative in which Ar¹¹ and Ar¹² are each independently a phenyl group having at least one of the monocyclic group and the fused ring group as a substituent.

Preferable specific examples of the monocyclic group and the fused ring group as a substituent for Ar¹¹ and Ar¹² in the formula (20) are the same as described above. The monocyclic group as the substituent is more preferably a phenyl group and a biphenyl group. The fused ring group as the substituent is more preferably a naphthyl group, phenanthryl group, 9,9-dimethylfluorenyl group, dibenzofuranyl group and benzoanthryl group.

Examples of the anthracene derivative represented by the formula (20) are as follows. However, the invention is not limited to the anthracene derivatives having these structures.

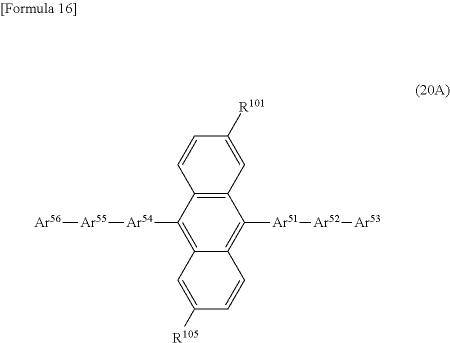

In the formula (20A), R¹⁰¹ and R¹⁰⁵ are each independently a hydrogen atom, halogen atom, cyano group, substituted or unsubstituted monocyclic group having 5 to 30 ring atoms, substituted or unsubstituted fused ring group having 10 to 30 ring atoms, a group provided by combining the monocyclic group and the fused ring group, substituted or unsubstituted alkyl group having 1 to 30 carbon atoms, substituted or unsubstituted cycloalkyl group having 3 to 30 ring carbon atoms, substituted or unsubstituted alkoxy group having 1 to 30 carbon atoms, substituted or unsubstituted aralkyl group having 7 to 30 carbon atoms, substituted or unsubstituted aryloxy having 6 to 30 ring carbon atoms, or substituted or unsubstituted silyl group.

In the formula (20A), Ar⁵¹ and Ar⁵⁴ are each independently a substituted or unsubstituted divalent monocyclic residue having 5 to 30 ring atoms, or a substituted or unsubstituted divalent fused ring residue having 10 to 30 ring atoms.

In the formula (20A), Ar⁵² and Ar⁵⁵ are each independently a single bond, a substituted or unsubstituted divalent monocyclic residue having 5 to 30 ring atoms, or a substituted or unsubstituted divalent fused ring residue having 10 to 30 ring atoms.

In the formula (20A), Ar⁵³ and Ar⁵⁶ are each independently a hydrogen atom, a substituted or unsubstituted monocyclic group having 5 to 30 ring atoms, or a substituted or unsubstituted fused ring having 10 to 30 ring atoms.

All or a part of hydrogen atoms in the formula (20A) may be a deuterium atom.

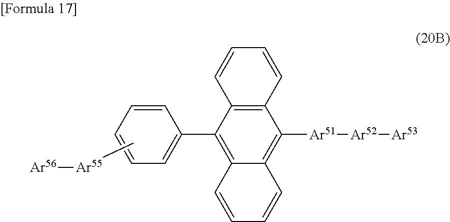

In the formula (20B), Ar⁵¹ is a substituted or unsubstituted divalent monocyclic residue having 5 to 30 ring atoms, or a substituted or unsubstituted divalent fused ring residue having 10 to 30 ring atoms.

In the formula (20B), Ar⁵² and Ar⁵⁵ are each independently a single bond, a substituted or unsubstituted divalent monocyclic residue having 5 to 30 ring atoms, or a substituted or unsubstituted divalent fused ring residue having 10 to 30 ring atoms.

In the formula (20B), Ar⁵³ and Ar⁵⁶ are each independently a hydrogen atom, a substituted or unsubstituted monocyclic group having 5 to 30 ring atoms, or a substituted or unsubstituted fused ring having 10 to 30 ring atoms.

All or a part of hydrogen atoms in the formula (20B) may be a deuterium atom.

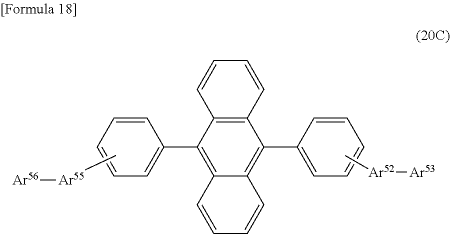

In the formula (20C), Ar⁵² is a substituted or unsubstituted divalent monocyclic residue having 5 to 30 ring atoms, or a substituted or unsubstituted divalent fused ring residue having 10 to 30 ring atoms.

In the formula (20C), Ar⁵⁵ is a single bond, a substituted or unsubstituted divalent monocyclic residue having 5 to 30 ring atoms, or a substituted or unsubstituted divalent fused ring residue having 10 to 30 ring atoms.

In the formula (20C), Ar⁵³ and Ar⁵⁶ are each independently a hydrogen atom, a substituted or unsubstituted monocyclic group having 5 to 30 ring atoms, or a substituted or unsubstituted fused ring having 10 to 30 ring atoms.

All or a part of hydrogen atoms in the formula (20C) may be a deuterium atom.

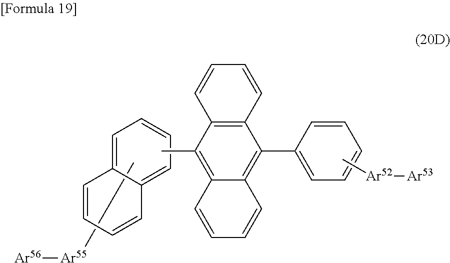

In the formula (20D), Ar⁵² is a substituted or unsubstituted divalent monocyclic residue having 5 to 30 ring atoms, or a substituted or unsubstituted divalent fused ring residue having 10 to 30 ring atoms.

In the formula (20D), Ar⁵⁵ is a single bond, a substituted or unsubstituted divalent monocyclic residue having 5 to 30 ring atoms, or a substituted or unsubstituted divalent fused ring residue having 10 to 30 ring atoms.

In the formula (20D), Ar⁵³ and Ar⁵⁶ are each independently a hydrogen atom, a substituted or unsubstituted monocyclic group having 5 to 30 ring atoms, or a substituted or unsubstituted fused ring having 10 to 30 ring atoms.

All or a part of hydrogen atoms in the formula (20D) may be a deuterium atom.

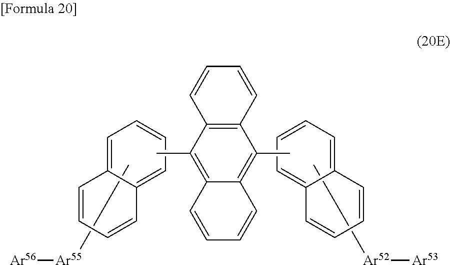

In the formula (20E), Ar⁵² and Ar⁵⁵ are each independently a single bond, a substituted or unsubstituted divalent monocyclic residue having 5 to 30 ring atoms, or a substituted or unsubstituted divalent fused ring residue having 10 to 30 ring atoms.

In the formula (20E), Ar⁵³ and Ar⁵⁶ are each independently a hydrogen atom, a substituted or unsubstituted monocyclic group having 5 to 30 ring atoms, or a substituted or unsubstituted fused ring having 10 to 30 ring atoms.

All or a part of hydrogen atoms in the formula (20E) may be a deuterium atom.

More specific examples of the anthracene derivative are as follows. However, the invention is not limited to the anthracene derivatives having these structures.

In EM36, EM44, EM77, EM85, EM86 and the like among the following specific structures of the anthracene derivatives, a line extending from a position 9 of a fluorene ring represents a methyl group. In other words, the fluorene ring is a 9,9-dimethylfluorene ring.

In compounds EM151, EM154, EM157, EM161, EM163, EM166, EM169, EM173 and the like among the following specific structures of the anthracene derivatives, a crossline extending outward from a cyclic structure represents a tertiary butyl group.

In compounds EM152, EM155, EM158, EM164, EM167, EM170, EM171, EM180, EM181, EM182, EM183, EM184, EM185 and the like among the following specific structures of the anthracene derivatives, a line extending from a silicon atom (Si) represents a methyl group. In other words, a substituent having the silicon atom is trimethylsilyl group.

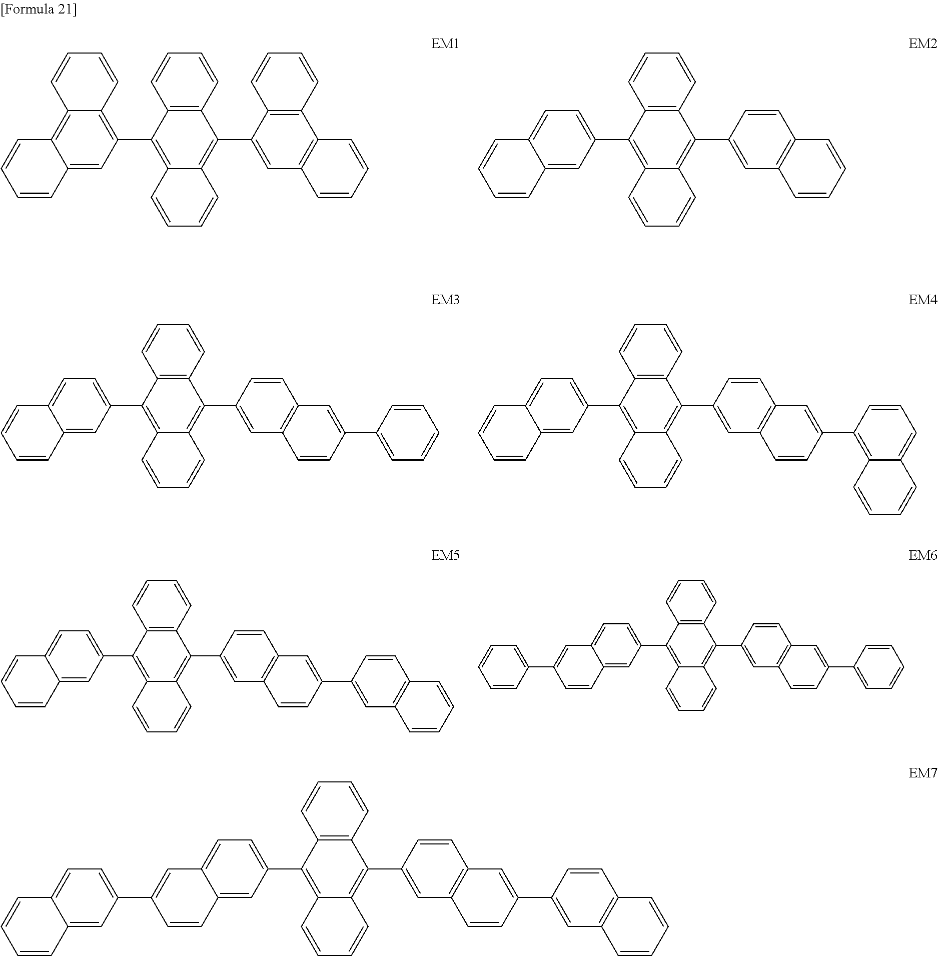

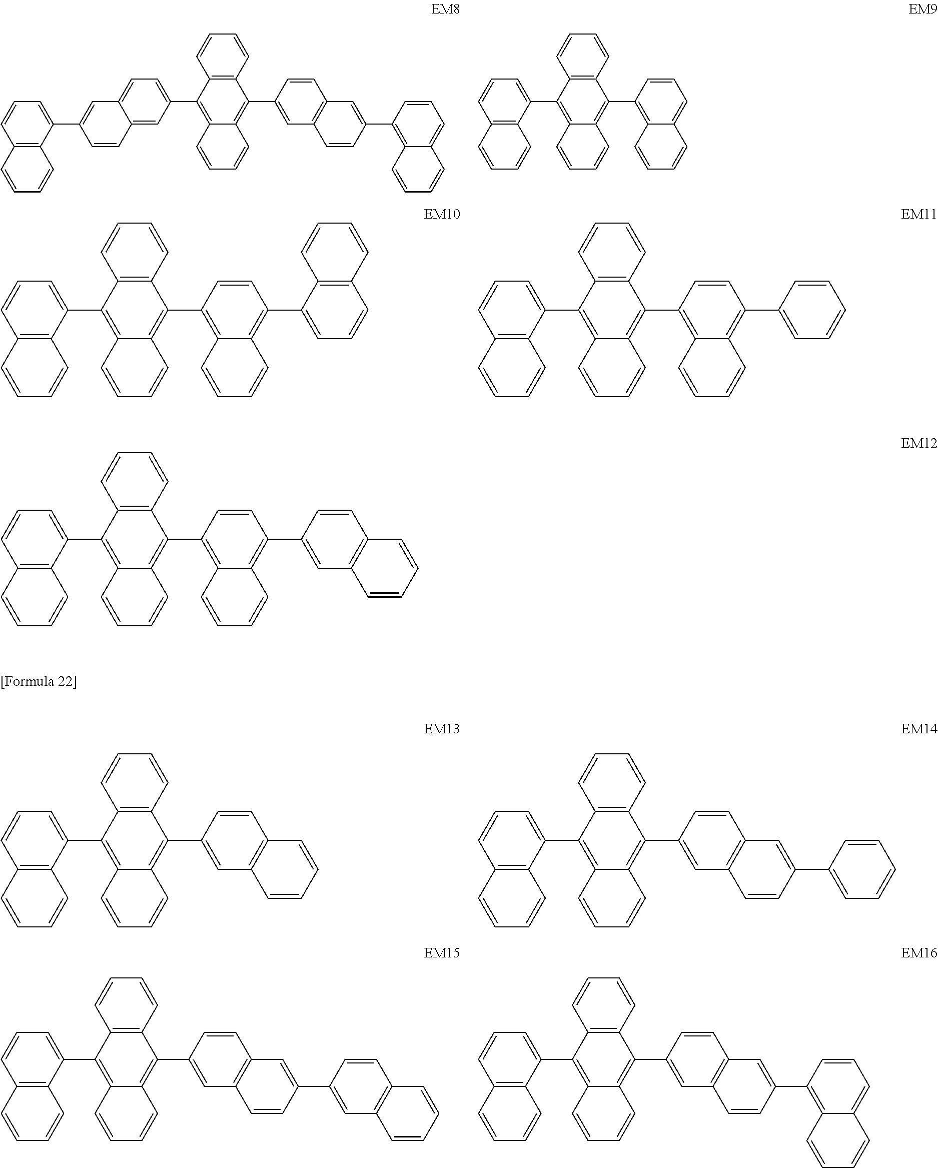

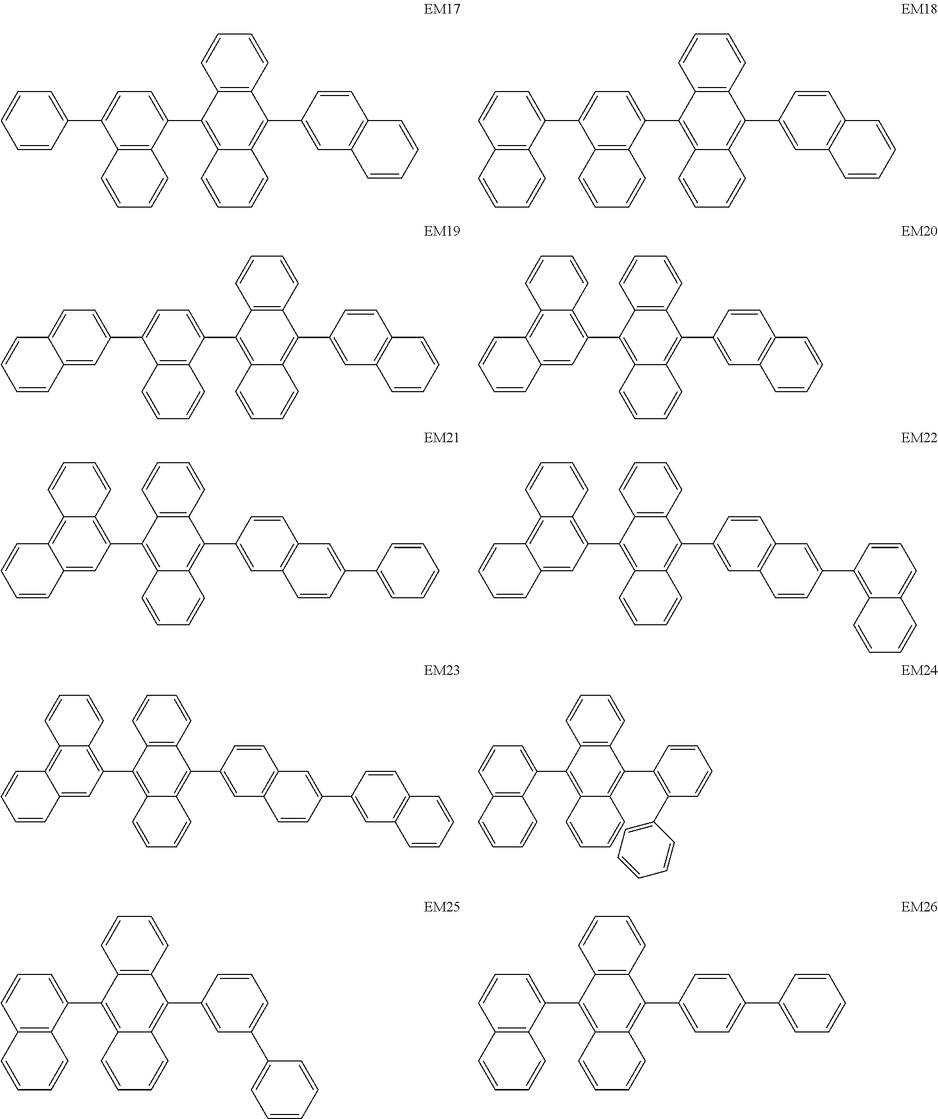

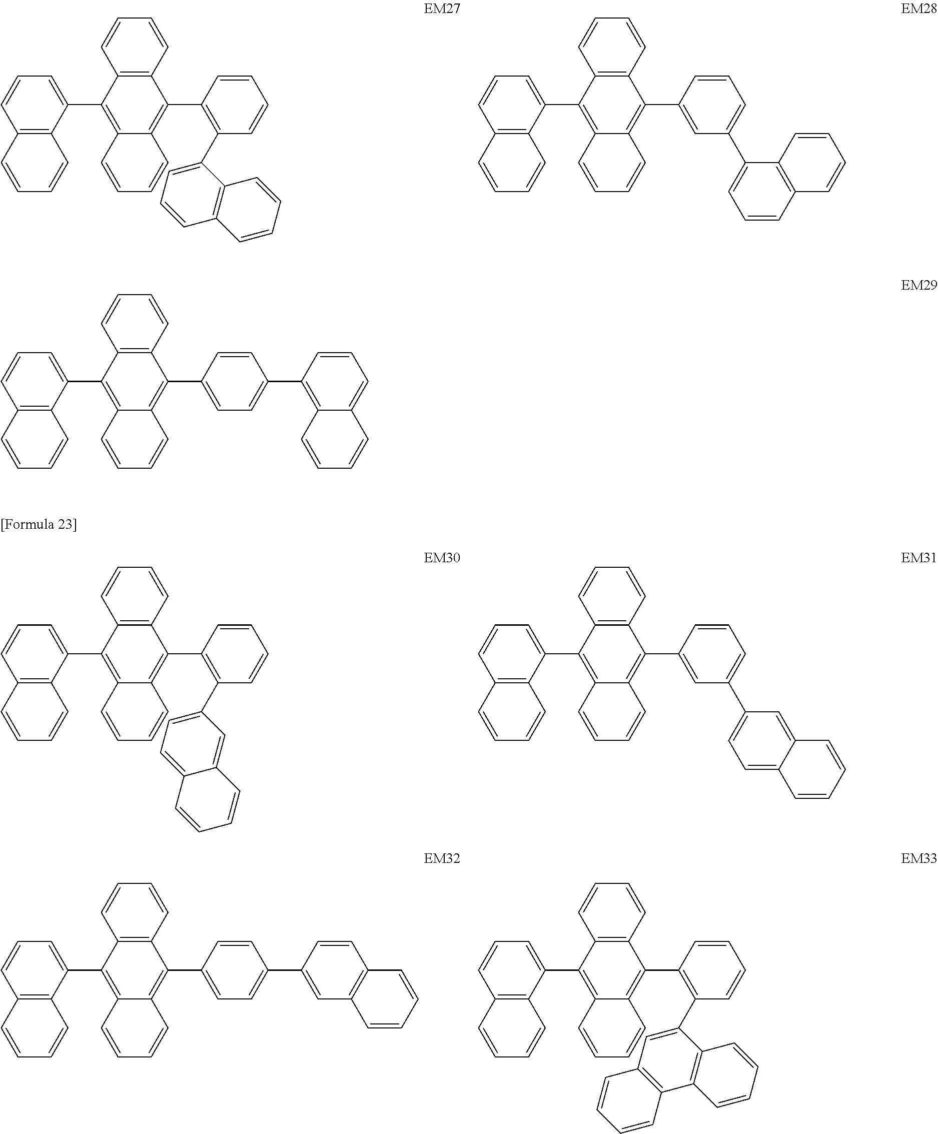

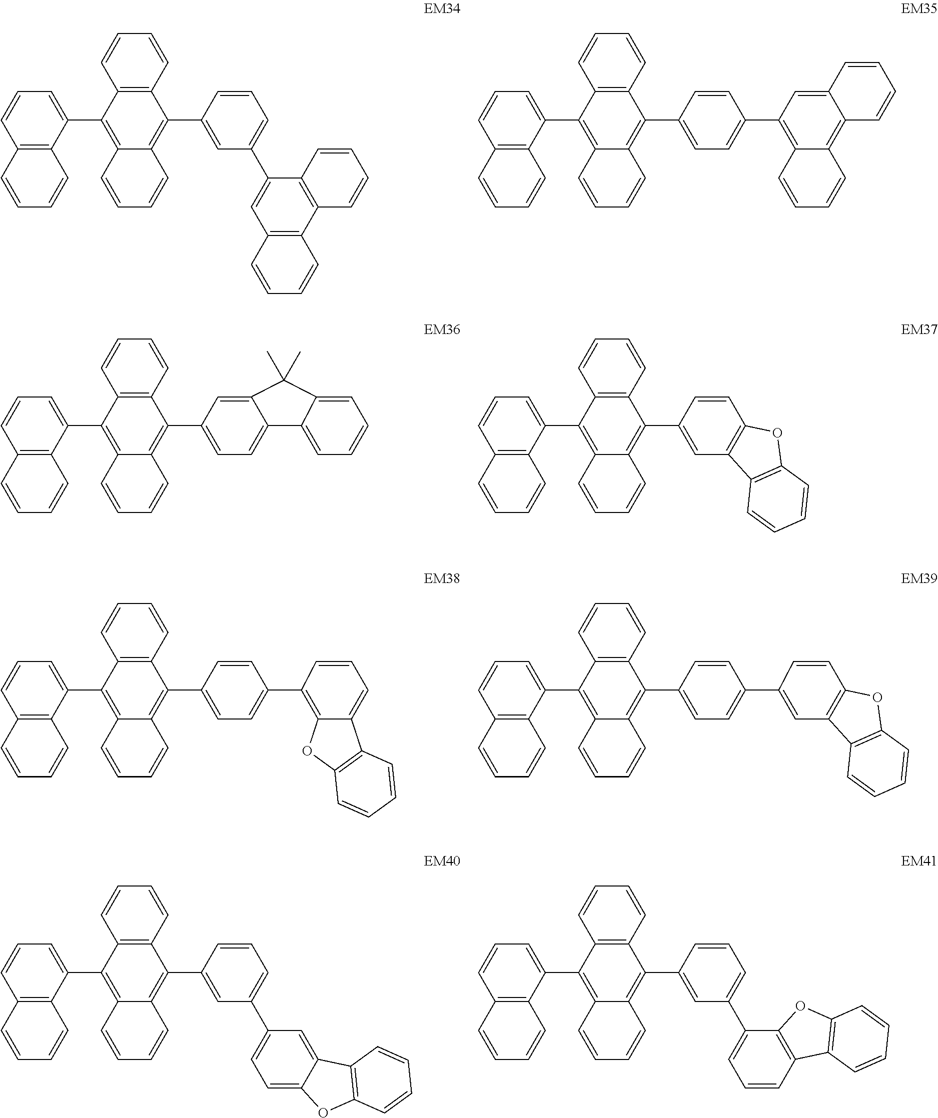

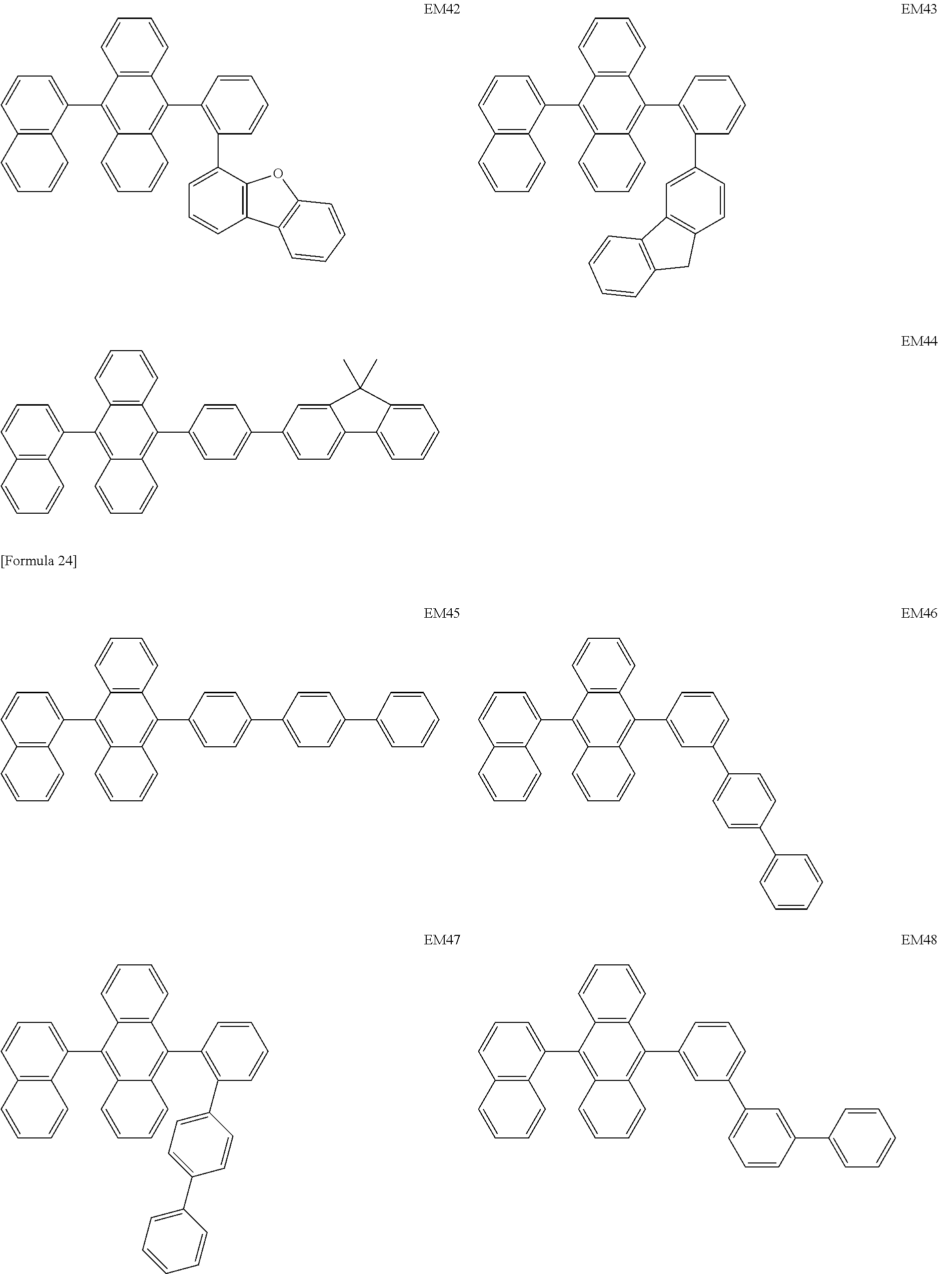

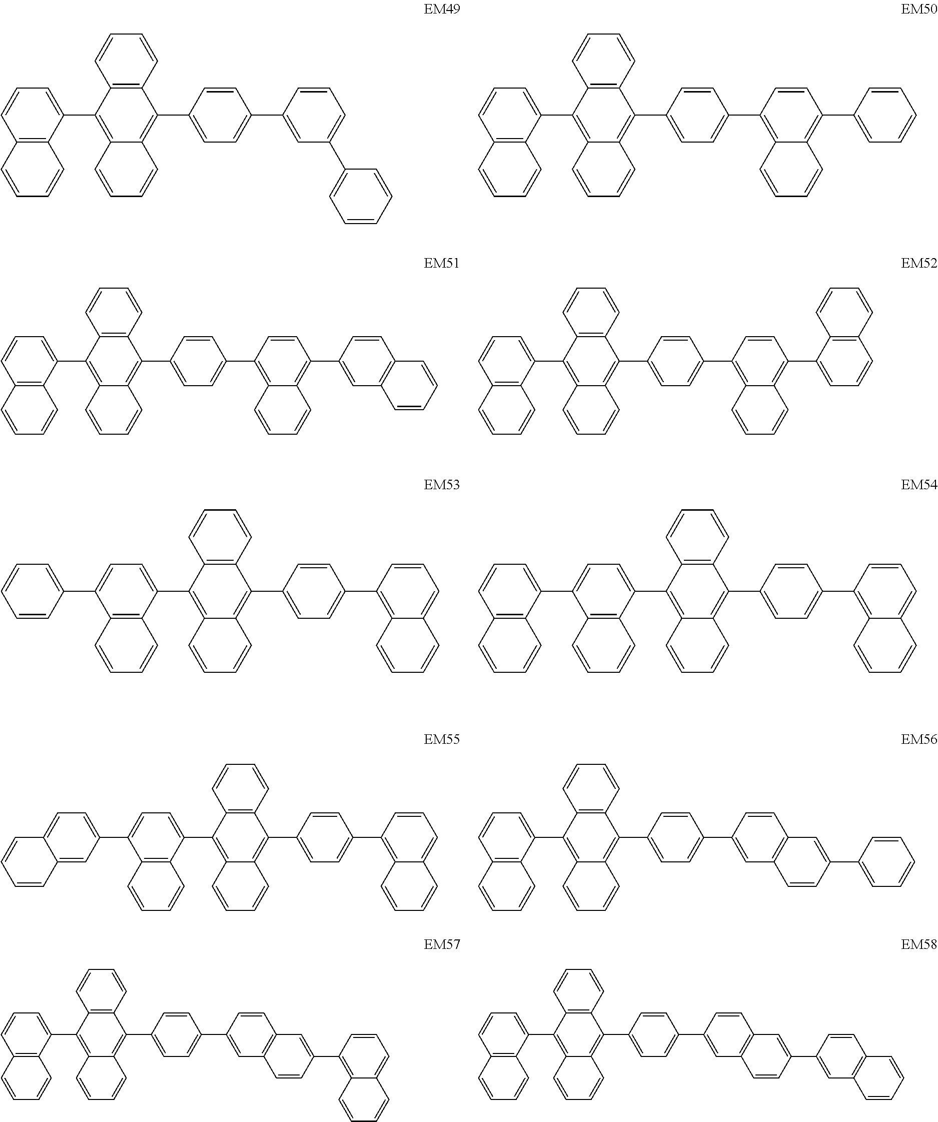

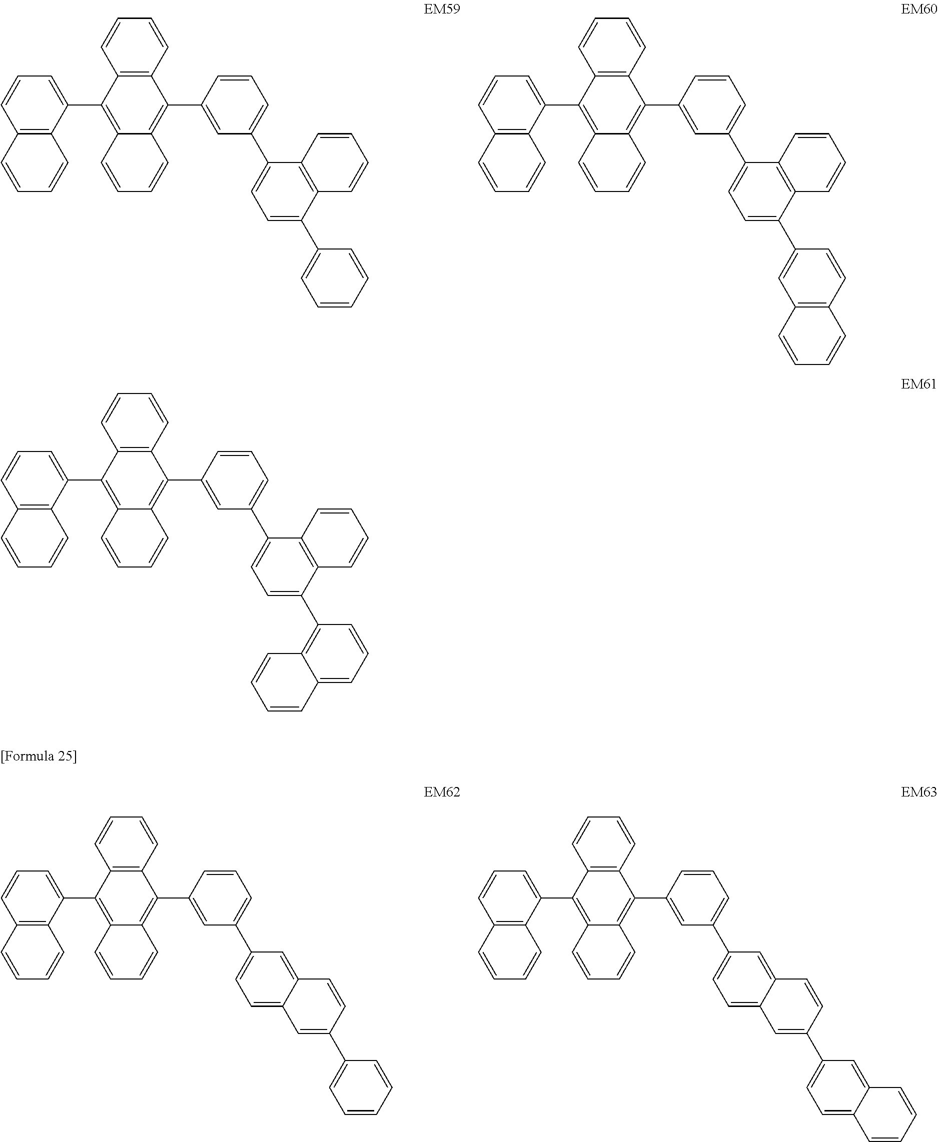

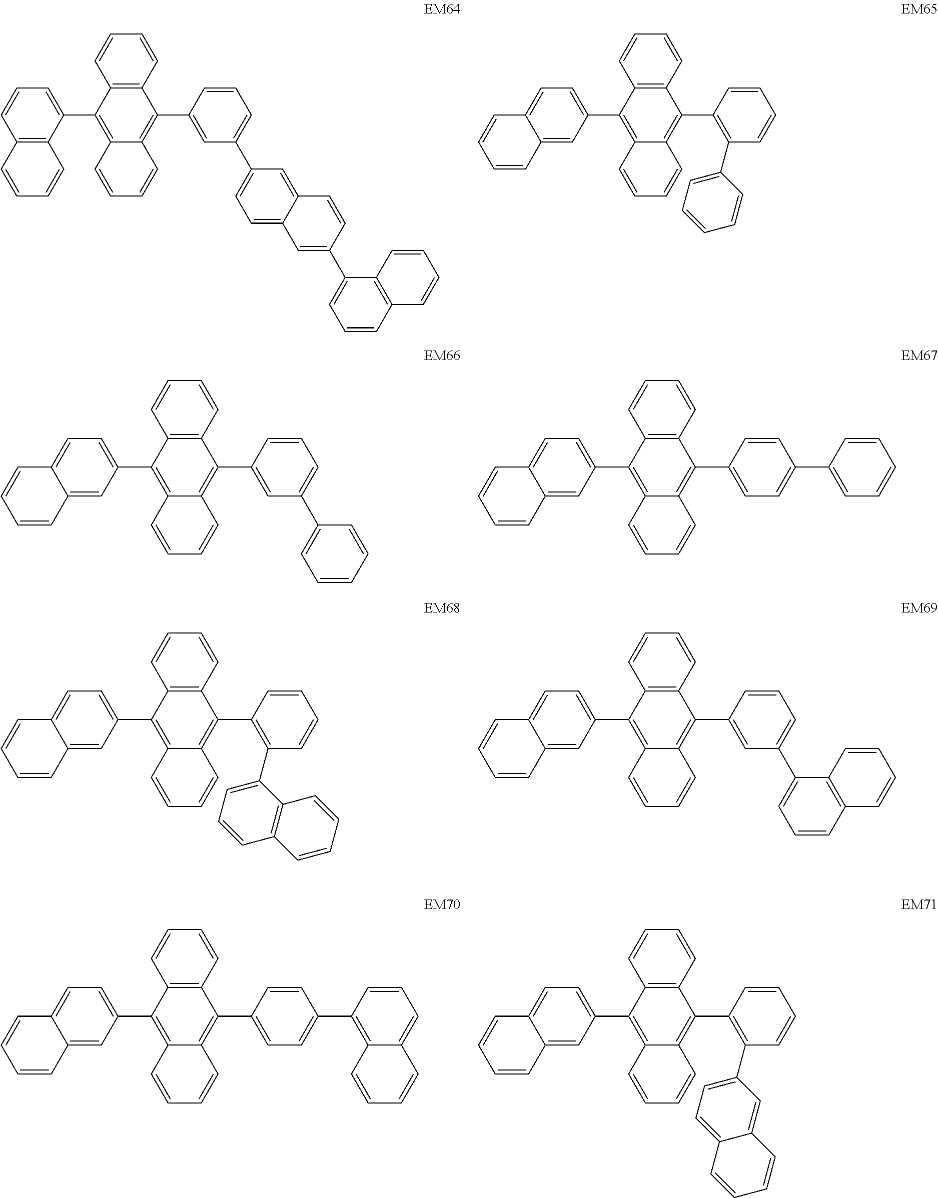

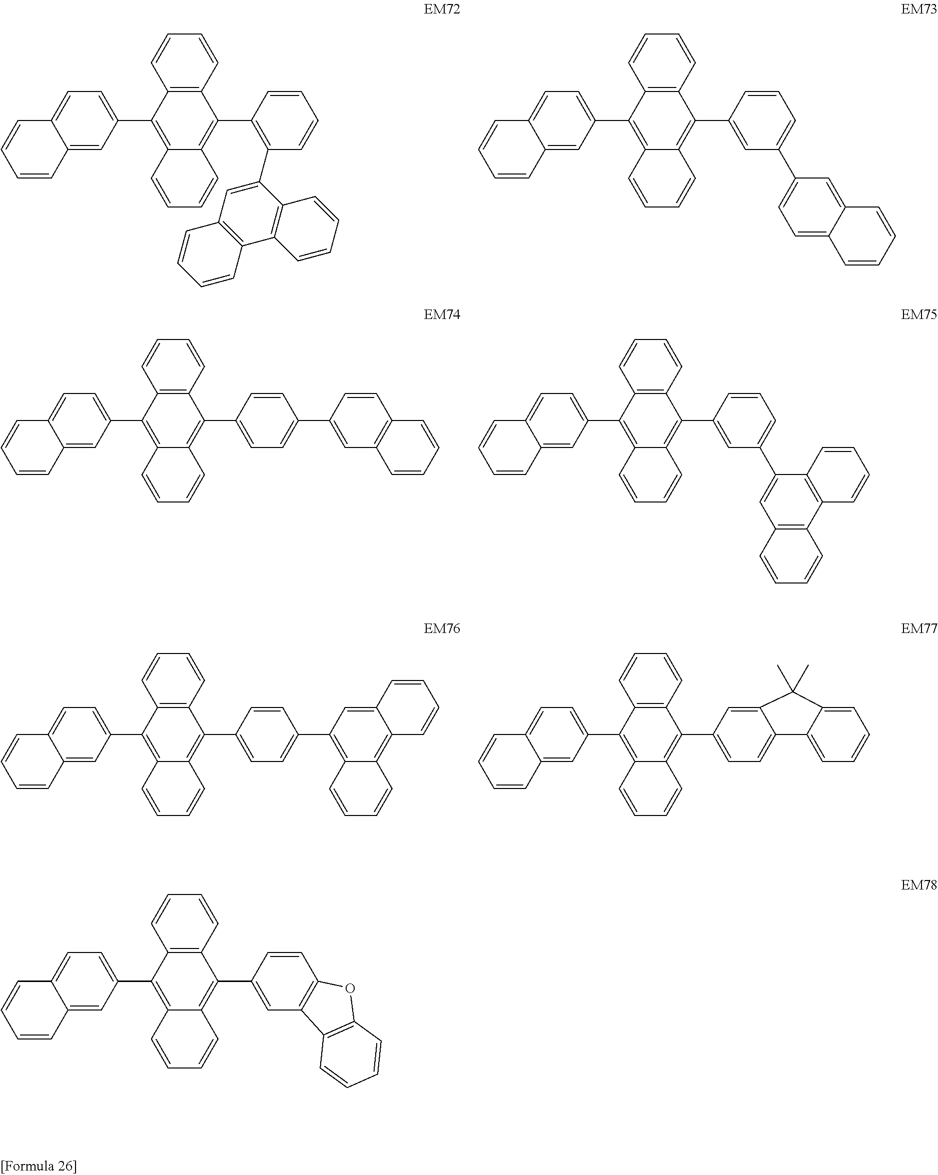

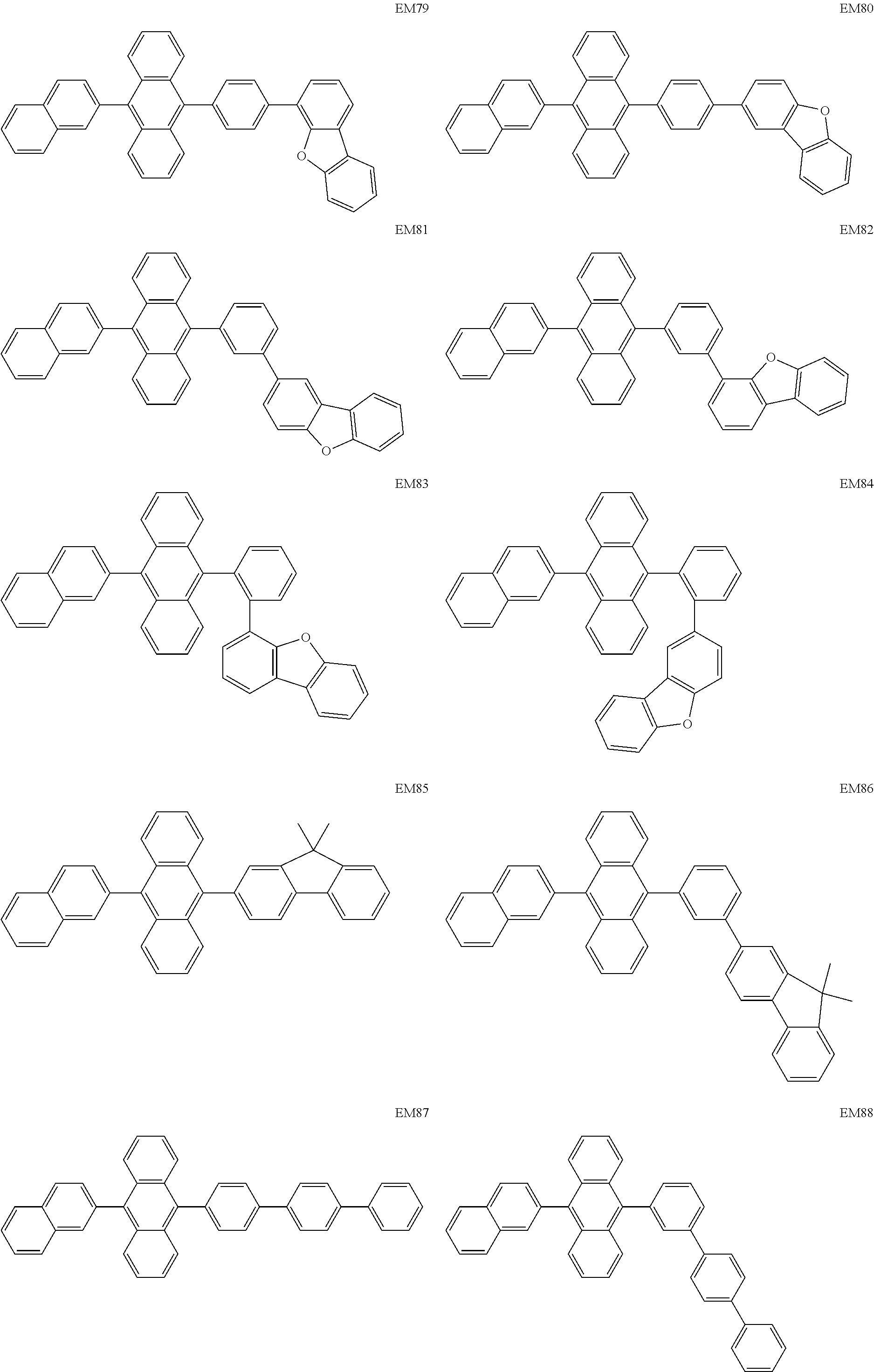

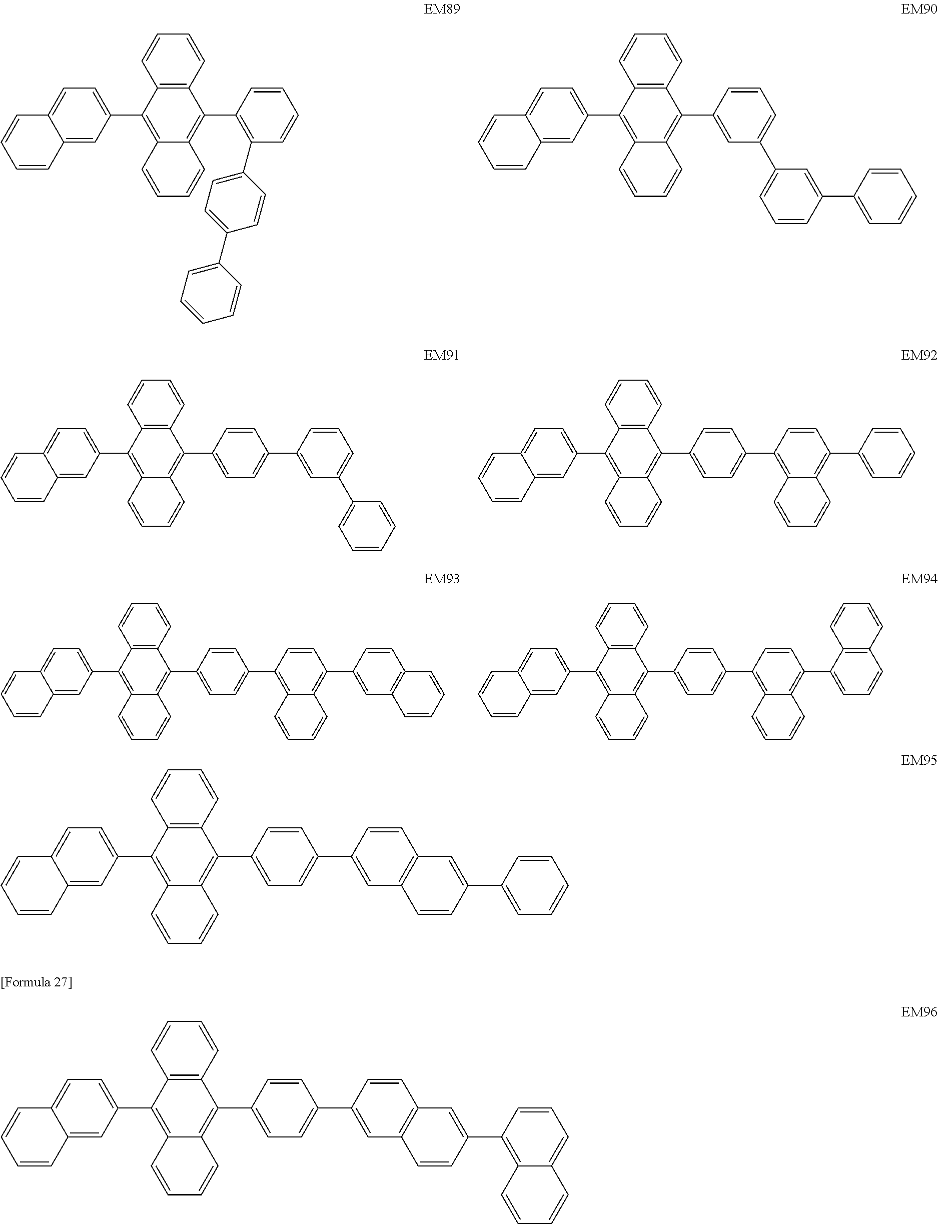

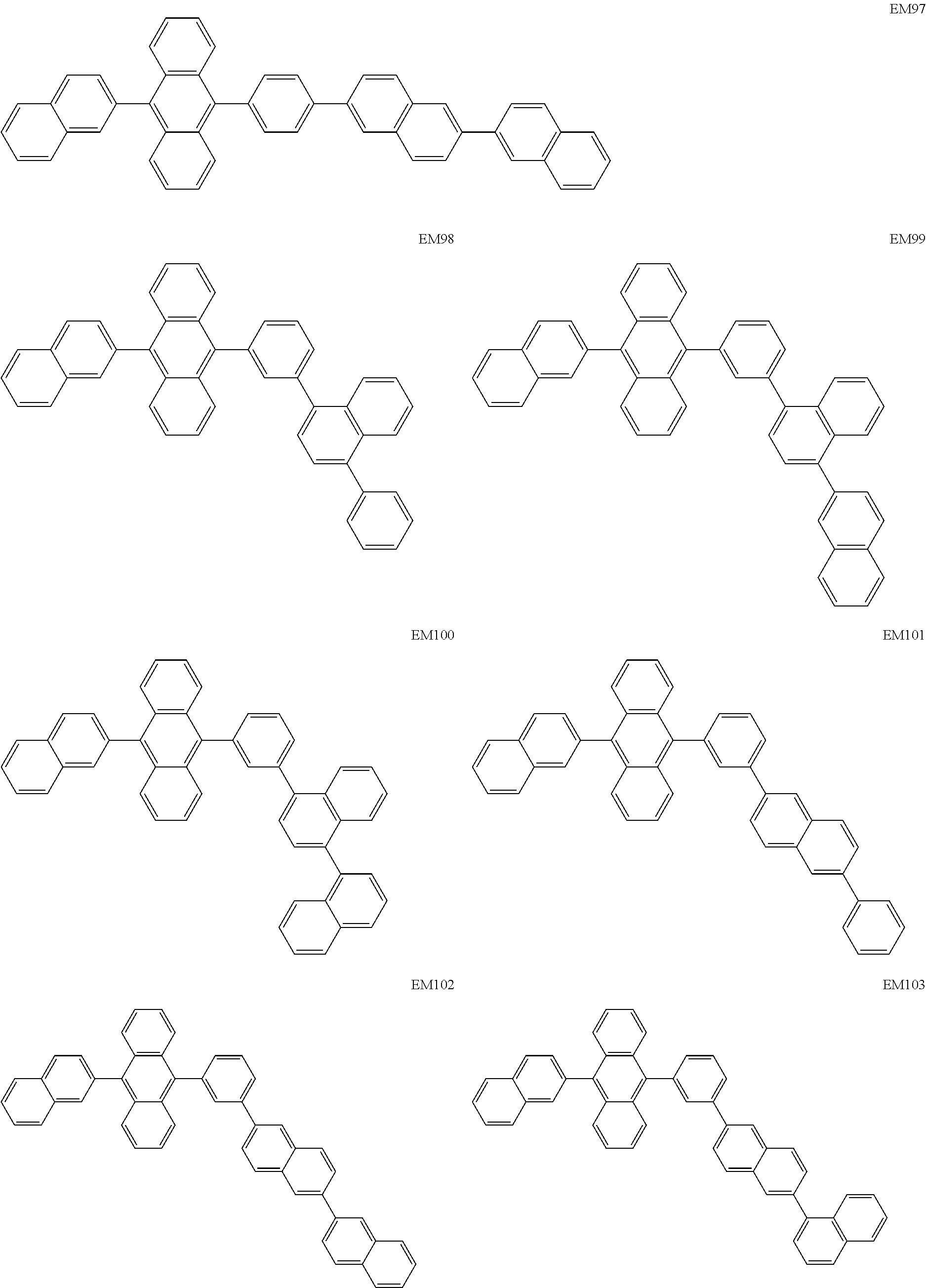

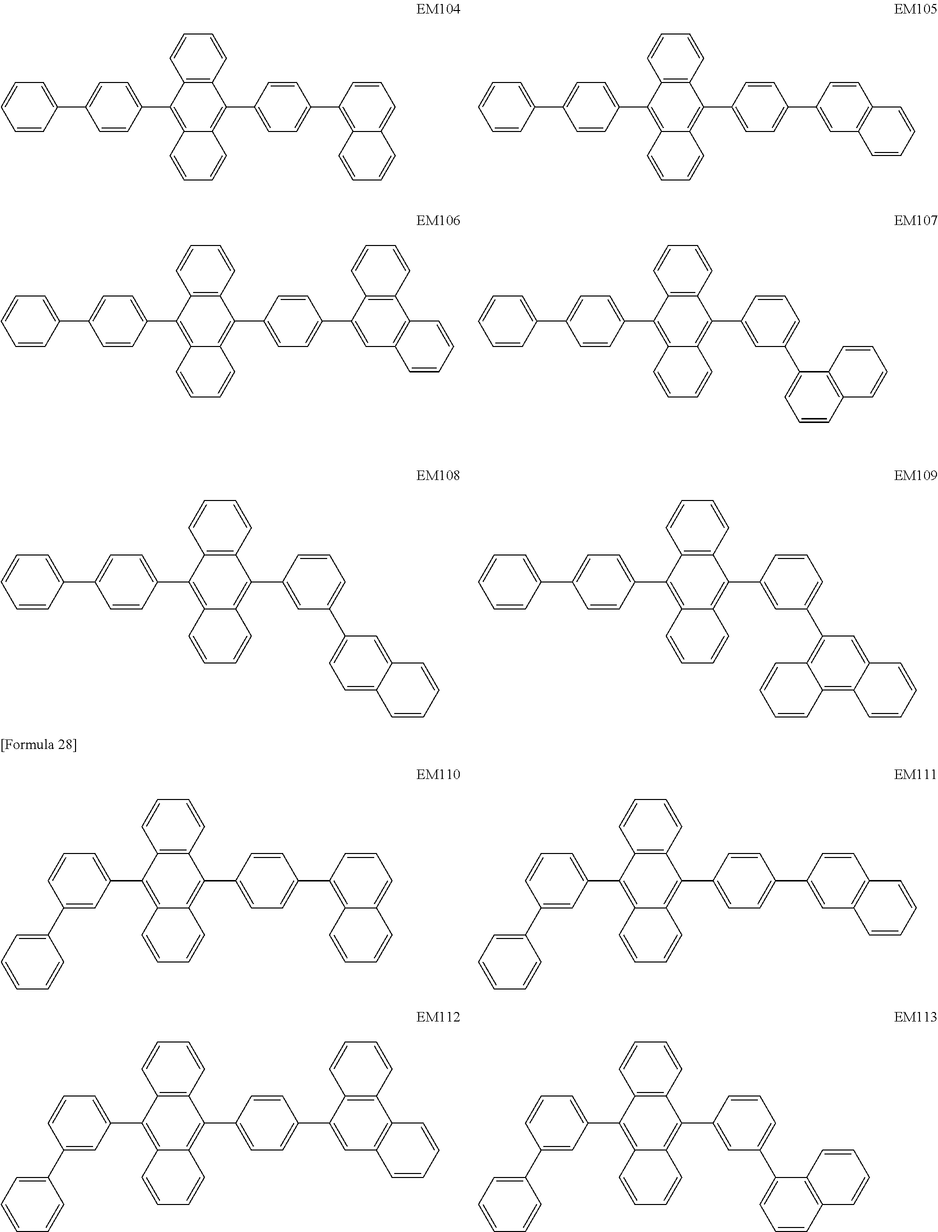

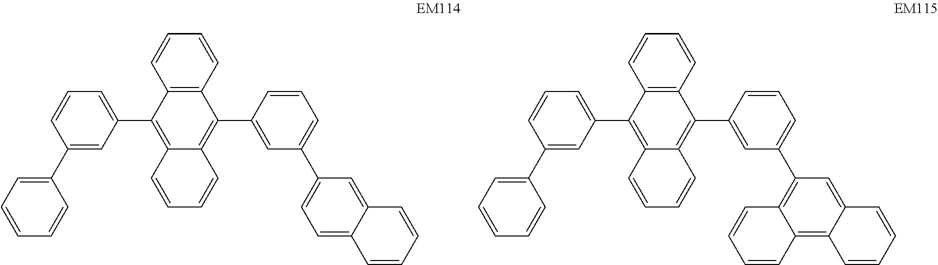

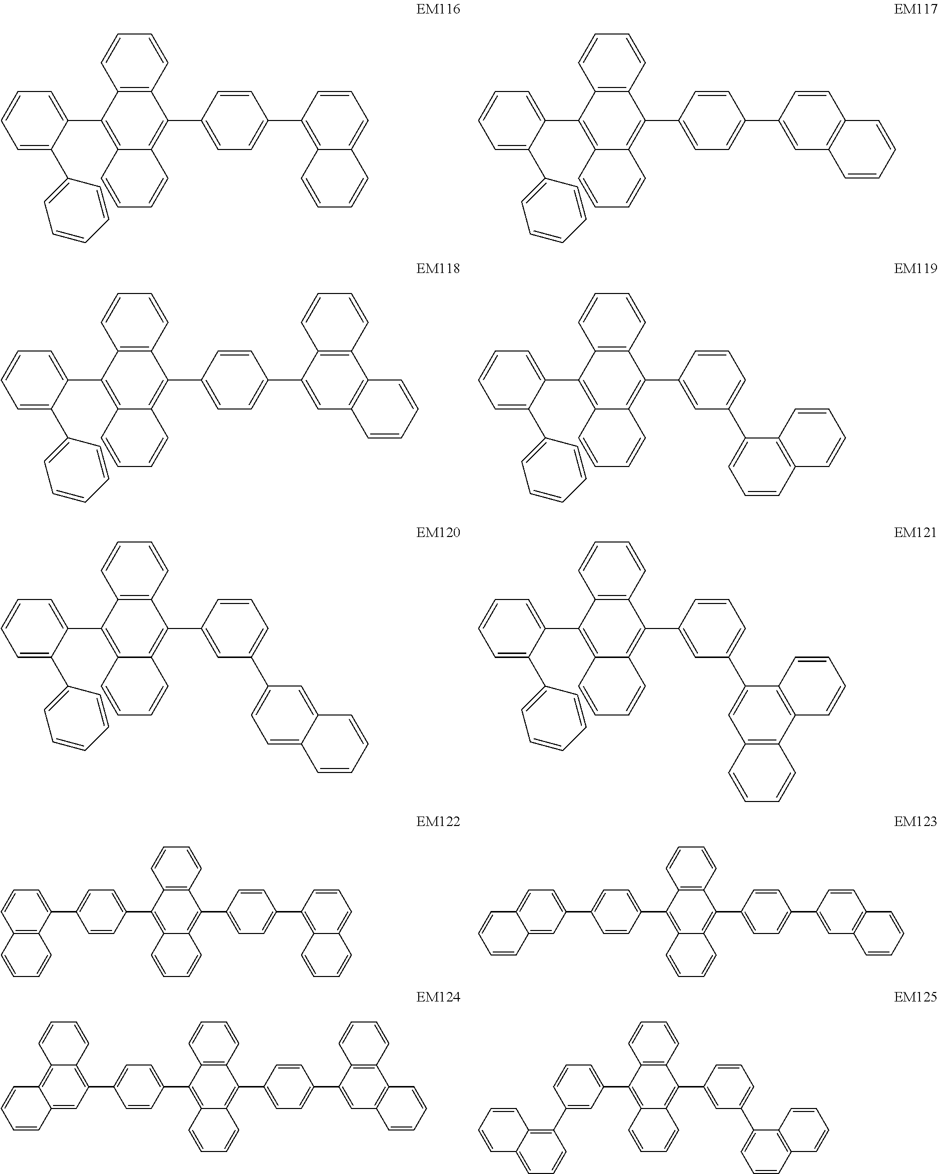

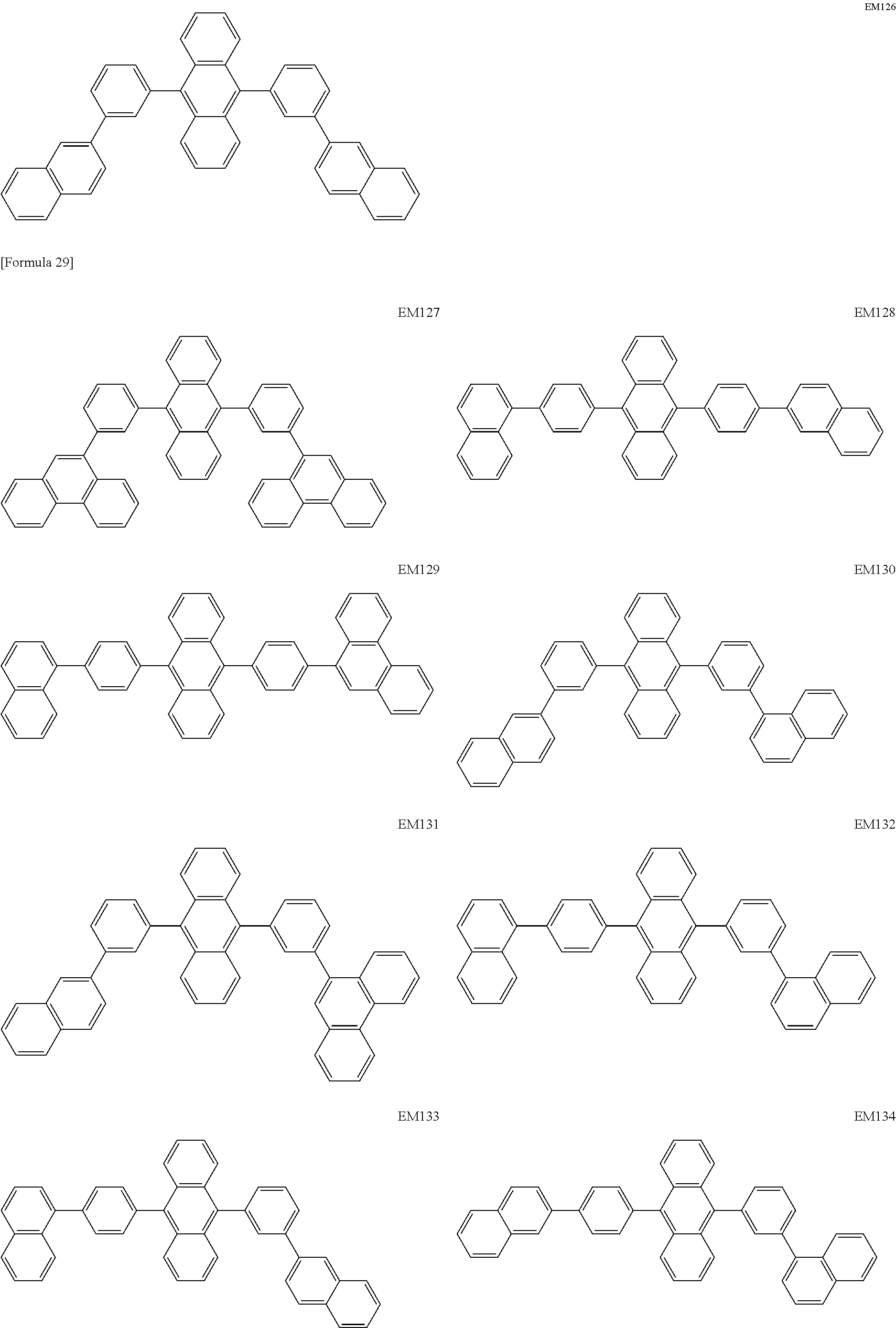

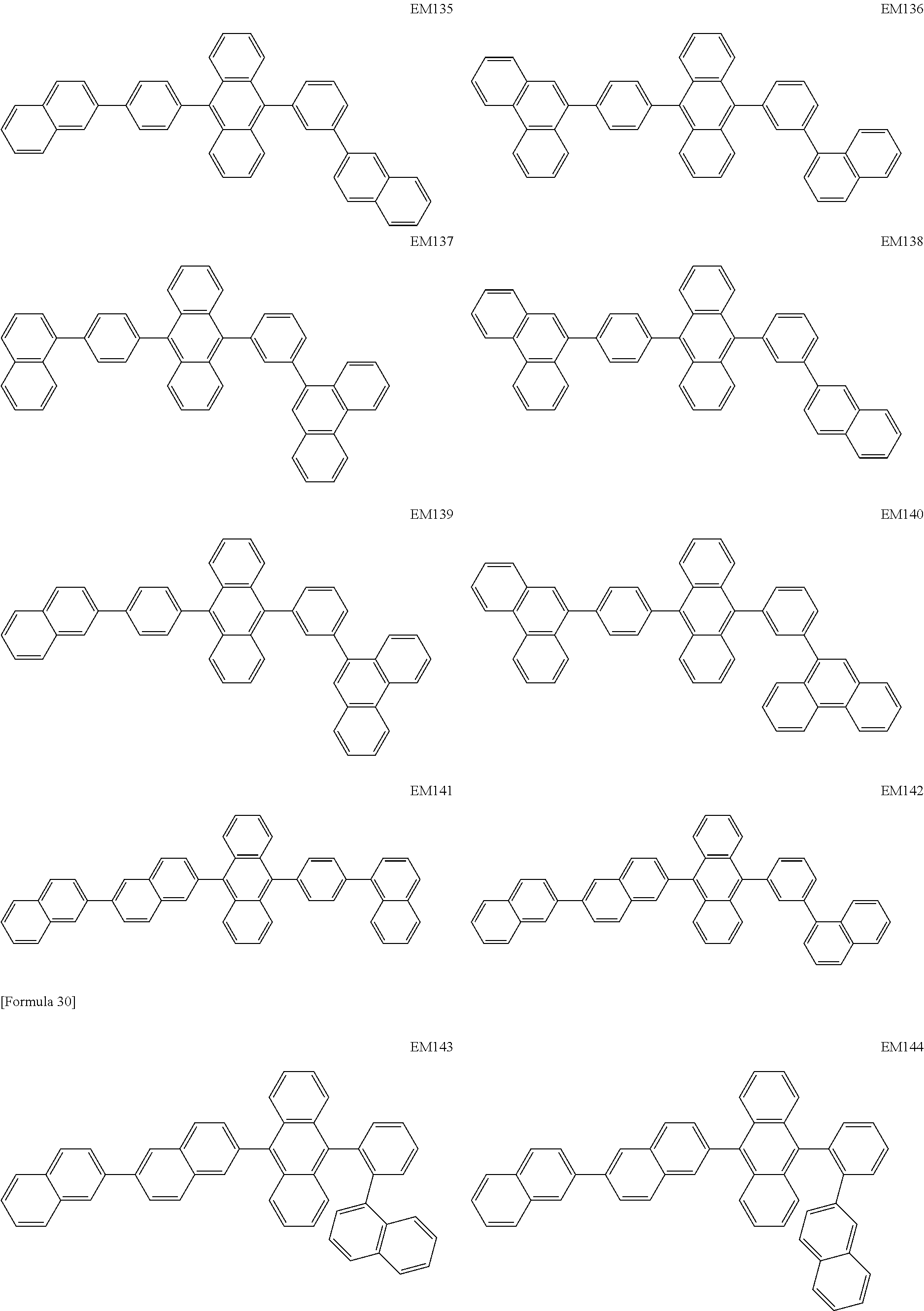

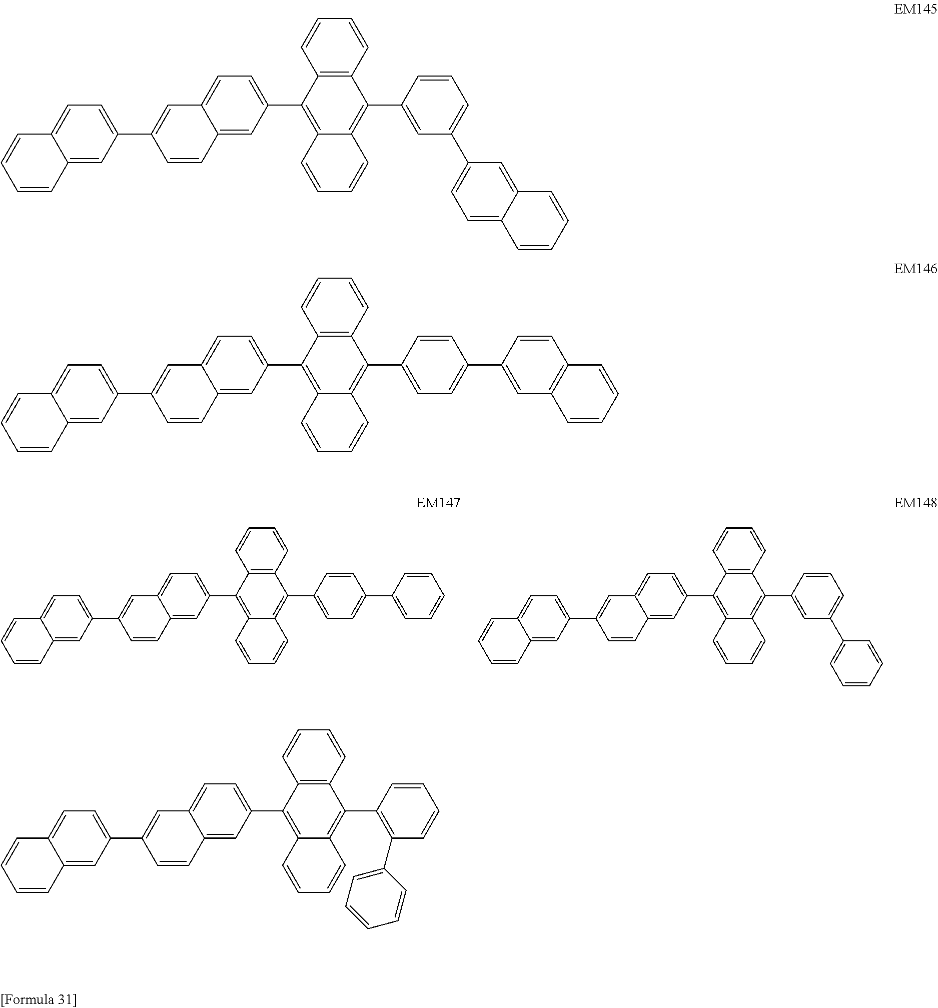

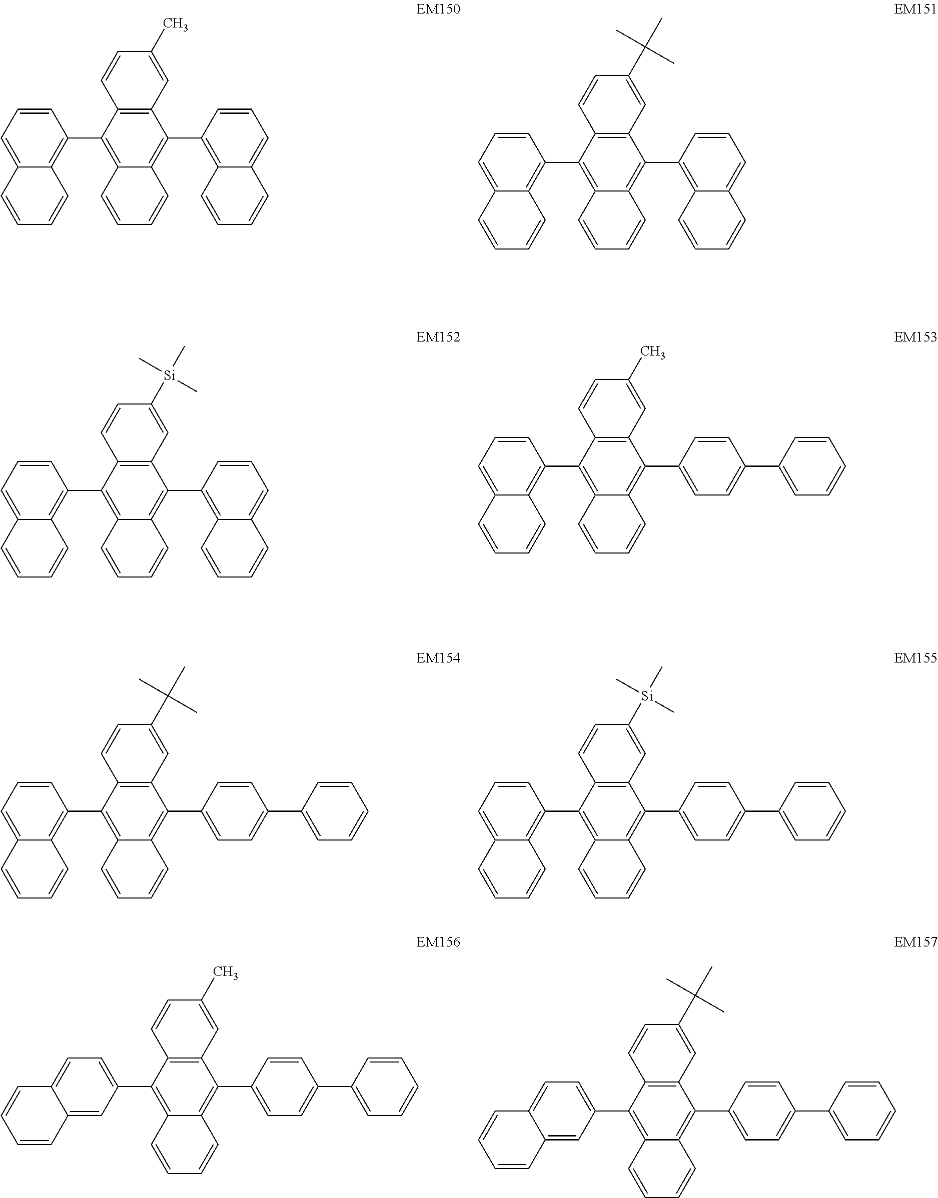

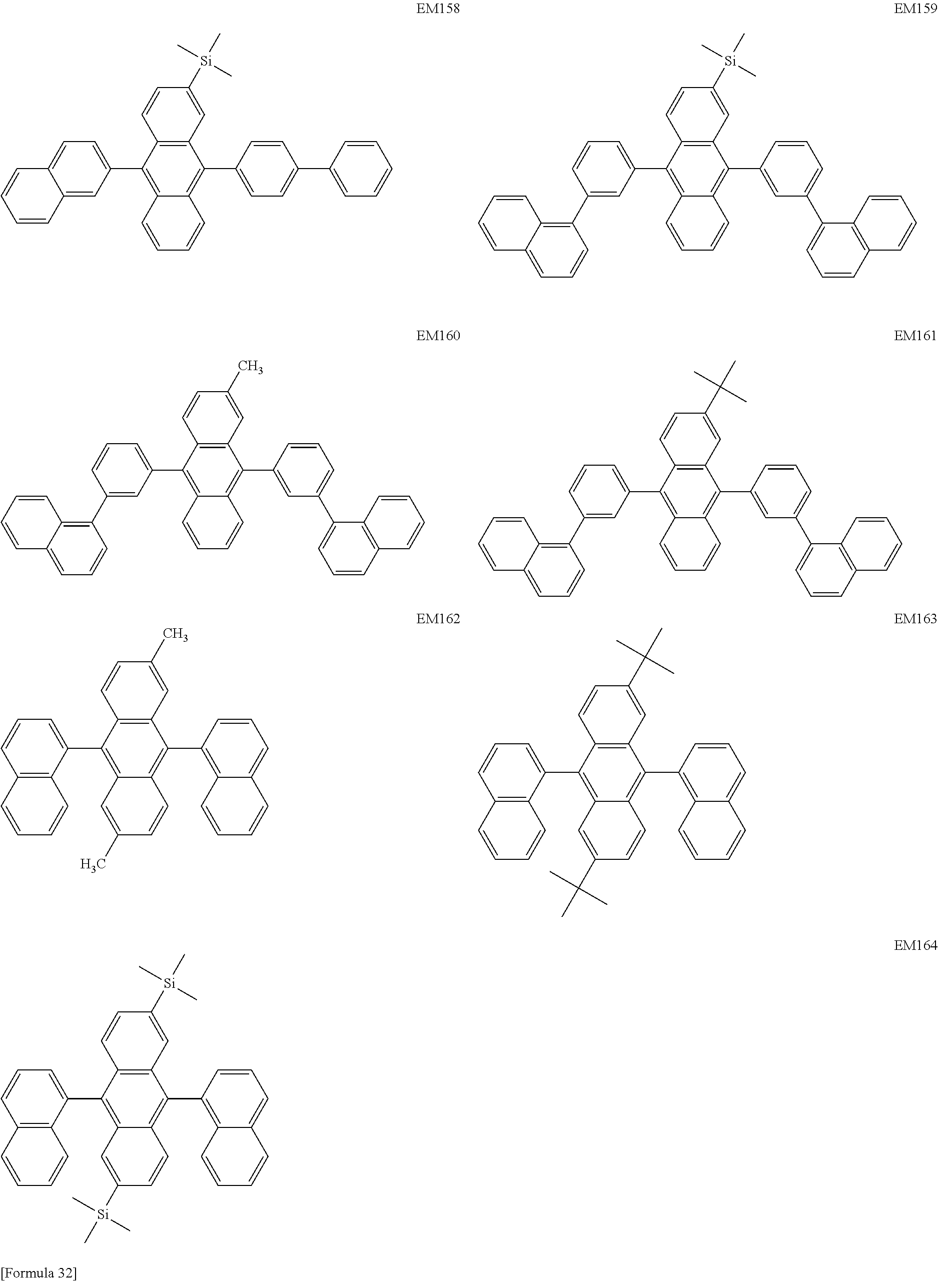

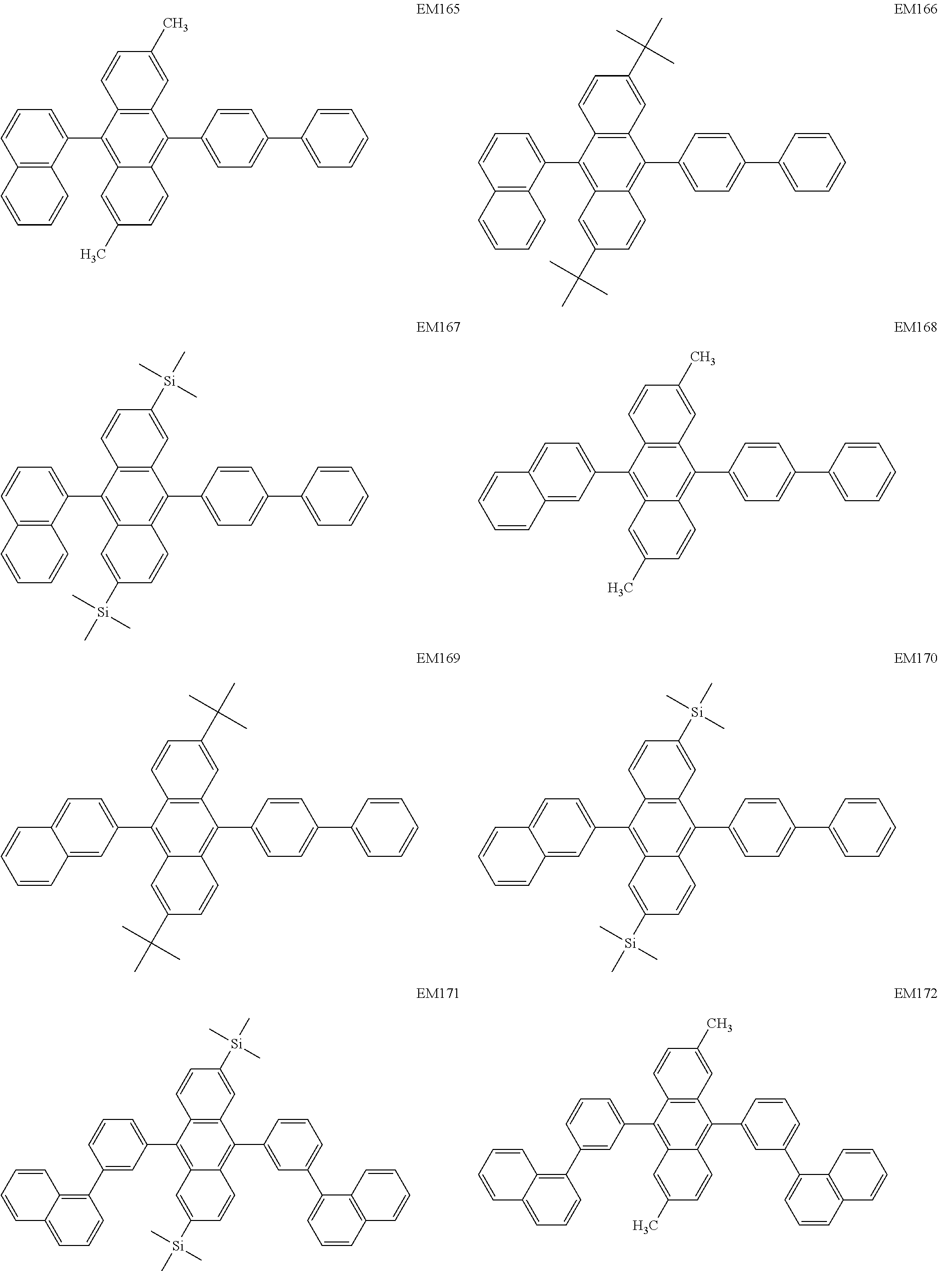

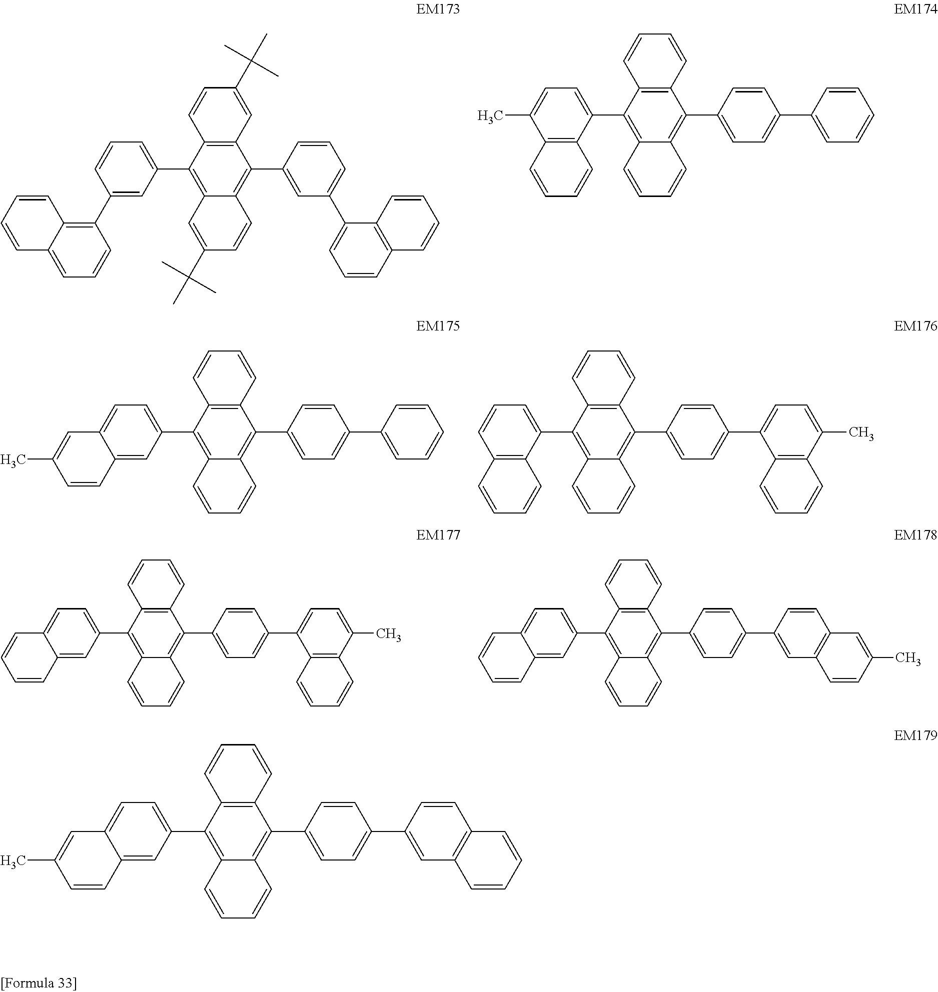

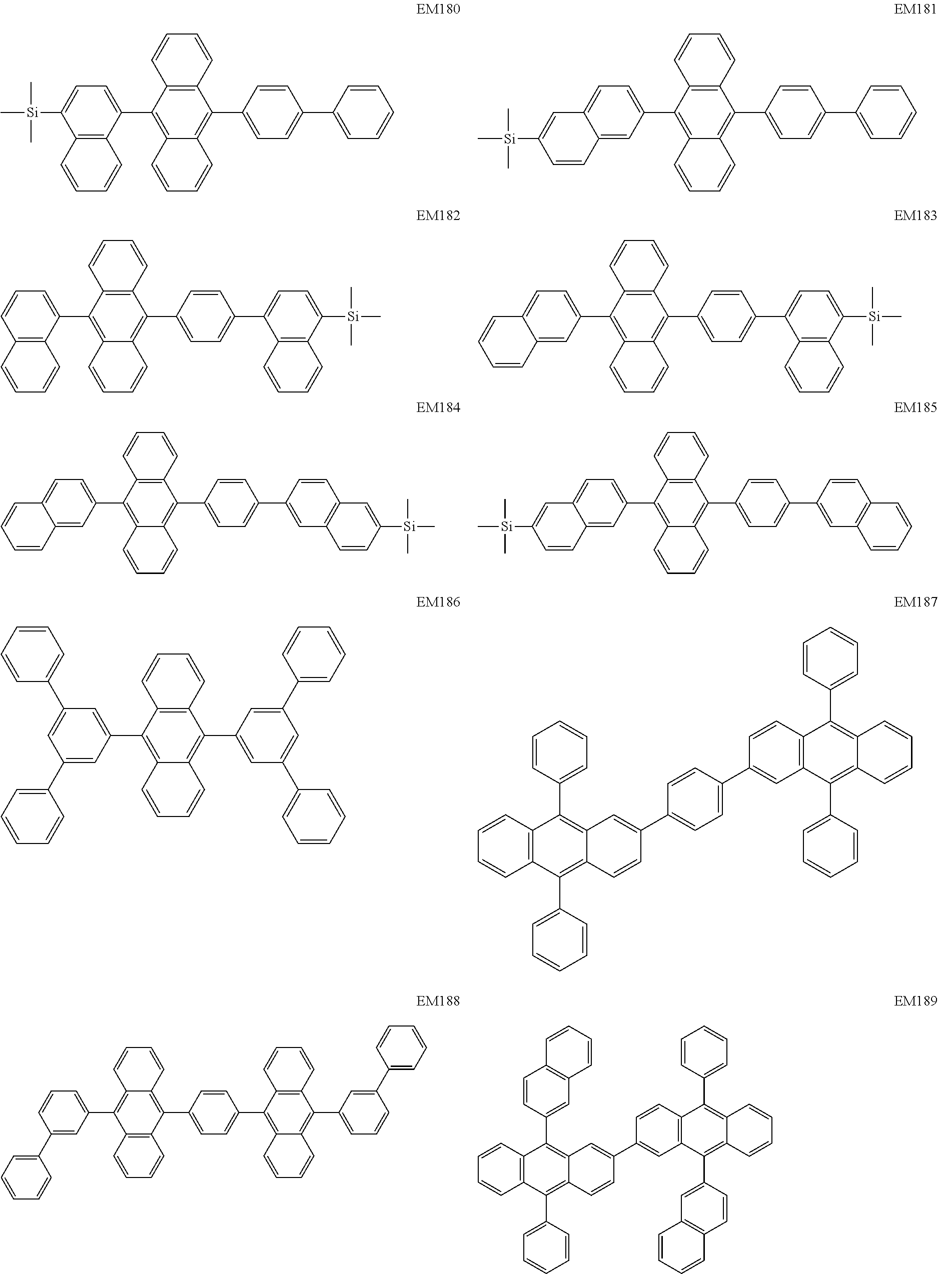

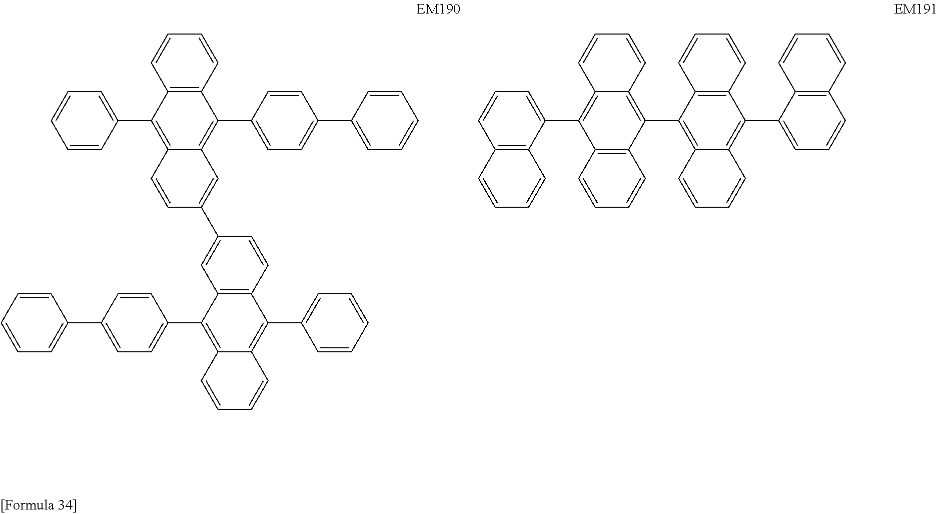

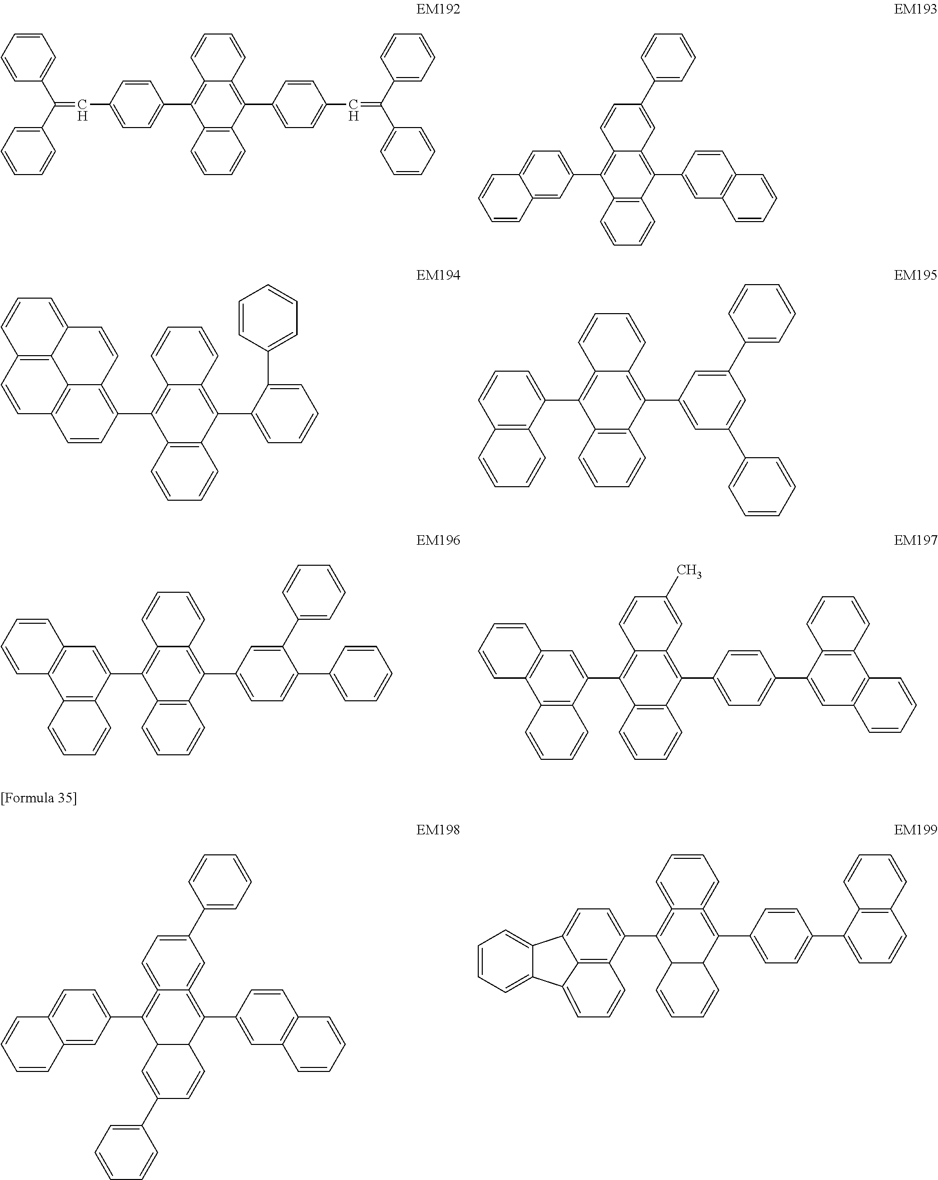

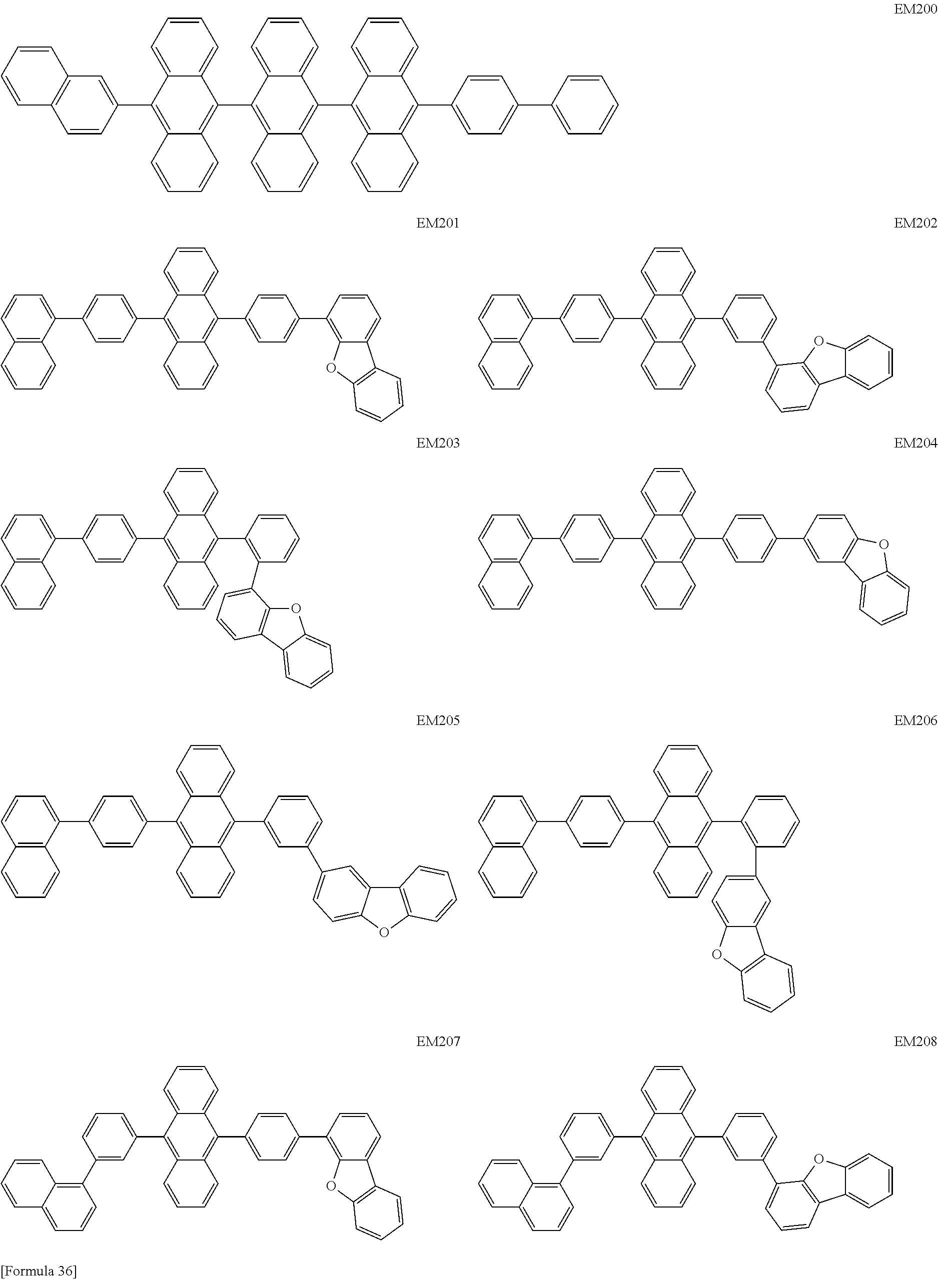

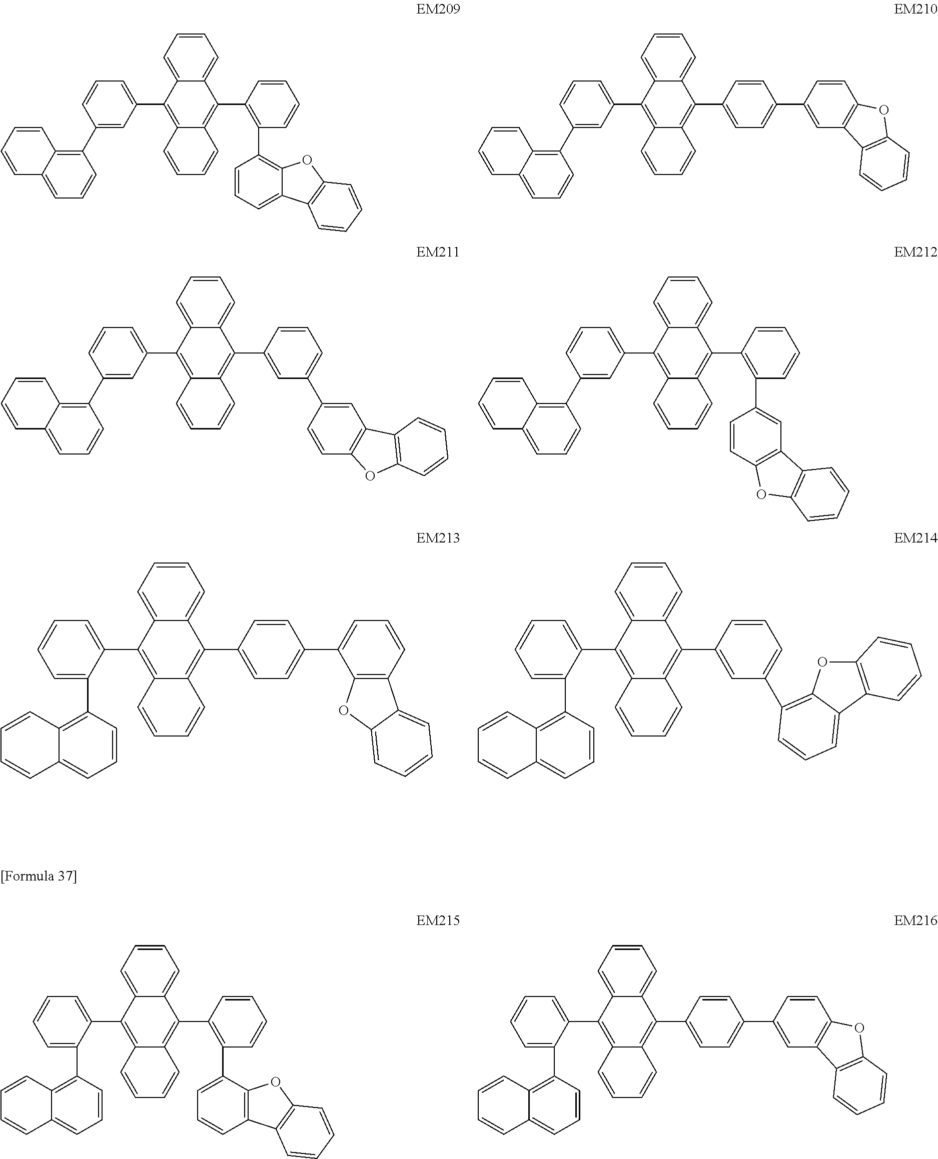

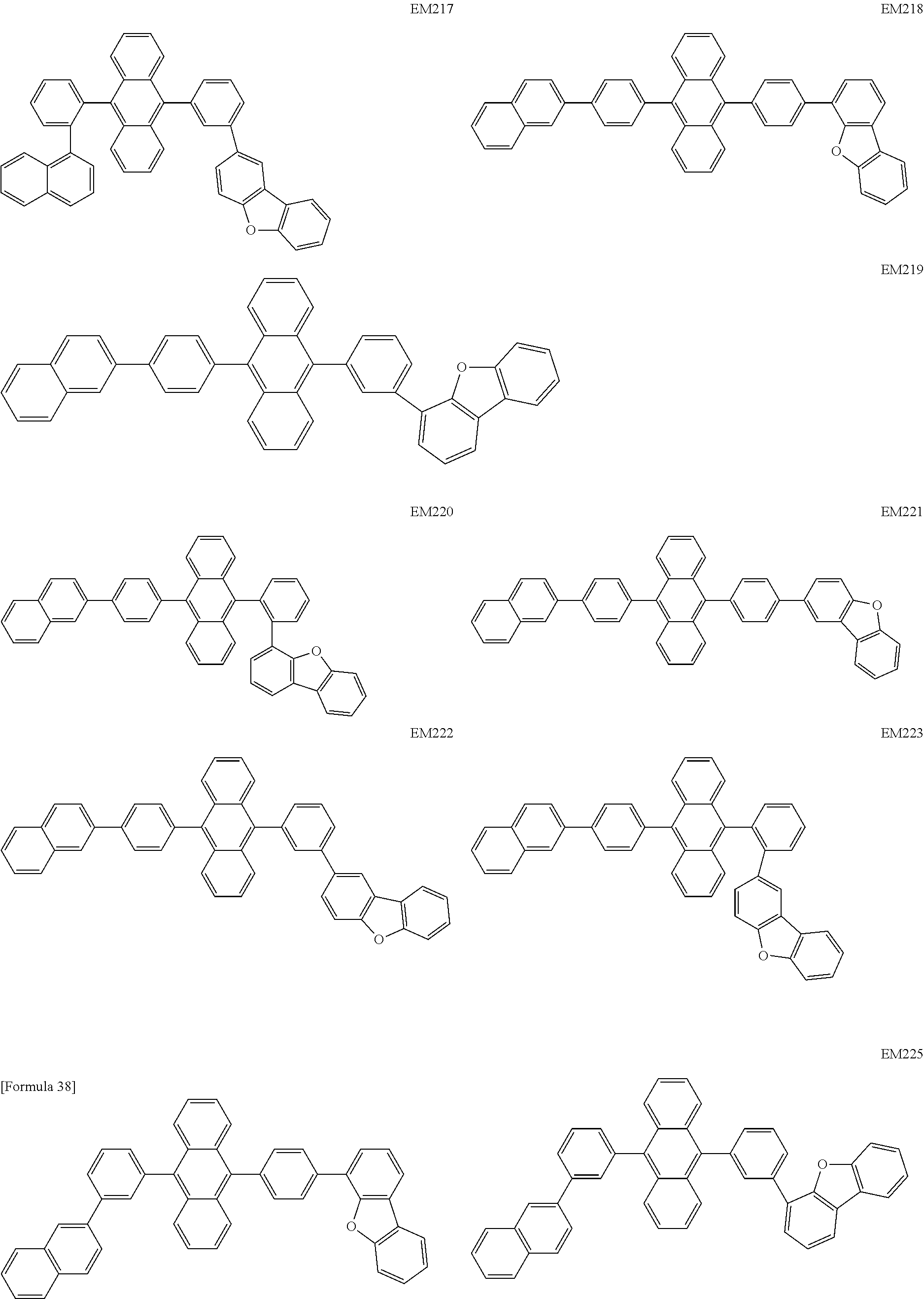

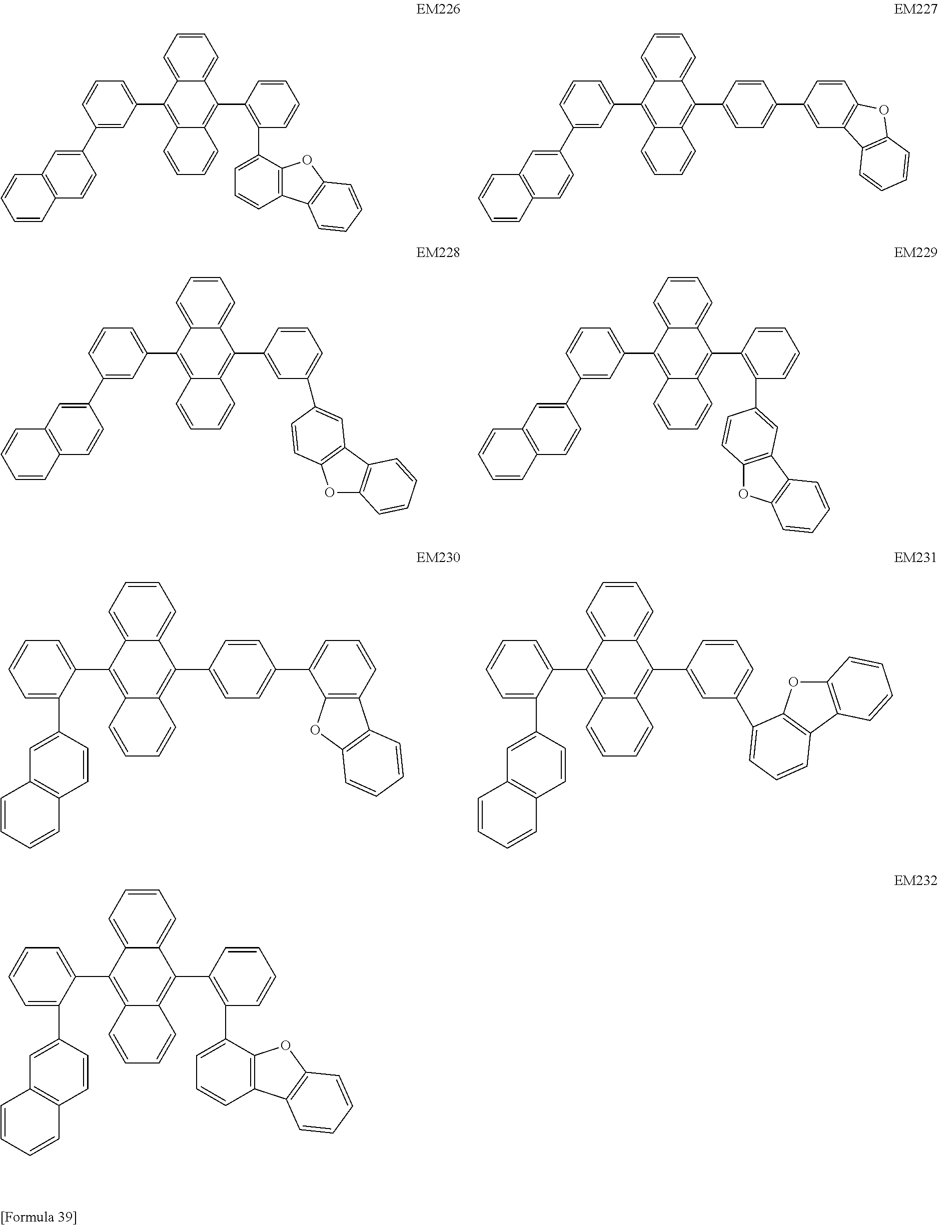

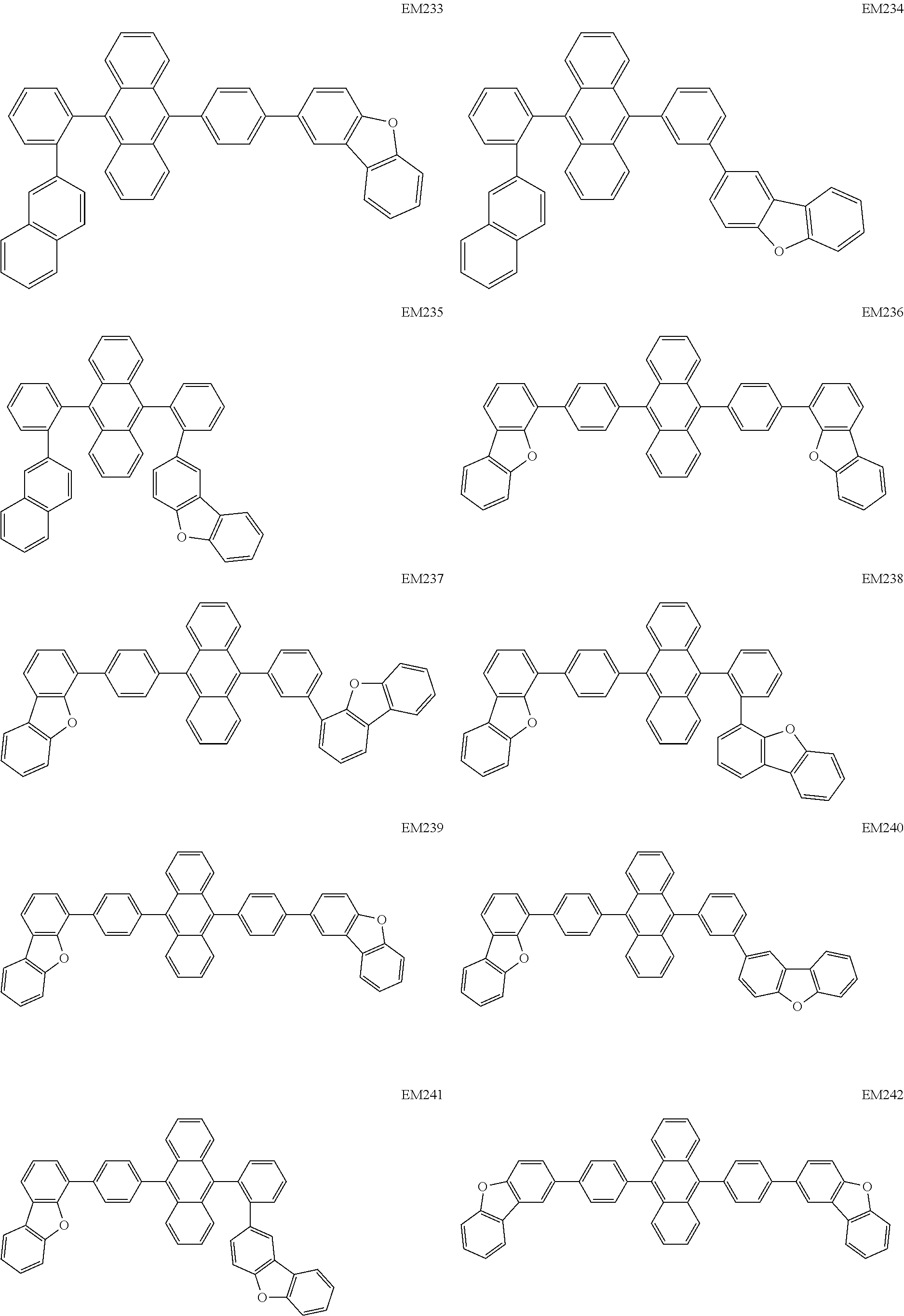

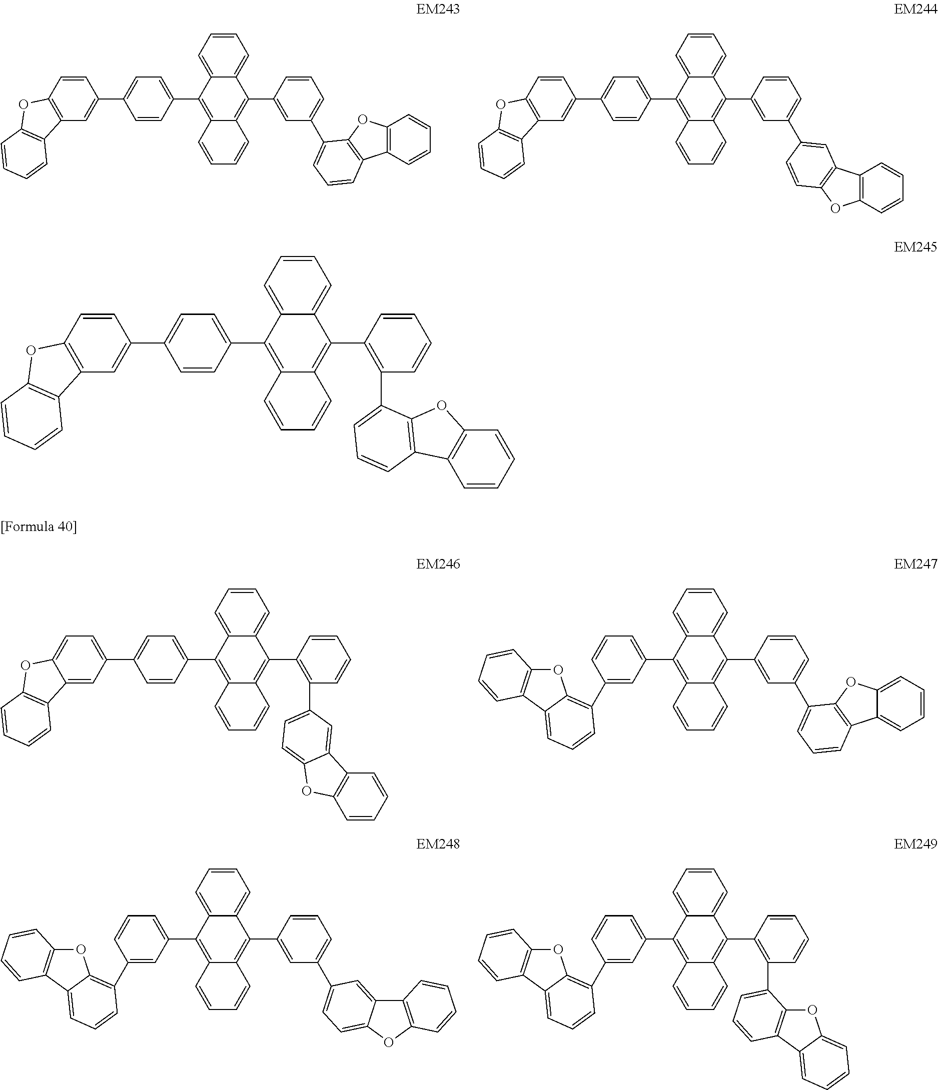

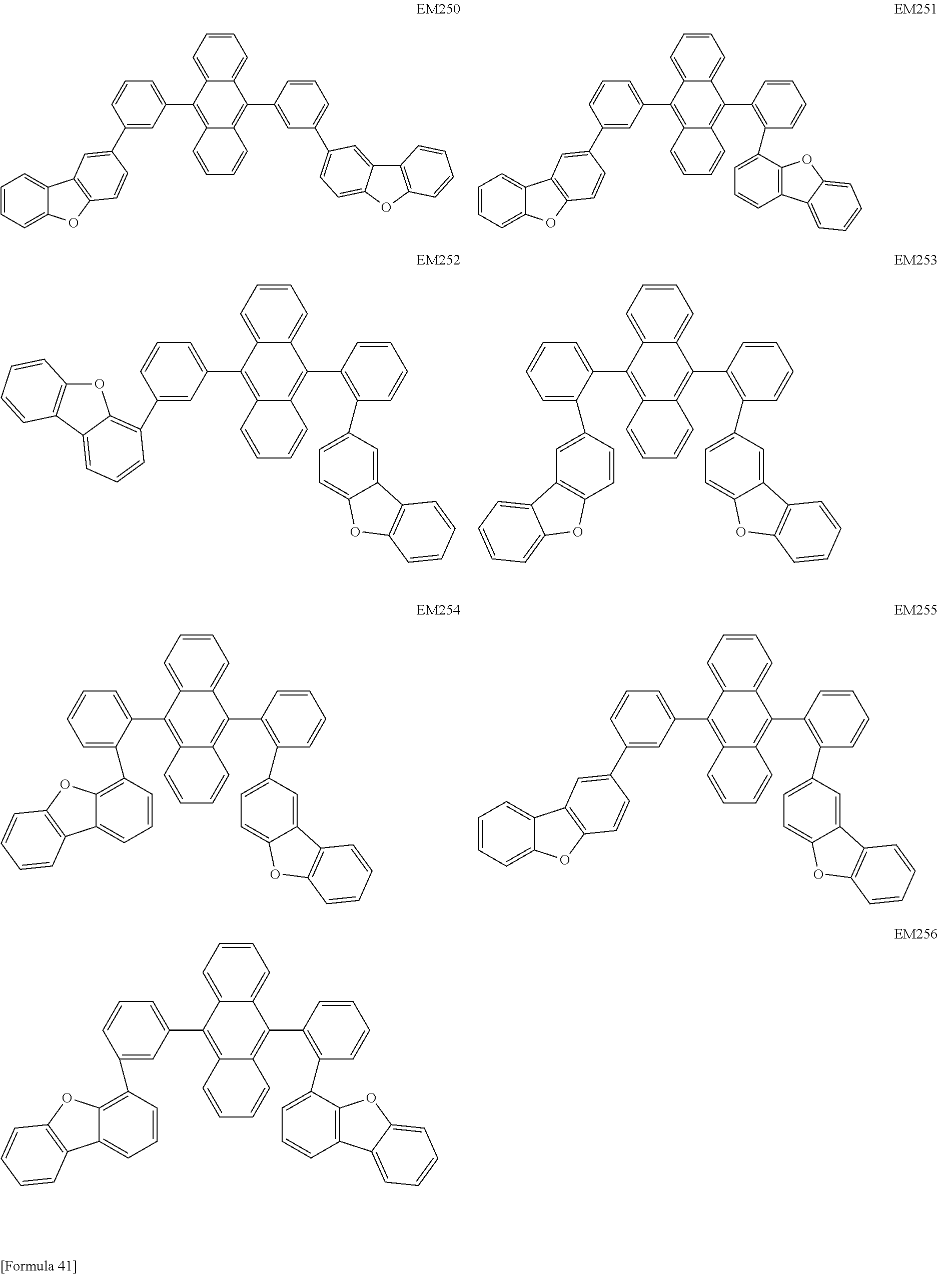

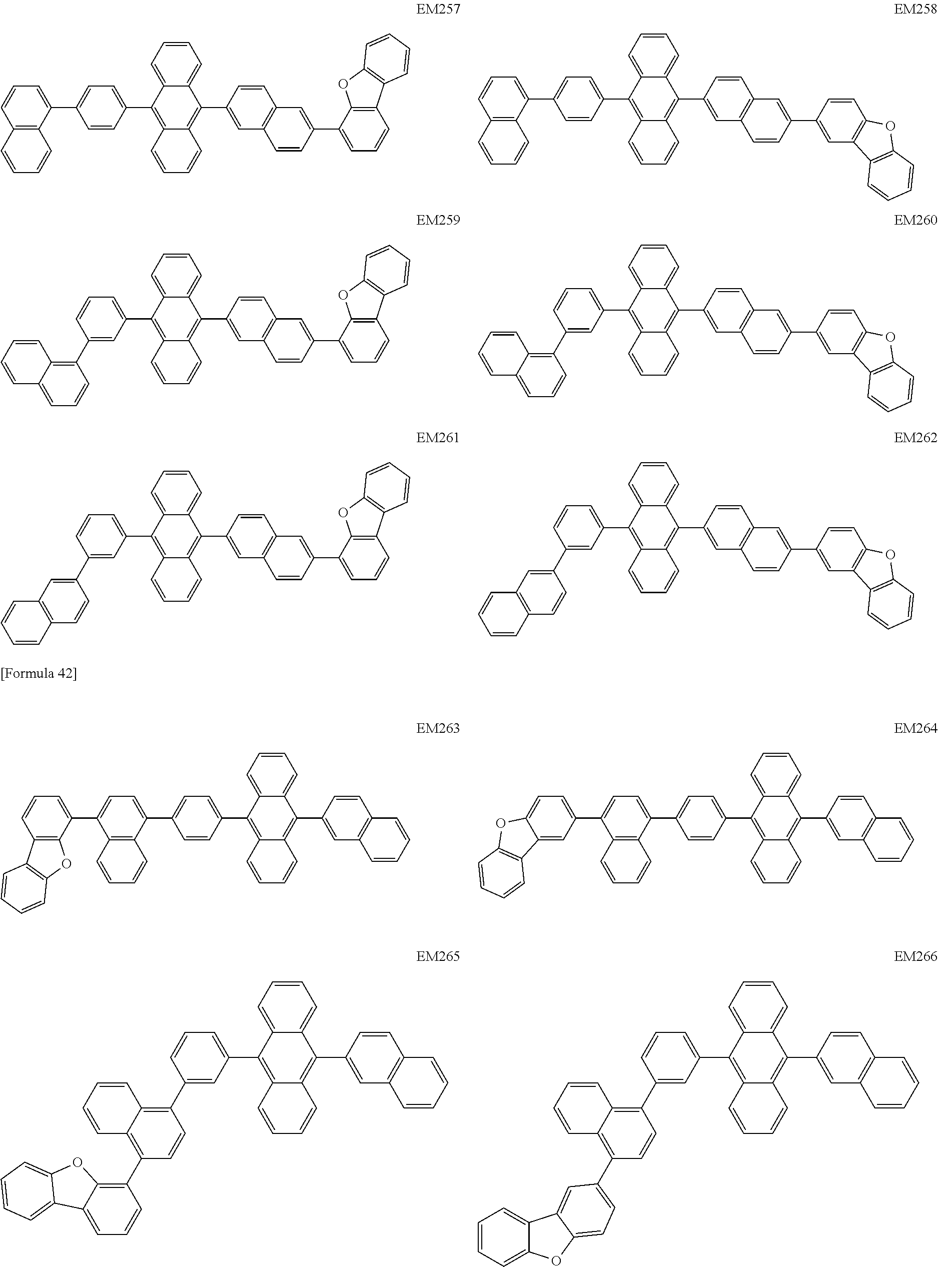

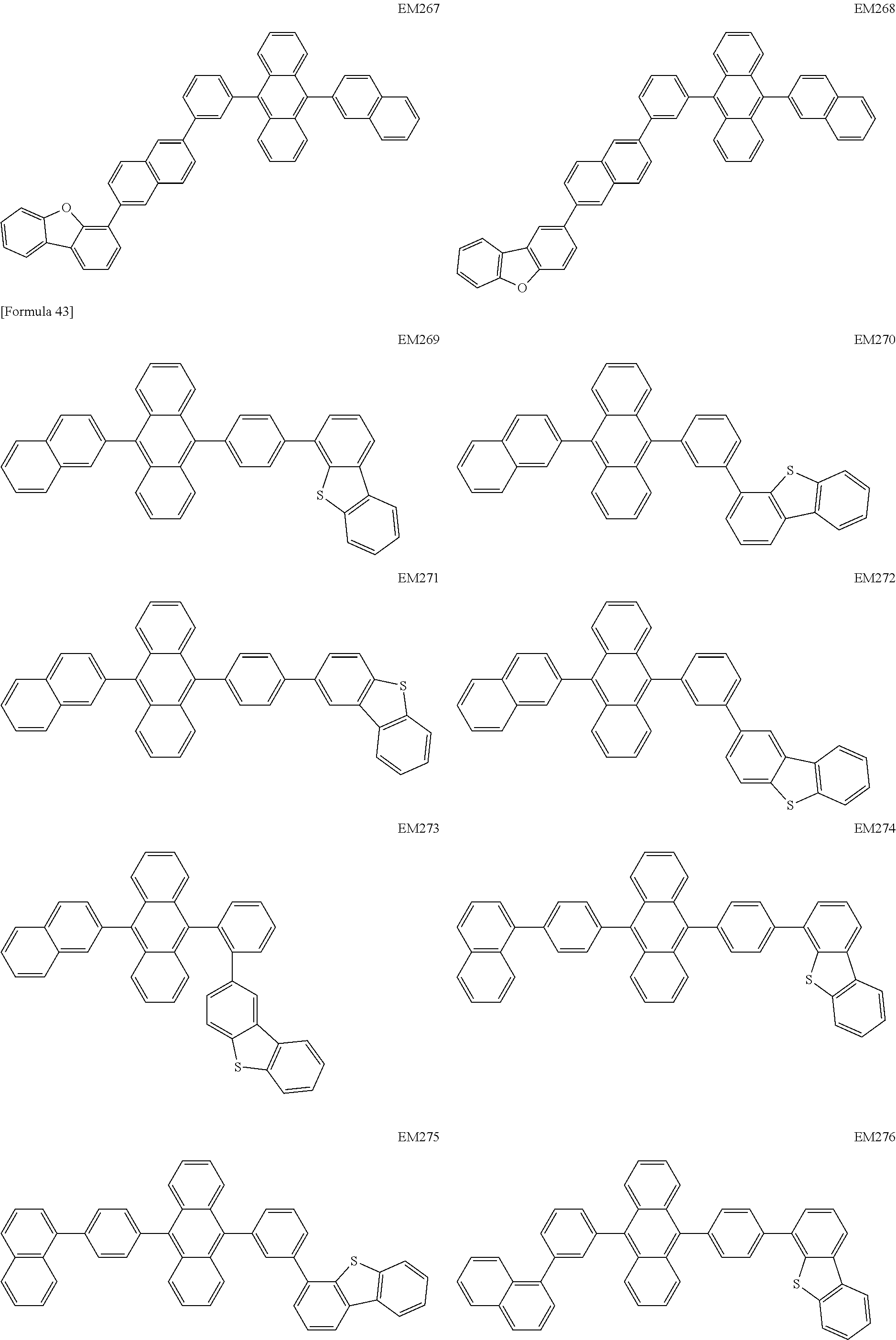

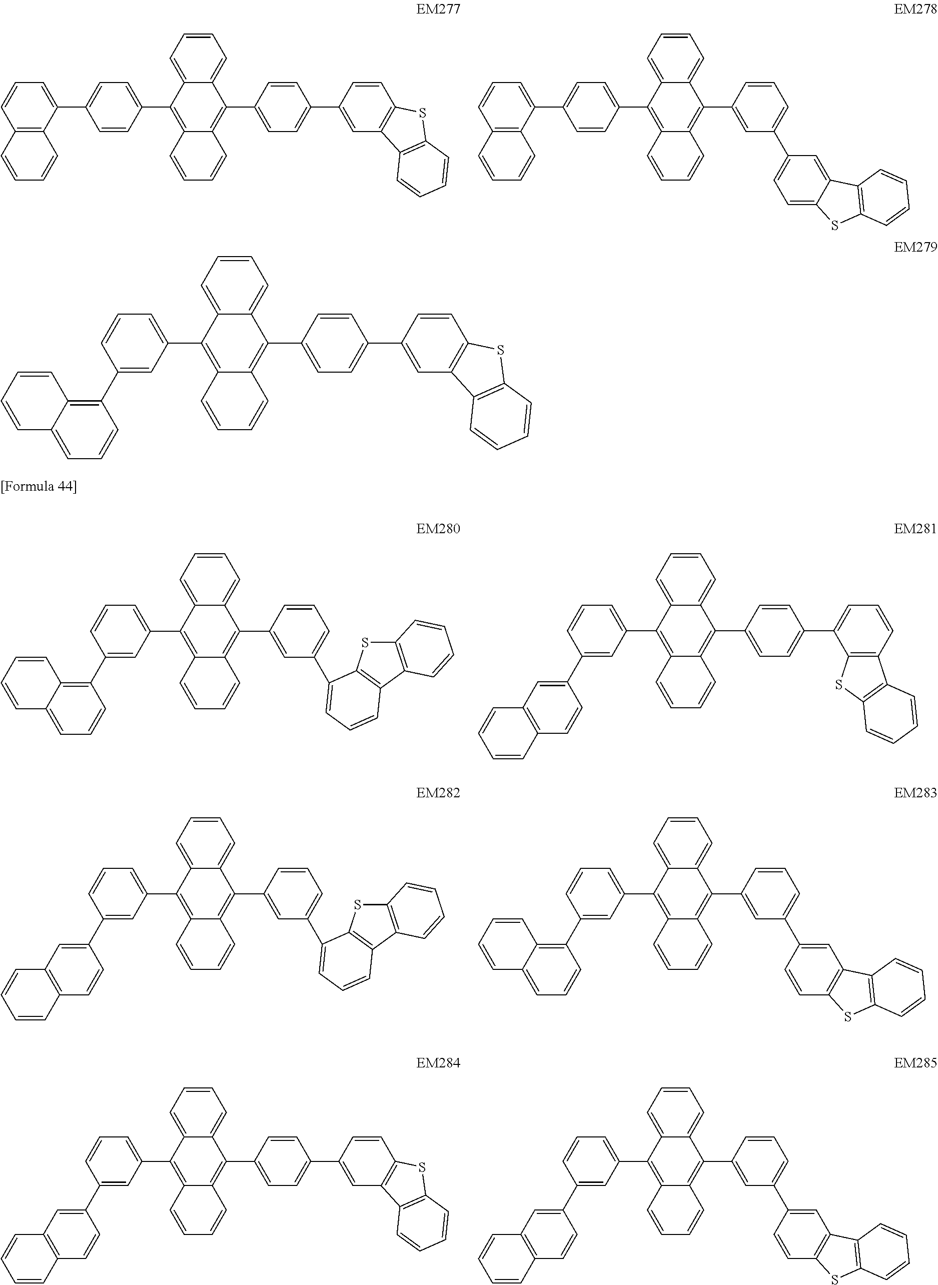

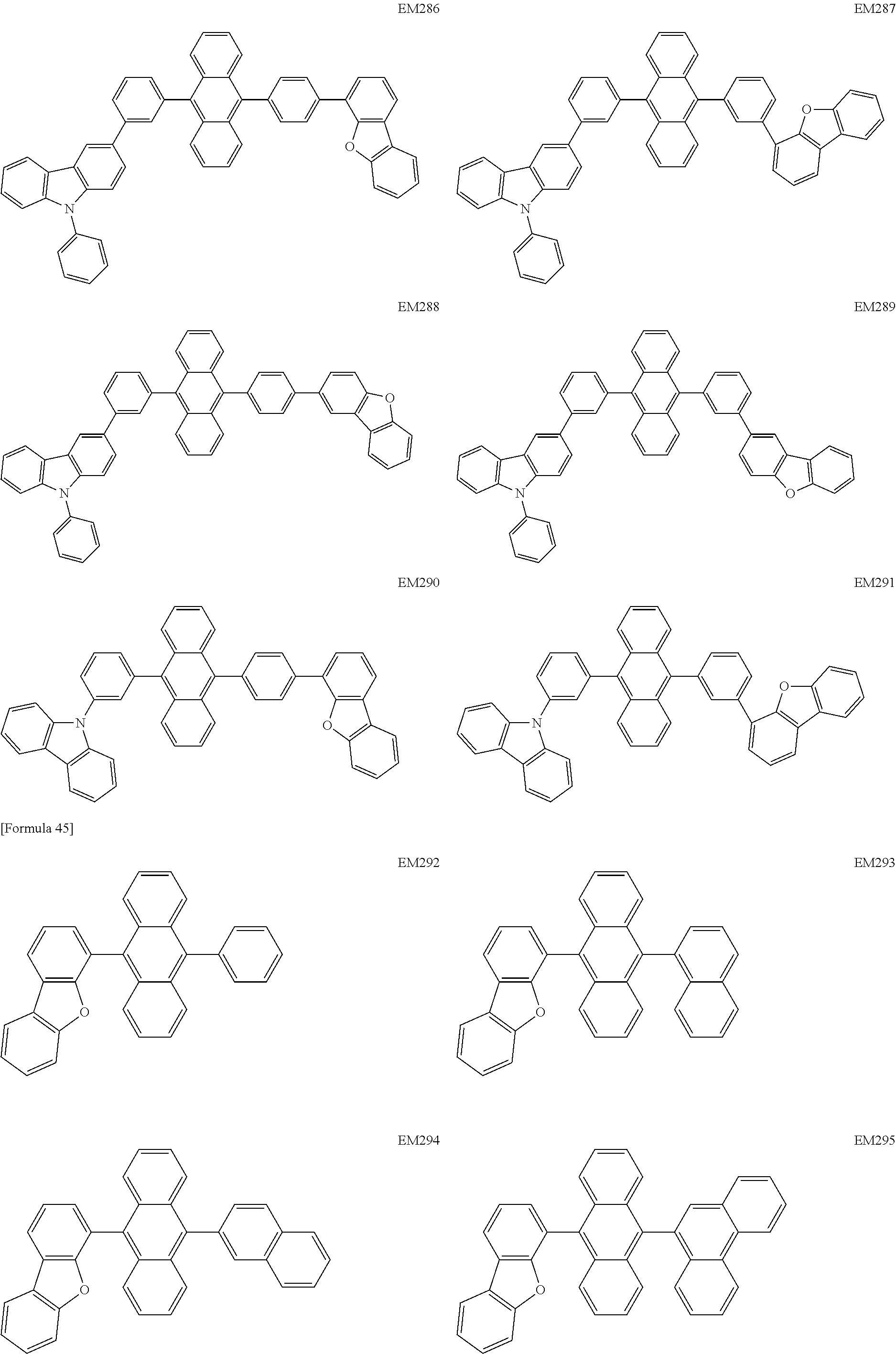

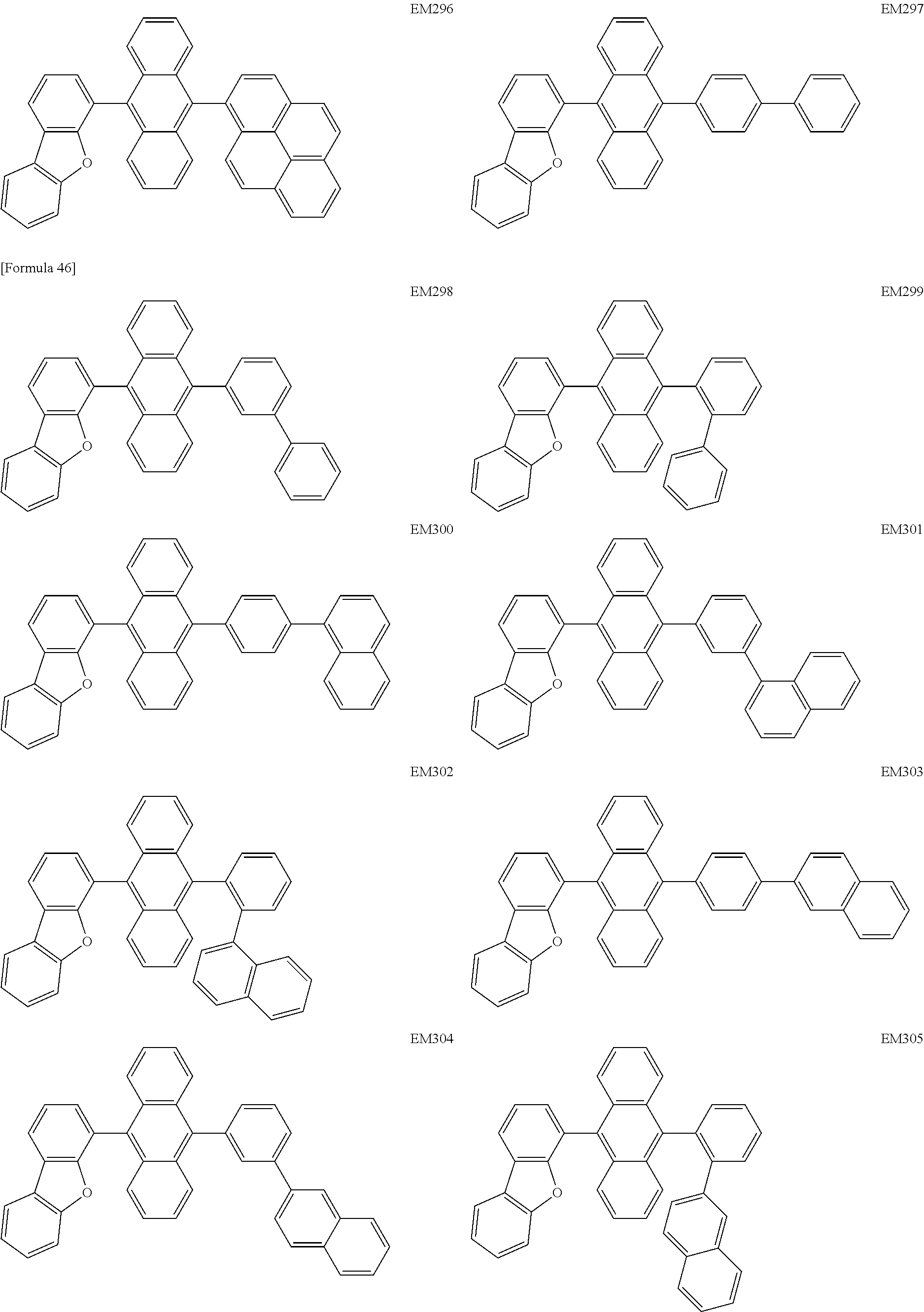

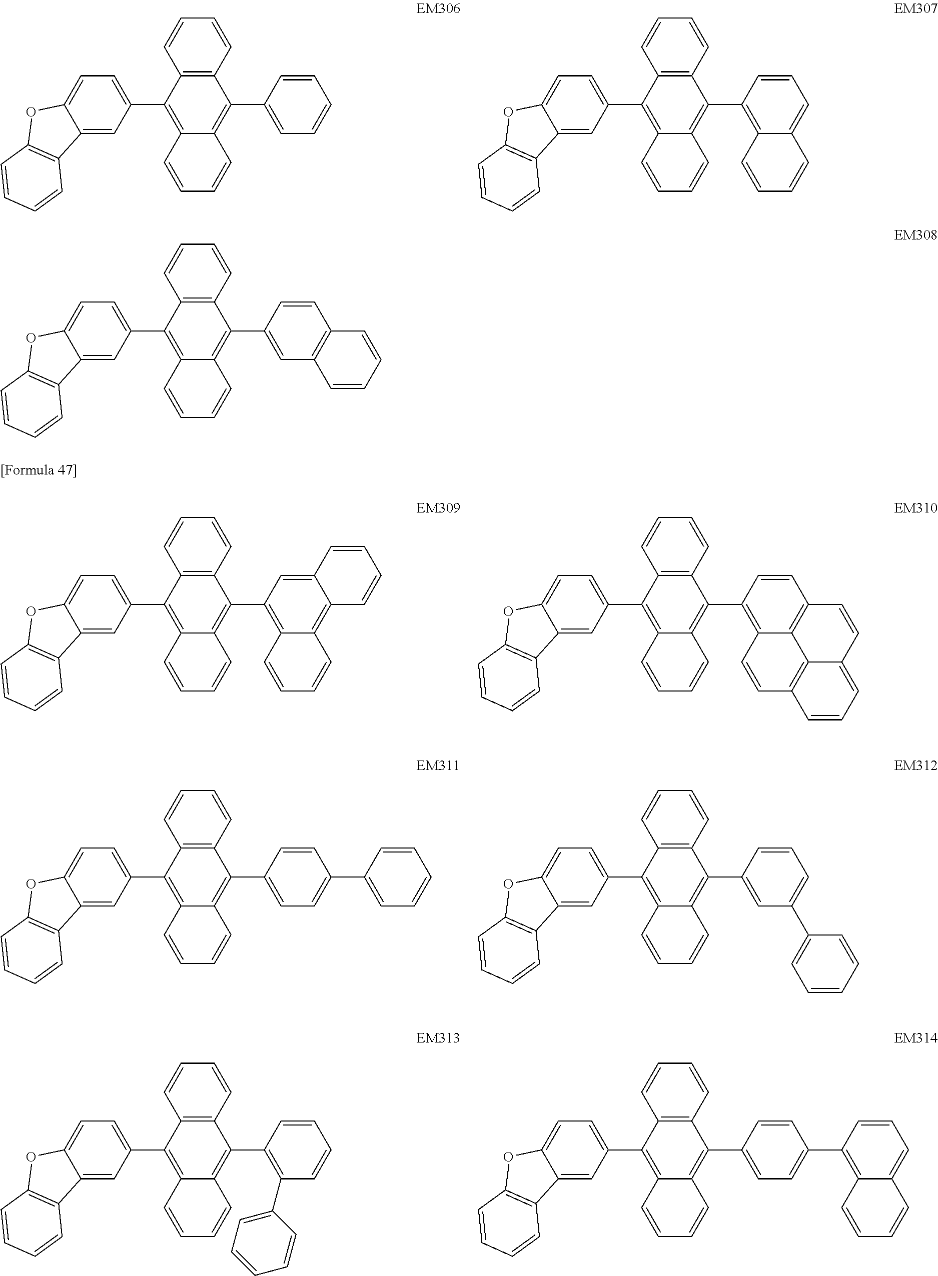

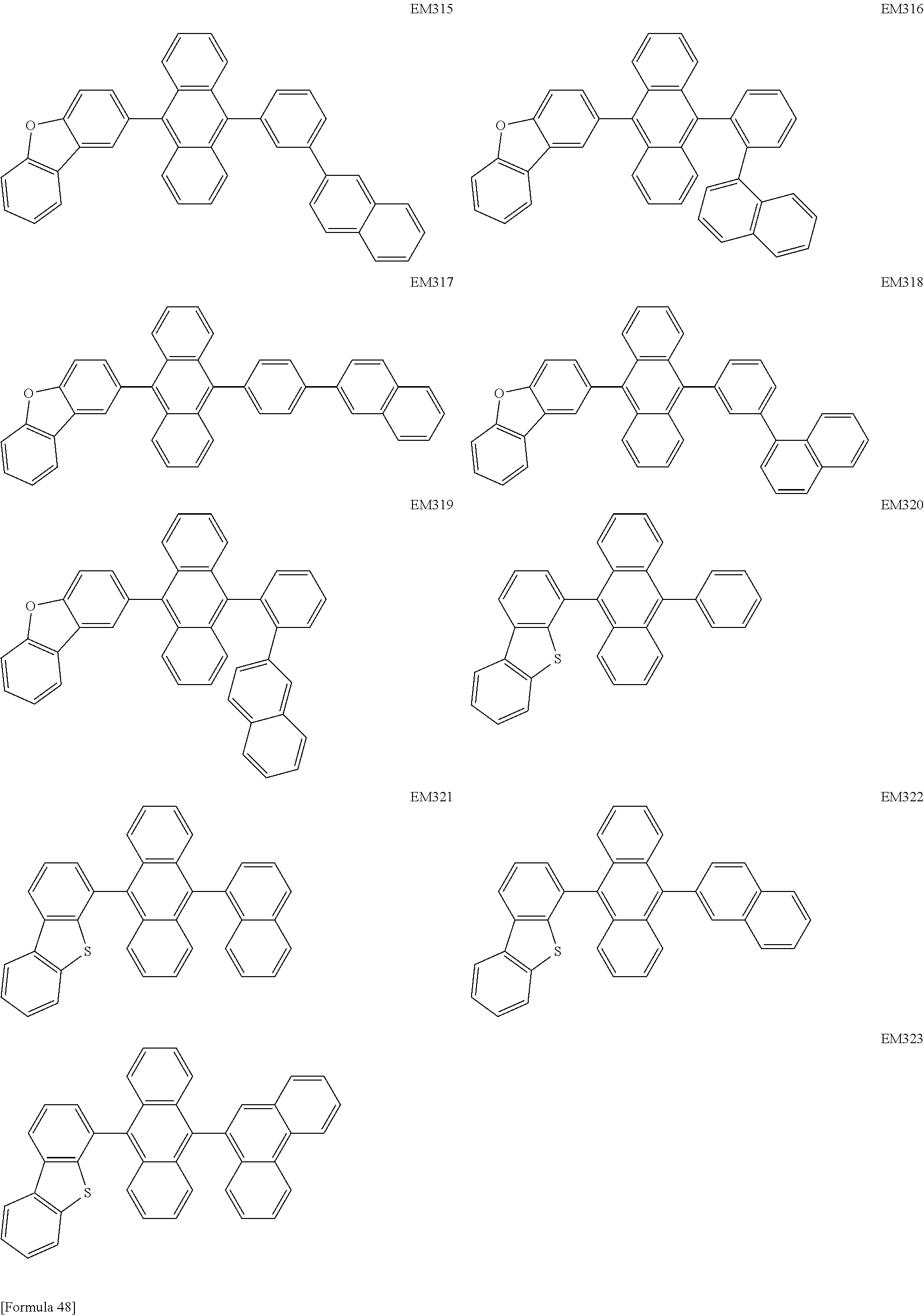

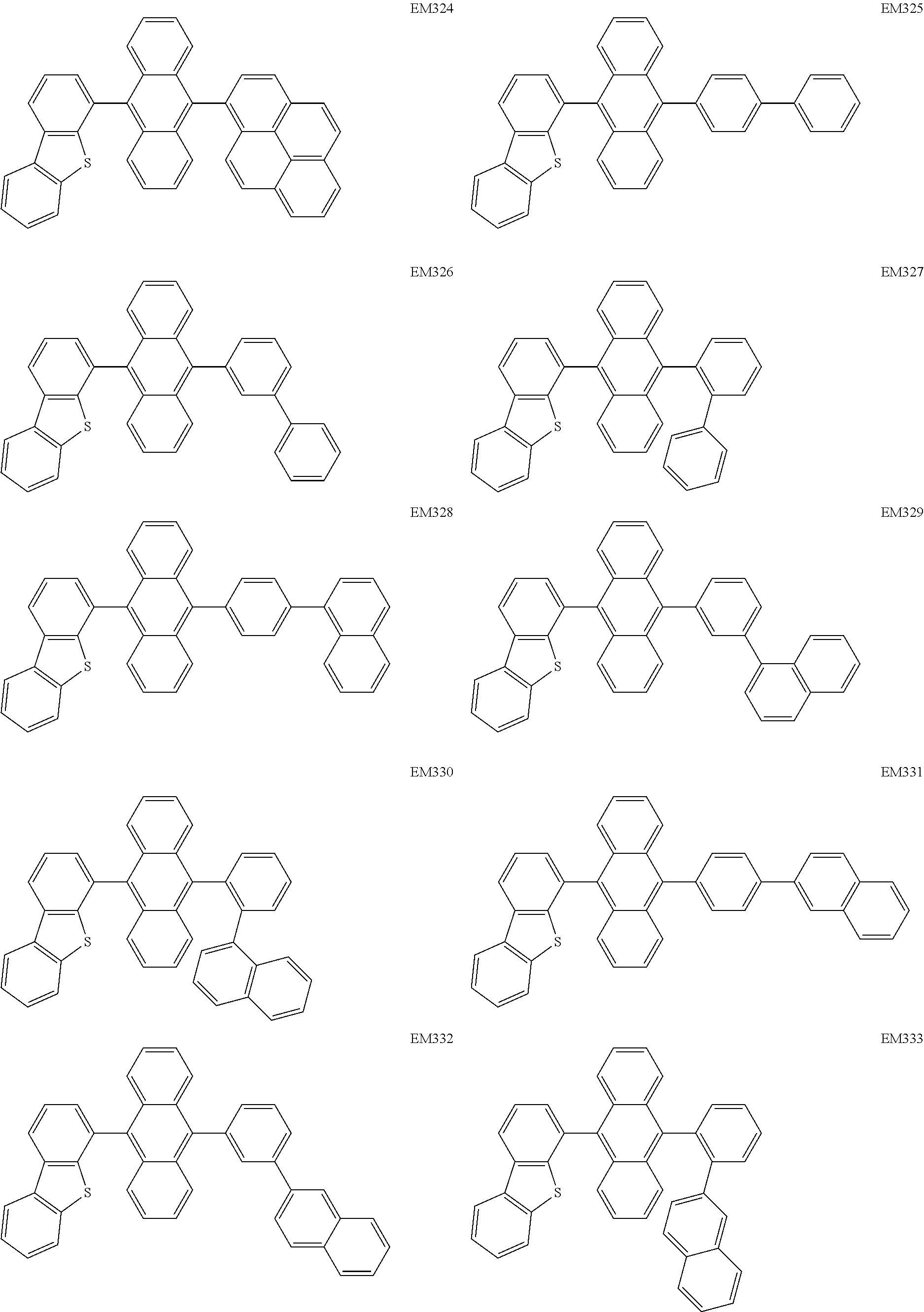

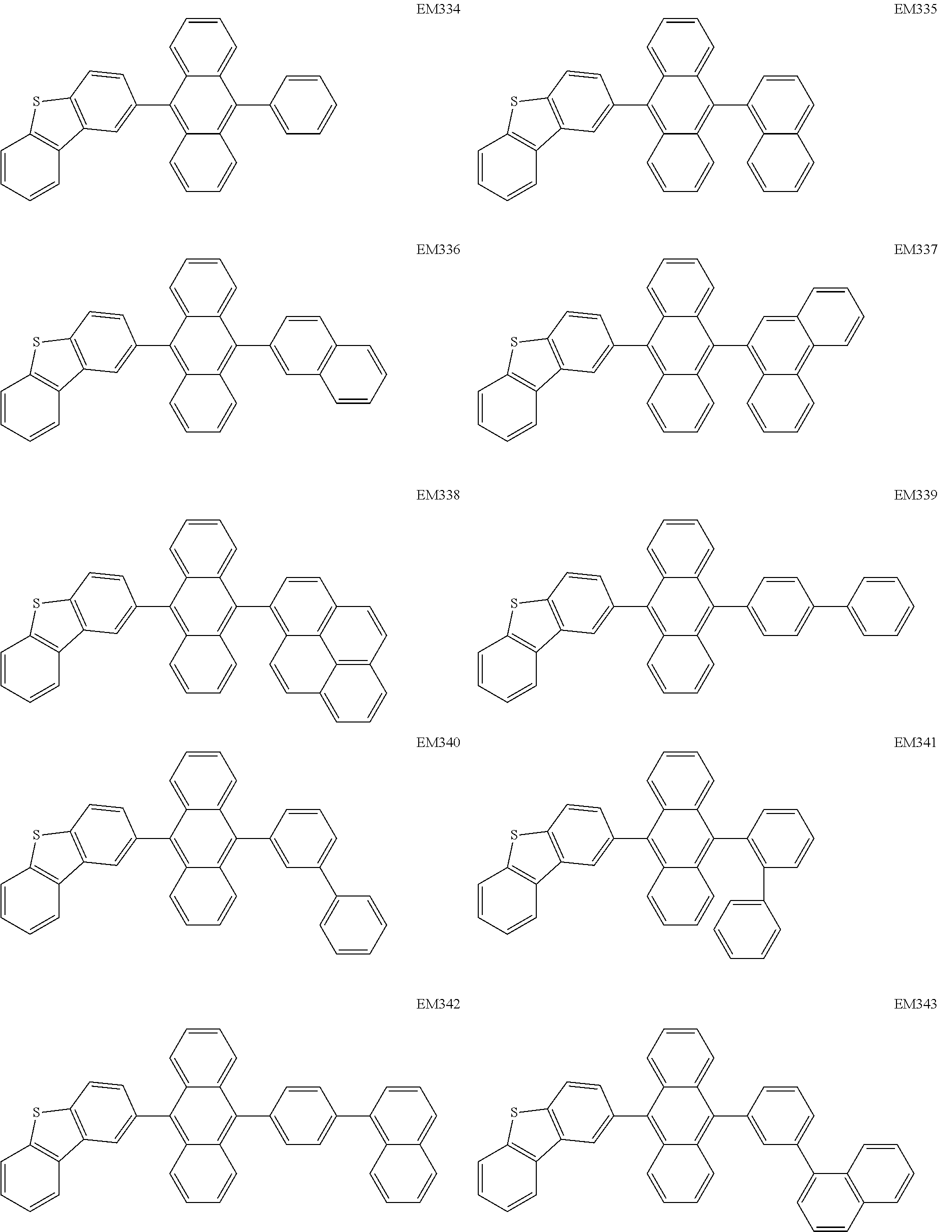

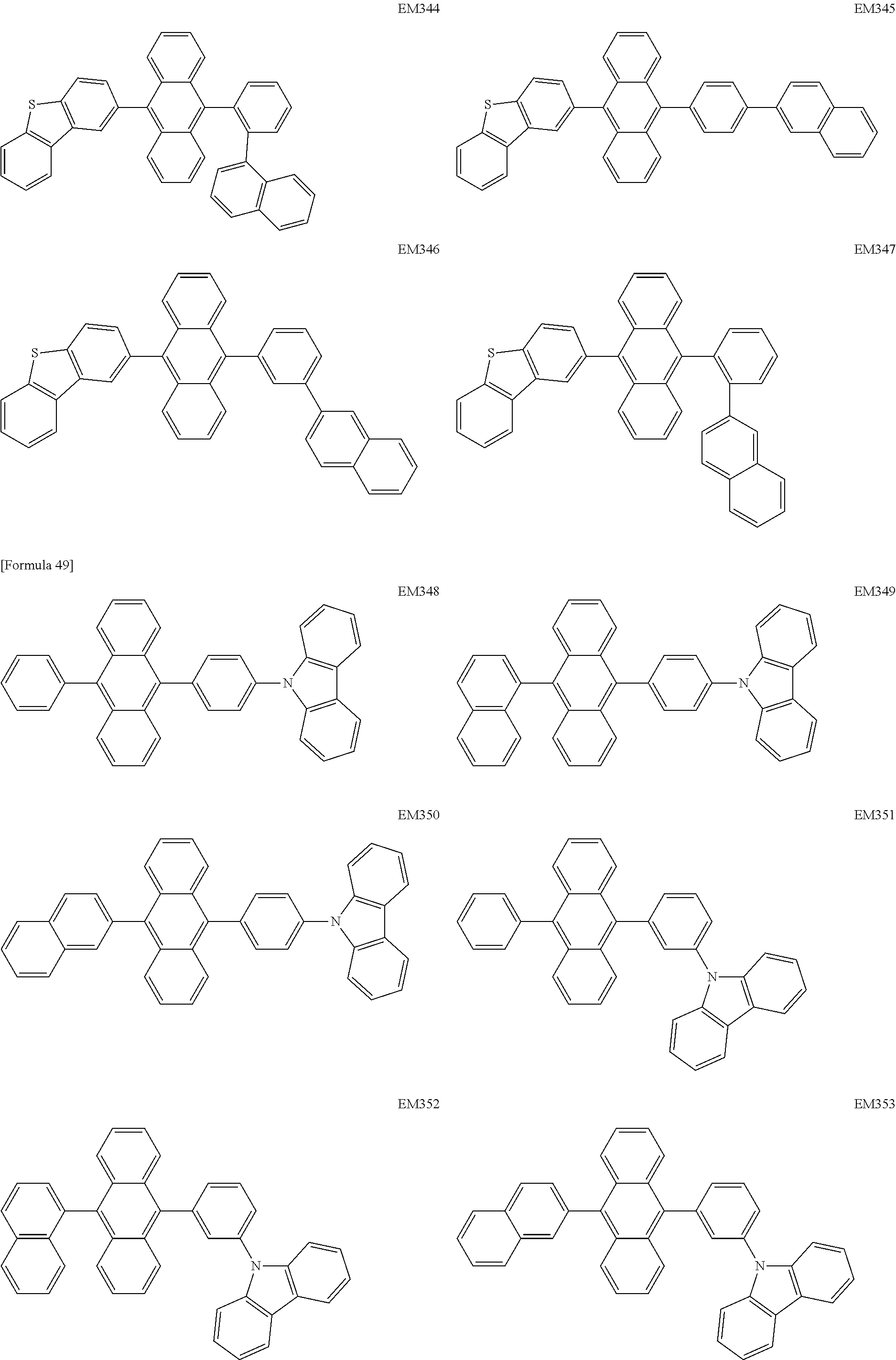

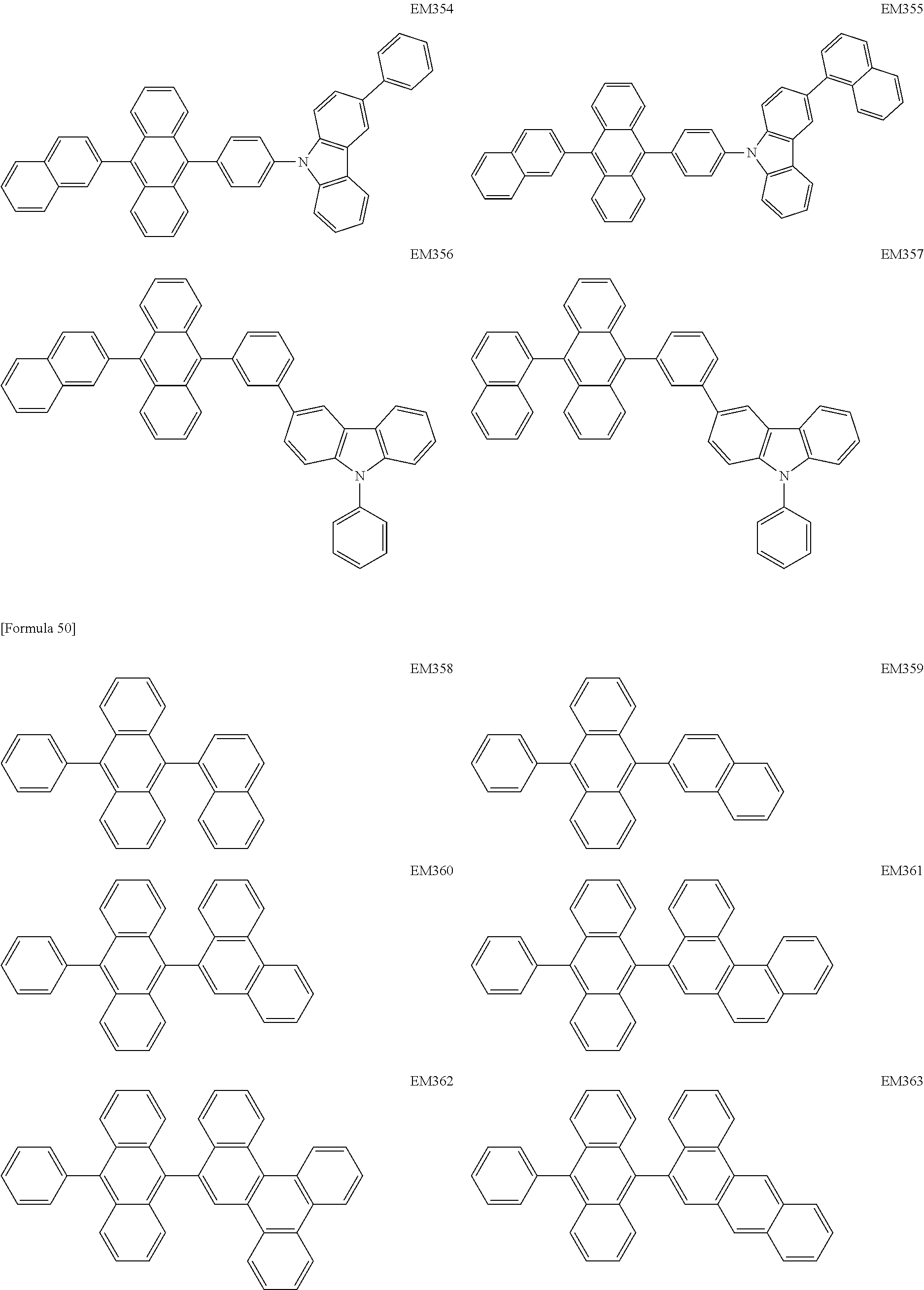

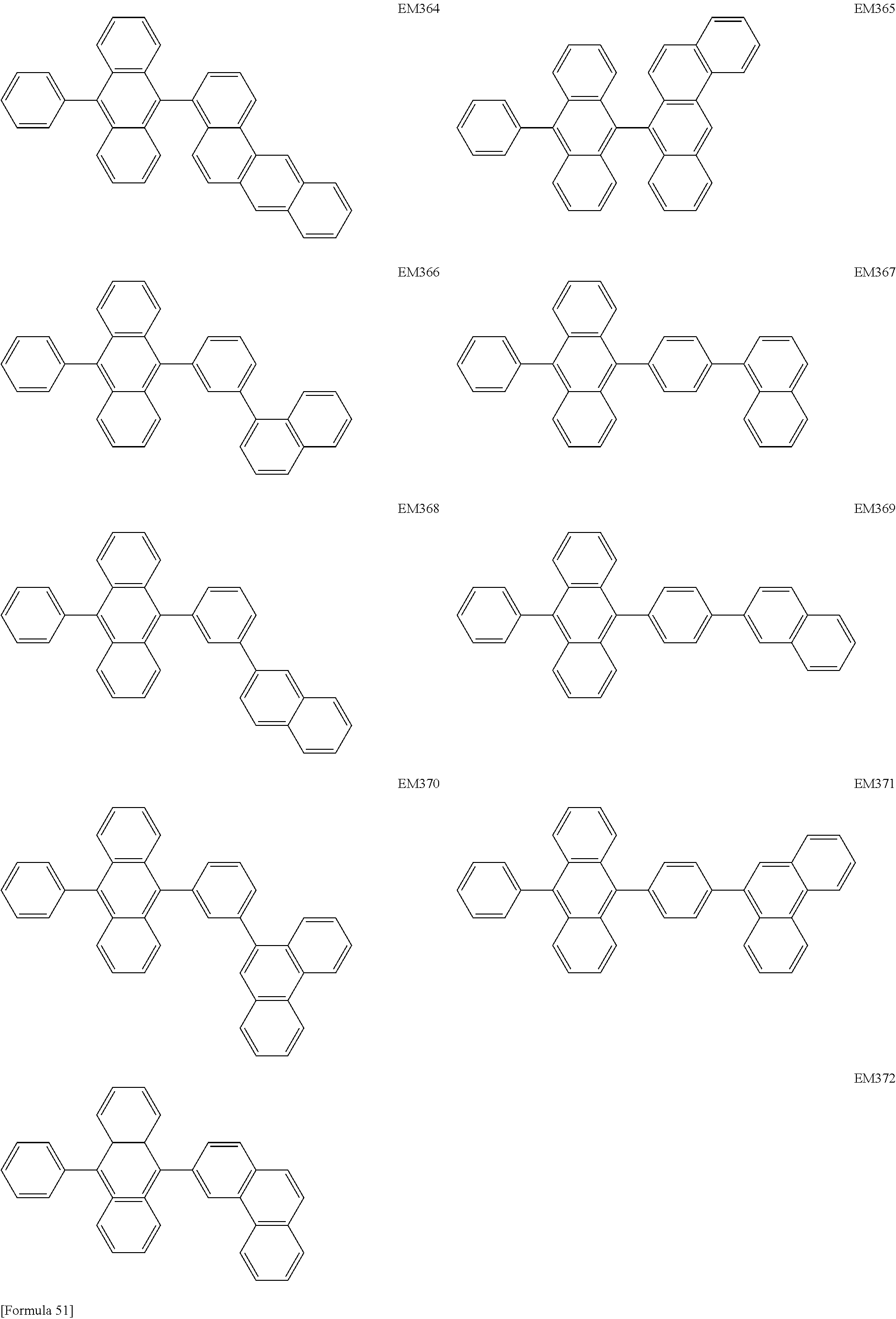

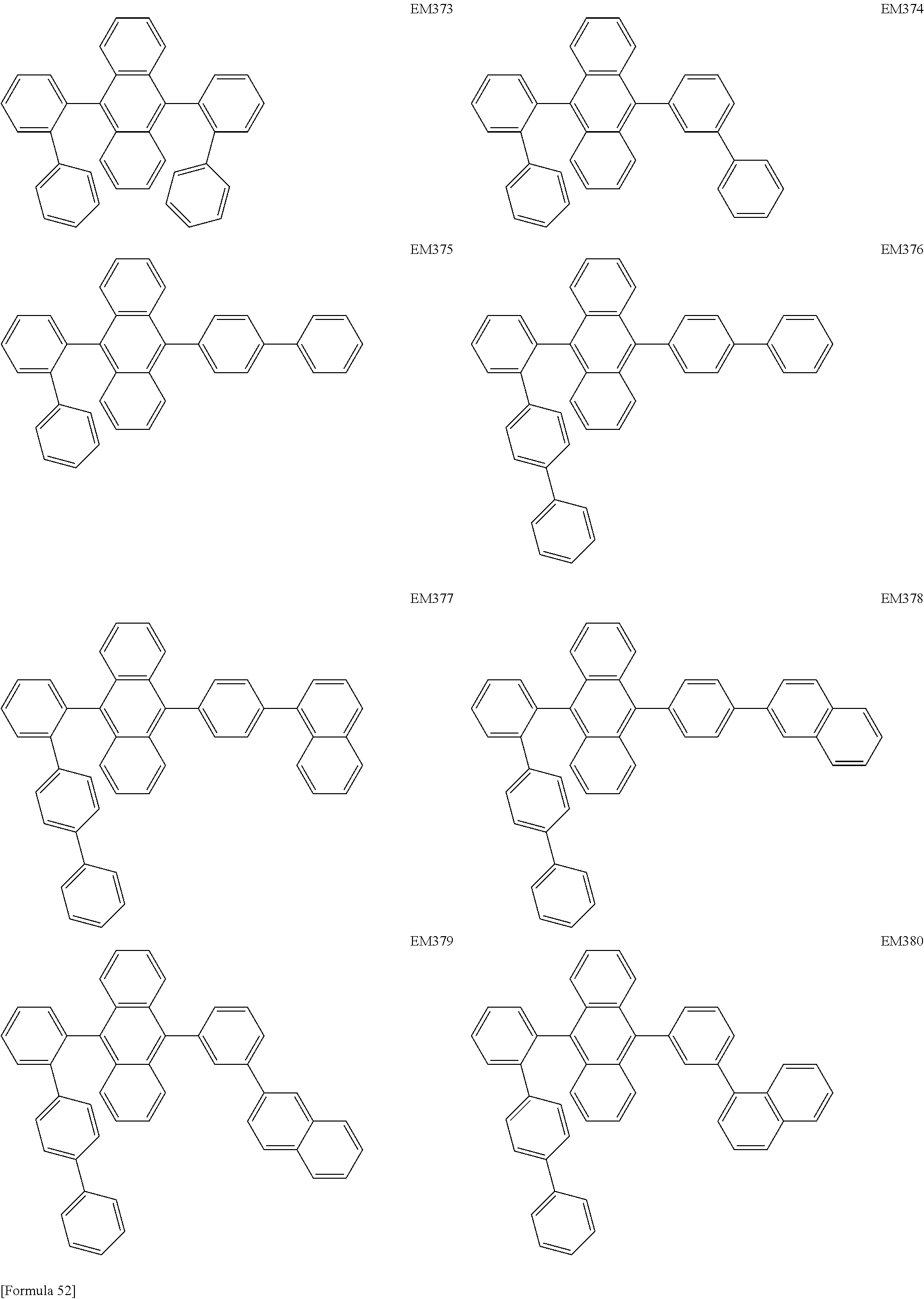

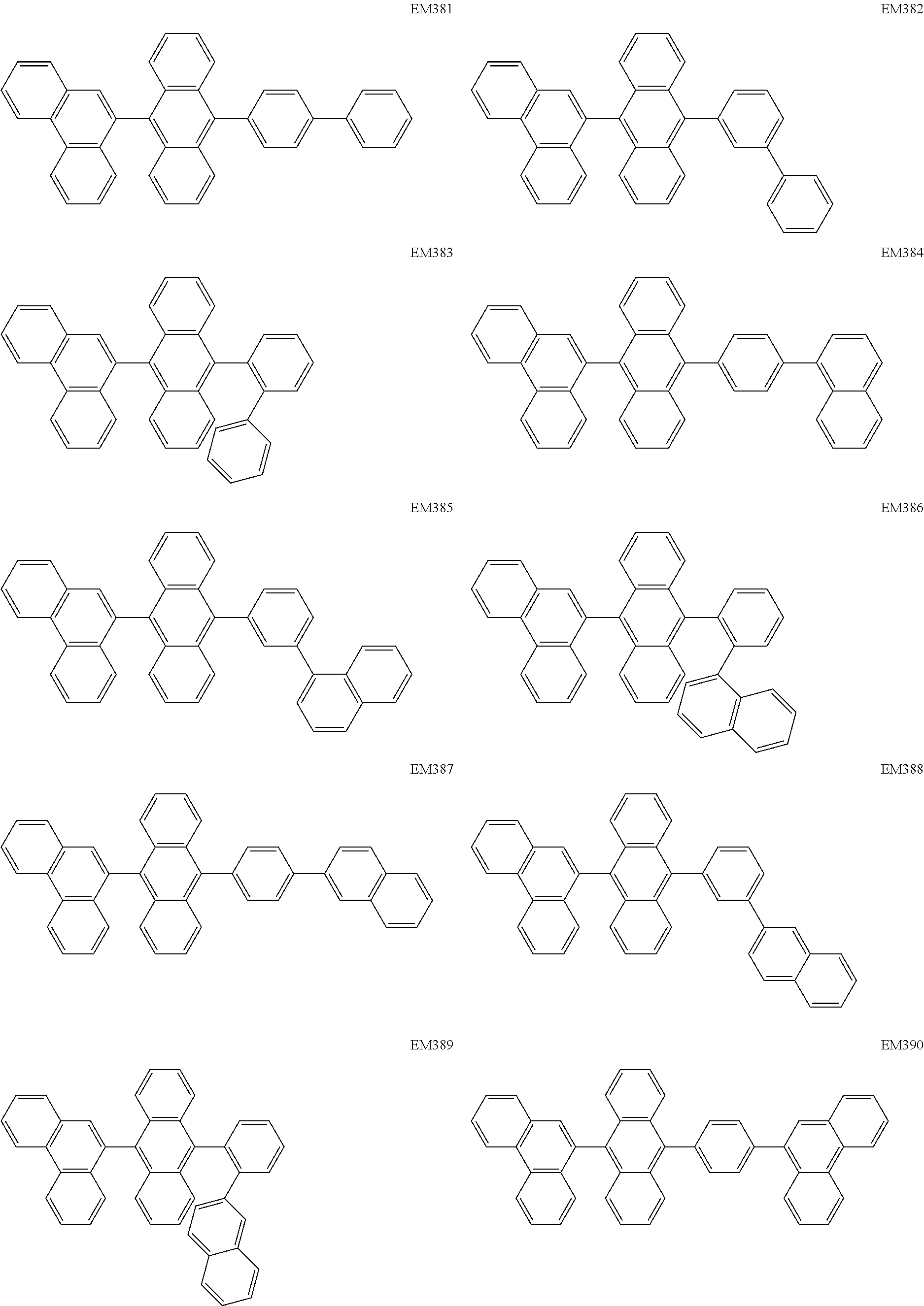

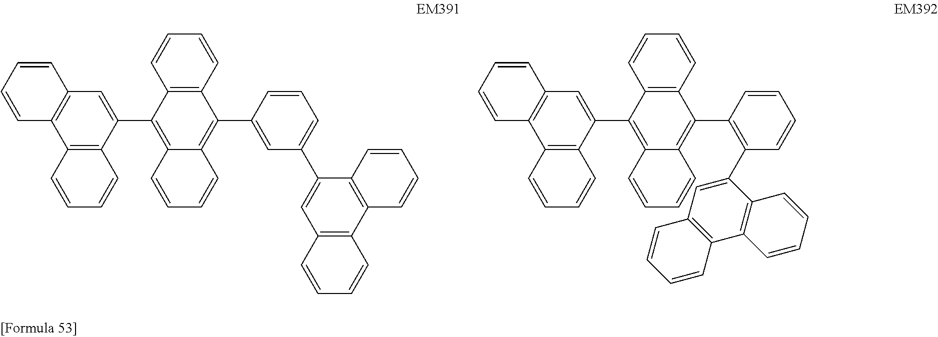

### Pyrene Derivative

In the organic EL device according to another aspect of the invention, at least one layer of the organic thin-film layers includes the aromatic amine derivative represented by the formula (1) and a pyrene derivative represented by the following formula (30). The emitting layer preferably includes the aromatic amine derivative as the dopant material and the pyrene derivative as the host material.

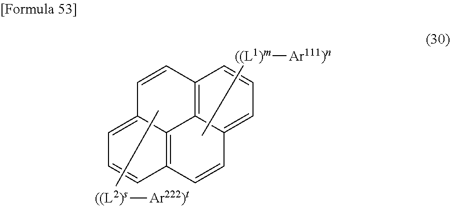

In the formula (30), Ar¹¹¹ and Ar²²² are each independently a substituted or unsubstituted aryl group having 6 to 30 ring carbon atoms.

In the formula (30), L¹ and L² are each independently a substituted or unsubstituted divalent aryl group having 6 to 30 ring carbon atoms or a heterocyclic group.

In the formula (30), m is an integer of 0 to 1, n is an integer of 1 to 4, s is an integer of 0 to 1 and t is an integer of 0 to 3.

In the formula (30), L¹ or Ar¹¹¹ is bonded to pyrene at any one of positions 1 to 5, and L² or Ar²²² is bonded to pyrene at any one of positions 6 to 10.

Moreover, examples of “substituted or unsubstituted” substituents for Ar¹¹¹, Ar¹¹², L¹ and L² in the formula (30) are the same as those in the above description.

L¹ and L² in the formula (30) are preferably selected from a substituted or unsubstituted phenylene group, a substituted or unsubstituted biphenylene group, a substituted or unsubstituted naphthylene group, a substituted or unsubstituted terphenylene group, a substituted or unsubstituted fluorenylene group, and a divalent aryl group provided by combinations of the above groups.

m in the formula (30) is preferably an integer of 0 to 1.

n in the formula (30) is preferably an integer of 1 to 2.

s in the formula (30) is preferably an integer of 0 to 1.

t in the formula (30) is preferably an integer of 0 to 2.

The aryl group for Ar¹¹¹ and Ar²²² in the formula (30) represents the same as R₂, R₃, R₄, R₅, R₇, R₈, R₉ and R₁₀ in the formula (1). A substituted or unsubstituted aryl group having 6 to 20 ring carbon atoms is preferable. A substituted or unsubstituted aryl group having 6 to 16 ring carbon atoms is more preferable. Specific examples of the aryl group are a phenyl group, naphthyl group, phenanthryl group, fluorenyl group, biphenyl group, anthryl group and pyrenyl group.

### Other Application of Compounds

The aromatic amine derivative of the invention, the anthracene derivative represented by the above formula (20), and the pyrene derivative represented by the above formula (30) are applicable to the hole injecting layer, hole transporting layer, electron injecting layer and electron transporting layer in addition to the emitting layer.

### Other Materials Usable in Emitting Layer

Examples of materials other than the derivatives represented by the formulae (20) and (30) usable in the emitting layer together with the aromatic amine derivative according to the exemplary embodiment include: a fused polycyclic aromatic compound such as naphthalene, phenanthrene, rubrene, anthracene, tetracene, pyrene, perylene, chrysene, decacyclene, coronene, tetraphenylcyclopentadiene, pentaphenylcyclopentadiene, fluorene, and spirofluorene, and derivatives thereof; an organic metal complex such as tris(8-quinolinolate)aluminium; triaryl amine derivative; styryl amine derivative; stilbene derivative; coumaline derivative; pyrane derivative; oxazone derivative; benzothiazole derivative; benzooxazole derivative; benzimidazole derivative; pyrazine derivative; cinnamic acid ester derivative; diketopyrrolopyrrole derivative; acridone derivative and quinacridone derivative. However, the materials are not limited thereto.

### Content

When the organic thin-film layer includes the aromatic amine derivate according to the exemplary embodiment as the dopant material, a content of the aromatic amine derivate is preferably in a range of 0.1 mass % to 20 mass %, more preferably of 1 mass % to 10 mass %.

### Substrate

The organic EL device according to the exemplary embodiment is formed on a light-transmissive substrate. The light-transmissive substrate, which supports the organic EL device, is preferably a smoothly-shaped substrate that transmits 50% or more of light in a visible region of 400 nm to 700 nm. Preferably, the substrate further has mechanical and thermal strength.

Specifically, a glass plate, a polymer plate, and the like are preferable.

For the glass plate, materials such as soda-lime glass, barium/strontium-containing glass, lead glass, aluminosilicate glass, borosilicate glass, barium borosilicate glass and quartz can be used.

For the polymer plate, materials such as polycarbonate, acryl, polyethylene terephthalate, polyether sulfide and polysulfone can be used. A polymer film can also be used as the substrate.

### Anode and Cathode

As a conductive material used in the anode of the organic EL device according to the exemplary embodiment, a conductive material having a work function of more than 4 eV is suitable. Examples of such a conductive material include: carbon, aluminium, vanadium, iron, cobalt, nickel, tungsten, silver, gold, platinum, palladium and alloys thereof; metal oxide such as tin oxide and indium oxide used in an ITO substrate and an NESA substrate; and an organic conductive resin such as polythiophene and polypyrrole. The anode can be prepared by forming a thin film of these conductive materials by vapor deposition, sputtering or the like.

When light from the emitting layer is to be extracted through the anode, the anode preferably transmits more than 10% of the light in the visible region. Sheet resistance of the anode is preferably several hundreds Ω/square or lower. Although depending on the material of the anode, the thickness of the anode is typically in a range of 10 nm to 1 μm, preferably in a range of 10 nm to 200 nm.

As a conductive substance used in the cathode of the organic EL device according to the exemplary embodiment, a conductive substance having a work function of less than 4 eV is suitable. Examples of such a conductive substance include magnesium, calcium, tin, lead, titanium, yttrium, lithium, ruthenium, manganese, aluminium, lithium fluoride and alloys thereof. However, the conductive substance is not limited thereto. Representative examples of the alloys are magnesium/silver, magnesium/indium and lithium/aluminium, but the alloys are not limited thereto. A ratio in each of the alloys is controlled by a temperature of a deposition source, atmosphere, vacuum and the like to be selected in an appropriate ratio. Like the anode, the cathode may be made by forming a thin film from the above materials through a method such as vapor deposition or sputtering. In addition, the light may be emitted through the cathode.

When light from the emitting layer is extracted through the cathode, the cathode preferably transmits more than 10% of the light in the visible region. Sheet resistance of the cathode is preferably several hundreds Ω per square or less. The thickness of the cathode is typically in a range of 10 nm to 1 μm, and preferably in a range of 50 nm to 200 nm, though it depends on the material of the cathode.

The anode and the cathode may be formed in two or more layers, if necessary.

In the organic EL device according to the exemplary embodiment, it is desirable that at least one surface of the organic EL device is sufficiently transparent in an emission wavelength region in order to efficiently emit light. It is also desirable that the substrate is transparent. A transparent electrode is set using the above conductive material by a method such as vapor deposition or sputtering so that a predetermined transparency of the electrode is ensured.

### Hole Injecting/Transporting Layer

The hole injecting/transporting layer is manufactured using the following hole injecting material and hole transporting material.

The hole injecting material is preferably a compound having hole transporting capability, exhibiting an excellent hole injecting effect from the anode and an excellent hole injecting effect to the emitting layer or the luminescent material, and exhibiting an excellent thin-film forming capability. Specific examples of the hole injecting material include: a phthalocyanine derivative; a naphthalocyanine derivative; a porphyrin derivative; benzidine-type triphenyl amine, diamine-type triphenyl amine, hexacyanohexaazatriphenylene and the like and derivatives thereof; and a polymer material such as polyvinyl carbazole, polysilane and a conductive polymer. However, the hole injecting material is not limited thereto.

Among the hole injecting materials usable in the organic EL device according to the exemplary embodiment, a further effective hole injecting material is a phthalocyanine derivative.

Examples of the phthalocyanine (Pc) derivative include a phthalocyanine derivative such as H₂Pc, CuPc, CoPc, NiPc, ZnPc, PdPc, FePc, MnPc, ClAlPc, ClGaPc, ClInPc, ClSnPc, Cl₂SiPc, (HO)AlPc, (HO)GaPc, VOPc, TiOPc, MoOPc, and GaPc-O—GaPc; and a naphthalocyanine derivative. However, the phthalocyanine (Pc) derivative is not limited thereto.

Moreover, carriers can be promoted by adding an electron accepting substance such as a TCNQ derivative to the hole injecting material.

In the organic EL device according to this exemplary embodiment, the hole transporting material is preferably an aromatic tertiary amine derivative.

Examples of the aromatic tertiary amine derivative include N,N′-diphenyl-N,N′-dinaphthyl-1,1′-biphenyl-4,4′-diamine, N,N,N′,N′-tetrabiphenyl-1,1′-biphenyl-4,4′-diamine, or an oligomer or a polymer thereof having such an aromatic tertiary amine skeleton. However, the aromatic tertiary amine derivative is not limited thereto.

### Electron Injecting/Transporting Layer

The electron injecting/transporting layer is manufactured using the following electron injecting material and the like.

The electron injecting material is preferably a compound having electron transporting capability, exhibiting an excellent electron injecting effect from the cathode and an excellent electron injecting effect to the emitting layer or the luminescent material, and exhibiting an excellent thin-film forming capability.

In the organic EL device according to the exemplary embodiment, more effective electron injecting materials are a metal complex compound and a nitrogen-containing heterocyclic derivative.

Examples of the metal complex compound include 8-hydroxyquinolinolato-lithium, bis(8-hydroxyquinolinolato)zinc, tris(8-hydroxyquinolinolato)aluminium, tris(8-hydroxyquinolinolato)gallium, bis(10-hydroxybenzo[h]quinolinolato)beryllium, and bis(10-hydroxybenzo[h]quinolinolato)zinc. However, the metal complex compound is not limited thereto.

Preferable examples of the nitrogen-containing heterocyclic derivative group are oxazole, thiazole, oxadiazole, thiadiazole, triazole, pyridine, pyrimidine, triazine, phenanthroline, benzimidazole, and imidazopyridine, among which a benzimidazole derivative, phenanthroline derivative and imidazopyridine derivative are preferable.

The organic EL device according to the exemplary embodiment is preferably an organic EL device including at least one of an electron-donating dopant and an organic metal complex in addition to the electron injecting material. More preferably, in order to easily accept electrons from the cathode, at least one of the electron-donating dopant and the organic metal complex is doped in the vicinity of an interface between the organic thin-film layer and the cathode.

With this arrangement, a luminance intensity of the organic EL device is improved and a lifetime thereof is prolonged.

The electron-donating dopant may be at least one selected from an alkali metal, an alkali metal compound, an alkaline-earth metal, an alkaline-earth metal compound, a rare-earth metal, a rare-earth metal compound and the like.

The organic metal complex may be at least one selected from an organic metal complex including an alkali metal, an organic metal complex including an alkaline-earth metal, an organic metal complex including a rare-earth metal and the like.

Examples of the alkali metal are lithium (Li) (work function: 2.93 eV), sodium (Na) (work function: 2.36 eV), potassium (K) (work function: 2.28 eV), rubidium (Rb) (work function: 2.16 eV) and cesium (Cs) (work function: 1.95 eV), which particularly preferably has a work function of 2.9 eV or less. Among the above, the reductive dopant is preferably K, Rb or Cs, more preferably Rb or Cs, the most preferably Cs.

Examples of the alkaline-earth metal are calcium (Ca) (work function: 2.9 eV), strontium (Sr) (work function: 2.0 to 2.5 eV), and barium (Ba) (work function: 2.52 eV), among which a substance having a work function of 2.9 eV or less is particularly preferable.

Examples of the rare-earth metal are scandium (Sc), yttrium (Y), cerium (Ce), terbium (Tb), and ytterbium (Yb), among which a substance having a work function of 2.9 eV or less is particularly preferable.

Since the above preferred metals have particularly high reducibility, addition of a relatively small amount of the metals to an electron injecting zone can enhance luminance intensity and lifetime of the organic EL device.

Examples of the alkali metal compound are an alkali oxide such as lithium oxide (Li₂O), cesium oxide (Cs₂O) and potassium oxide (K₂O), and an alkali halogenide such as sodium fluoride (NaF), cesium fluoride (CsF) and potassium fluoride (KF), among which lithium fluoride (LiF), lithium oxide (Li₂O) and sodium fluoride (NaF) are preferable.

Examples of the alkaline-earth metal compound are barium oxide (BaO), strontium oxide (SrO), calcium oxide (CaO) and a mixture thereof, i.e., barium strontium oxide (BaₓSr₁₋ₓO) (0<x<1), barium calcium oxide (BaₓCa₁₋ₓO) (0<x<1), among which BaO, SrO and CaO are preferable.

Examples of the rare earth metal compound are ytterbium fluoride (YbF₃), scandium fluoride (ScF₃), scandium oxide (ScO₃), yttrium oxide (Y₂O₃), cerium oxide (Ce₂O₃), gadolinium fluoride (GdF₃) and terbium fluoride (TbF₃), among which YbF₃, ScF₃, and TbF₃ are preferable.

The organic metal complex is not specifically limited as long as containing at least one metal ion of an alkali metal ion, an alkaline-earth metal ion and a rare earth metal ion. A ligand for each of the complexes is preferably quinolinol, benzoquinolinol, acridinol, phenanthridinol, hydroxyphenyl oxazole, hydroxyphenyl thiazole, hydroxydiaryl oxadiazole, hydroxydiaryl thiadiazole, hydroxyphenyl pyridine, hydroxyphenyl benzoimidazole, hydroxybenzo triazole, hydroxy fluborane, bipyridyl, phenanthroline, phthalocyanine, porphyrin, cyclopentadiene, β-diketones, azomethines, or a derivative thereof, but the ligand is not limited thereto.

One of the electron-donating dopant and the organic metal complex may be singularly used, or two or more of the above may be used together.

### Formation Method of Each Layer of Organic EL Device

Each layer of the organic EL device according to the exemplary embodiment can be formed by any method of dry film-forming such as vacuum deposition, sputtering, plasma or ion plating and wet film-forming such as spin coating, dipping, flow coating or ink-jet.

In wet film-forming, a material for forming each layer is dissolved or dispersed in an appropriate solvent such as ethanol, chloroform, tetrahydrofuran or dioxane to form a thin film, in which any one of the solvent is usable.

An organic-EL-device-material-containing solution that contains the aromatic amine derivative according to the exemplary embodiment (organic-EL-device material) and the solvent is usable as a solution appropriate for such wet film-forming.

An appropriate resin and an additive may be used in any organic thin-film layer for improvement in film formation, prevention of pin holes on a film, and the like.

### Film Thickness of Each Layer of Organic EL Device

A film thickness is not particularly limited, but needs to be set to be appropriate. When the film thickness is too large, a large voltage needs to be applied for outputting light at a certain level, thereby deteriorating efficiency. When the film thickness is too small, pin holes and the like are generated, whereby a sufficient luminescence intensity cannot be obtained even by applying an electric field. The film thickness is typically in a range of 5 nm to 10 μm, preferably in a range of 10 nm to 0.2 μm.

### Use of Organic EL Device

The organic EL device according to the exemplary embodiment is applicable to a flat light-emitting body such as a flat panel display, a light source of instruments or a backlight of a copy machine, a printer and a liquid crystal display, an illuminator, a display plate, a sigh lamp and the like. Moreover, the compound according to the exemplary embodiment is usable not only in the organic EL device but also in fields such as an electrophotographic photoreceptor, photoelectric conversion element, solar battery and image sensor.

### Modifications of Embodiment(s)

It should be noted that the invention is not limited to the above exemplary embodiment but may include any modification and improvement as long as such modification and improvement fall within the scope of the invention.

For instance, in the organic EL device of the invention, the emitting layer may contain at least one of the luminescent material, doping material, hole injecting material, hole transporting material, and electron injecting material in addition to at least one of the aromatic amine derivatives represented by formula (1). Moreover, in order to improve stability against the temperature, humidity, atmosphere and the like of the organic EL device obtained by the invention, a protection layer can be provided on a surface of the device, or the entire device can be protected by silicone oil, resins and the like.

An arrangement of the organic EL device is not particularly limited to the arrangement of the organic EL device 1 shown in FIG. 1. For instance, an electron blocking layer may be provided to the emitting layer adjacent to the anode while a hole blocking layer may be provided to the emitting layer adjacent to the cathode.

The emitting layer is not limited to a single layer, but may be provided by laminating a plurality of emitting layers. When the organic EL device has the plurality of emitting layers, at least one of the emitting layers preferably contains the aromatic amine derivative of the invention. In this instance, the other emitting layer(s) may be a fluorescent-emitting layer including a fluorescent material, or a phosphorescent-emitting layer including a phosphorescent material.

Moreover, when the organic EL device includes the plurality of emitting layers, the plurality of emitting layers may be adjacent to each other, or may be laminated on each other via a layer other than the emitting layers (e.g., a charge generating layer).

### EXAMPLES

Next, the invention will be described in further detail by exemplifying Example(s) and Comparative(s). However, the invention is not limited by the description of Example(s).

### Synthesis of Compounds

### Synthesis Example 1

### Synthesis of Compound 1

A synthesis scheme of a compound 1 is shown below.

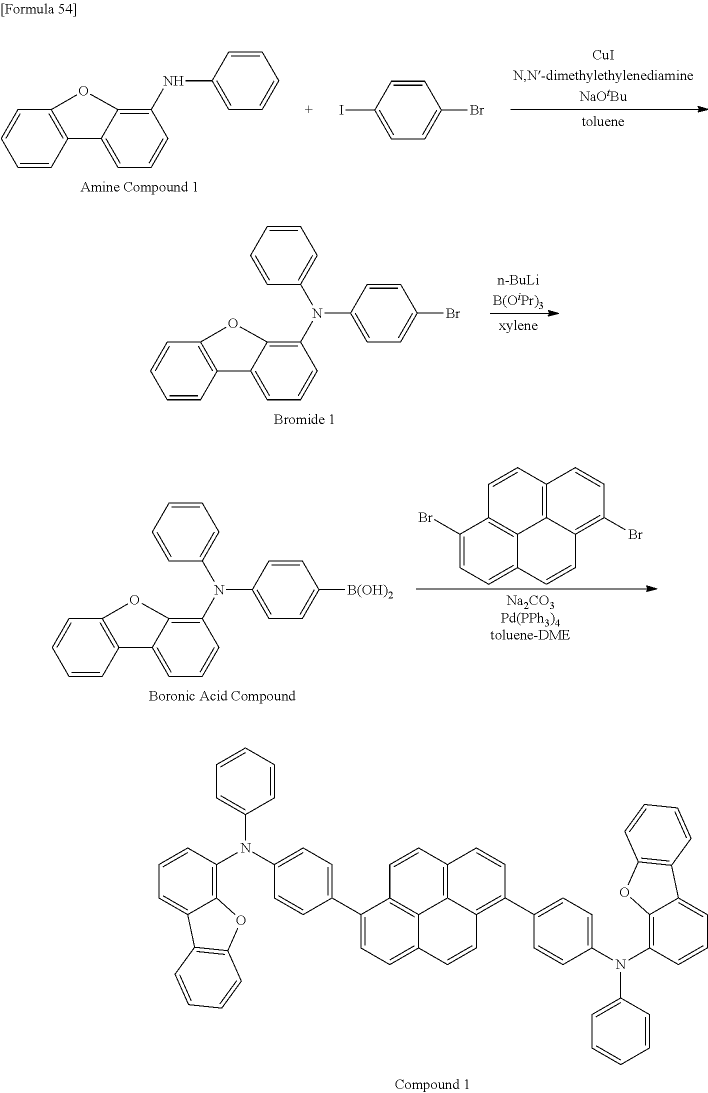 [SMILES: c1ccc(Nc2cccc3c2oc2ccccc23)cc1 ; Brc1ccc(I)cc1 ; Brc1ccc(N(c2ccccc2)c2cccc3c2oc2ccccc23)cc1 ; OB(O)c1ccc(N(c2ccccc2)c2cccc3c2oc2ccccc23)cc1 ; Brc1ccc2ccc3c(Br)ccc4ccc1c2c43 ; c1ccc(N(c2ccc(-c3ccc4ccc5c(-c6ccc(N(c7ccccc7)c7cccc8c7oc7ccccc78)cc6)ccc6ccc3c4c65)cc2)c2cccc3c2oc2ccccc23)cc1]

In an argon gas stream, into a 300-mL three-necked flask, an amine compound 1 (2.6 g, 10 mmol), 4-iodobromobiphenyl (3.1 g, 11 mmol), copper iodide (I) (0.4 g), N,N′-dimethylethylenediamine (0.4 g), t-butoxysodium (1.7 g), and dehydrated toluene (100 mL) were put and reacted at 110 degrees C. for eight hours.

After the reaction, the reaction solution was extracted with toluene and dried with magnesium sulfate.

After being dried, the reactant was condensed under reduced pressure. The obtained crude product was purified by using a column. After the purification, the obtained solid was recrystallized with toluene and filtrated. After the filtration, the obtained product was dried to obtain a bromide 1 of 2.5 g.

In an argon stream, the bromide 1 (2.5 g (6 mmol)) and dehydrated xylene (100 mL) were added to a 300-mL three-necked flask and cooled to −30 degrees C. After being cooled, the mixture was added with 4.5 mL of n-butyllithium (1.6 M hexane solution) and reacted for one hour. After the reaction, the reaction mixture was cooled to −70 degrees C. and subsequently was added with 1.6 mL of triisopropyl borate The reaction mixture was gradually heated up and stirred at room temperature for 1 hour. After being stirred, the reaction mixture was further added with 20 mL of a 10% hydrochloric acid solution and stirred. After being stirred, the reaction mixture was extracted with ethyl acetate and water. An organic phase was washed with water. After being washed, the organic phase was dried with anhydrous sodium sulfate to distill away a solvent. The reactant was washed with hexane to obtain 1.5 g of a boronic acid compound 1.

In an argon gas stream, to a 300-mL three-necked flask with a condenser, 1,6-dibromopyrene (360 mg, (1 mmol)), the boronic acid compound 1 (950 mg, (2.5 mmol)), tetrakis(triphenylphosphine)palladium (50 mg), sodium carbonate (200 mg), water (10 mL), toluene (100 mL) and DME (50 mL) were added and heated to reflux for eight hours. After the reaction, the deposited crystals were filtrated and washed with toluene (50 mL) and methanol (100 mL). The obtained crude crystals were recrystallized with toluene to obtain 500 mg of the compound 1 of the aromatic amine derivative shown in Table 1.

The obtained compound 1 was analyzed by FD-MS (Field Desorption Mass Spectrometry). The details are shown below.

FDMS, calcd for C₆₄H₄₀N₂O₂=868, found m/z=868(M+)

### Manufacturing of Organic EL Device

### Example 1

A 120 nm-thick transparent electrode formed of indium tin oxide was formed on a glass substrate having a size of 25 mm×75 mm×1.1 mm. The transparent electrode served as the anode.

Subsequently, the glass substrate was irradiated and washed with ultraviolet ray and ozone, and then was set in vacuum deposition equipment.

Firstly, N′,N″-bis[4-(diphenylamino)phenyl]-N′,N″-diphenylbiphenyl-4,4′-diamine was deposited to form a 60-nm thick hole injecting layer.

Next, N,N,N′,N′-tetrakis(4-biphenyl)-4,4′-benzidine was deposited on the hole injecting layer to form a 20-nm thick hole transporting layer.

Next, the anthracene derivative EM2 (the host material) and the compound 1 (the dopant material) were co-deposited on the hole transporting layer at a mass ratio of 40:2 to form a 40-nm thick emitting layer.

Next, tris(8-hydroxyquinolinate)aluminium was deposited on the emitting layer to form a 20-nm thick electron injecting layer.

Next, lithium fluoride was deposited on the electron injecting layer to form a 1-nm thick film.

Next, aluminium was deposited on the lithium-fluoride film to form a 150-nm thick film. The aluminum film and the lithium-fluoride film served as the cathode.

Thus, the organic EL device of Example 1 was prepared.

When the organic EL device of Example 1 was driven at a current density of 10 mA/cm², blue emission was observed. Thus, it was verified that the compound 1 was useful as the organic-EL-device material.

### Example 2

An organic EL device of Example 2 was prepared in the same manner as in the organic EL device of Example 1 except that EM2 (the host material) of the organic EL device of Example 1 was replaced by EM367.

The organic EL device of Example 2 was driven at a current density of 10 mA/cm² in the same manner as the organic EL device of Example 1. As a result, in the organic EL devices of Example 2, blue emission was observed. Thus, it was verified that the compound 1 was useful as the organic-EL-device material.

The aromatic amine derivative of the invention is exemplified by one exhibiting blue emission in Examples, but not limited thereto. An aromatic amine derivative in which an aryl group and the like are directly bonded to a pyrene ring can emit green light. For instance, such an aromatic amine derivative is exemplified by the above compounds D204 to D211.

1. An aromatic amine derivative represented by a formula (1) below, 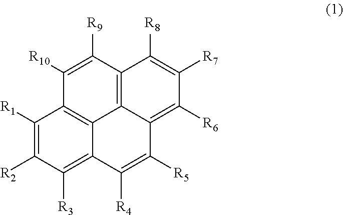
where: R₂, R₃, R₄, R₅, R₇, R₈, R₉ and R₁₀ each independently represent a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms,
R₁ and R₆ are represented by a formula (2) below, 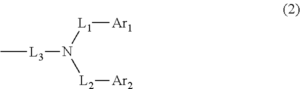
where: L₁ and L₂ each independently represent a single bond, a divalent residue of a substituted or unsubstituted aryl group having 6 to 30 ring carbon atoms, or a divalent residue of a substituted or unsubstituted heterocyclic group having 5 to 30 ring atoms,
L₃ represents a divalent residue of a substituted or unsubstituted aryl group having 6 to 30 ring carbon atoms, or a divalent residue of a substituted or unsubstituted heterocyclic group having 5 to 30 ring atoms,
Ar₁ is a monovalent substituent having a partial structure represented by a formula (3) below, 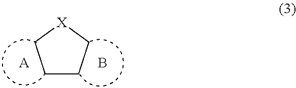
where: X represents an oxygen atom or a sulfur atom,
A and B represent a six-membered ring, the six-membered ring represented by A and B is optionally fused with another ring, and
Ar₂ is a substituted or unsubstituted aryl group having 6 to 30 ring carbon atoms, a substituted or unsubstituted heterocyclic group having 5 to 30 ring atoms, or a monovalent substituent having a partial structure represented by the formula (3).

2. The aromatic amine derivative according to claim 1, wherein
the monovalent substituent having the partial structure represented by the formula (3) is a monovalent residue represented by a formula (4) below, 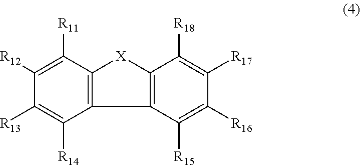
where: X represents an oxygen atom or a sulfur atom,
R₁₁ to R₁₈ each independently represent a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms, with the proviso that; in the formula (2), when Ar₁ is a monovalent residue of the formula (4), one of R₁₁ to R₁₈ is a single bond to be bonded to L₁; and when Ar₂ is a monovalent residue of the formula (4), one of R₁₁ to R₁₈ is a single bond to be bonded to L₂, and
at least one combination of R₁₁ and R₁₂, R₁₂ and R₁₃, R₁₃ and R₁₄, R₁₅ and R₁₆, R₁₆ and R₁₇, and R₁₇ and R₁₈ optionally form a saturated or unsaturated ring.

3. The aromatic amine derivative according to claim 1, wherein
the monovalent substituent having the partial structure represented by the formula (3) is any one of monovalent residues represented by formulae (5) to (10) below, 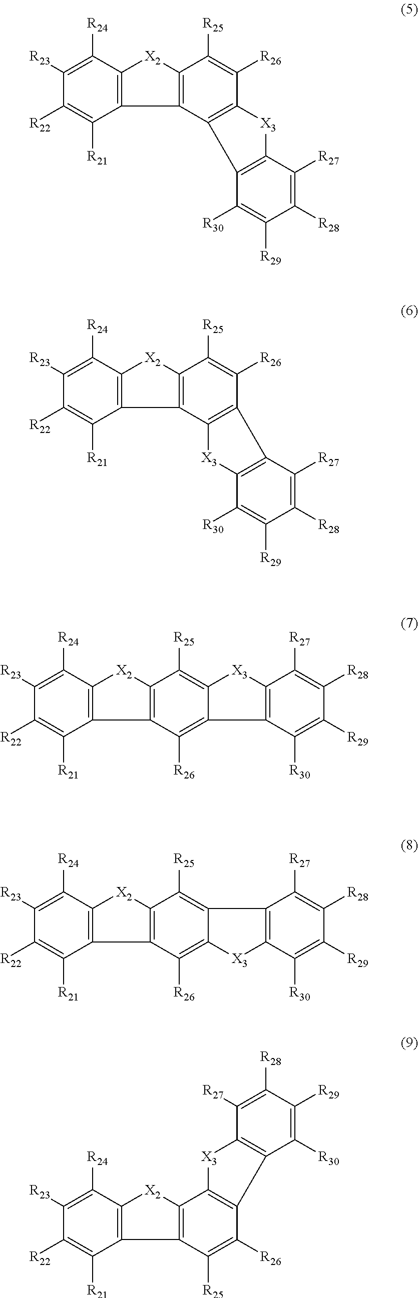 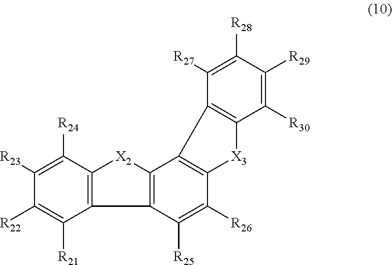
where: X₂ represents an oxygen atom or a sulfur atom,
X₃ represents an oxygen atom, a sulfur atom, NR₃₁ or CR₃₂R₃₃,
R₂₁ to R₃₀ each independently represent a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms, with the proviso that; in the formula (2), when Ar₁ is one of the monovalent residues of the formulae (5) to (10), one of R₂₁ to R₃₀ is a single bond to be bonded to L₁; and when Ar₂ is one of the monovalent residues of the formulae (5) to (10), one of R₂₁ to R₃₀ is a single bond to be bonded to L₂,
R₃₁, R₃₂ and R₃₃ each independently represent a substituted or unsubstituted aryl group having 6 to 30 ring carbon atoms, a substituted or unsubstituted heterocyclic group having 5 to 30 ring atoms, or a substituted or unsubstituted alkyl group having 1 to 30 carbon atoms, and
at least one combination of R₂₁ and R₂₂, R₂₂ and R₂₃, R₂₃ and R₂₄, R₂₅ and R₂₆, R₂₇ and R₂₈, R₂₈ and R₂₉, and R₂₉ and R₃₀ optionally forms a saturated or unsaturated ring, with the proviso that, in the formulae (7) and (8), R₂₅ and R₂₆ do not form a ring.

4. An organic electroluminescence device comprising:
a cathode;
an anode; and
an organic compound layer between the cathode and the anode, wherein
the organic compound layer comprises the aromatic amine derivative according to claim 1.

5. The organic electroluminescence device according to claim 4, wherein
the organic compound layer comprises a plurality of organic thin-film layers comprising an emitting layer, and
at least one of the plurality of organic thin-film layers comprises the aromatic amine derivative.

6. The organic electroluminescence device according to claim 5, wherein
at least one of the plurality of organic thin-film layers comprises the aromatic amine derivative and an anthracene derivative represented by a formula (20) below, 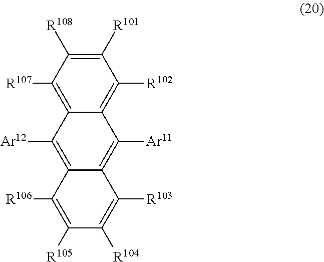
where: Ar¹¹ and Ar¹² each independently represent a substituted or unsubstituted monocyclic group having 5 to 30 ring atoms, a substituted or unsubstituted fused ring group having 10 to 30 ring atoms, or a group provided by combining the monocyclic group and the fused ring group,
R¹⁰¹ to R¹⁰⁸ each independently represent a hydrogen atom, a halogen atom, a cyano group, a substituted or unsubstituted monocyclic group having 5 to 30 ring atoms, a substituted or unsubstituted fused ring group having 10 to 30 ring atoms, a group provided by combining the monocyclic group and the fused ring group, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aralkyl group having 7 to 30 carbon atoms, a substituted or unsubstituted aryloxy group having 6 to 30 ring carbon atoms, or a substituted or unsubstituted silyl group.

7. The organic electroluminescence device according to claim 6, wherein
Ar¹¹ and Ar¹² in the formula (20) are each independently a substituted or unsubstituted fused ring group having 10 to 30 ring atoms.

8. The organic electroluminescence device according to claim 6, wherein
in the formula (20), one of Ar¹¹ and Ar¹² is a substituted or unsubstituted monocyclic group having 5 to 30 ring atoms, and the other of Ar¹¹ and Ar¹² is a substituted or unsubstituted fused ring group having 10 to 30 ring atoms.

9. The organic electroluminescence device according to claim 8, wherein
in the formula (20), Ar¹² is selected from a naphthyl group, phenanthryl group, benzoanthryl group and dibenzofuranyl group, and Ar¹¹ is an unsubstituted phenyl group or a phenyl group substituted by at least one of the monocyclic group and the fused ring group.

10. The organic electroluminescence device according to claim 8, wherein
in the formula (20), Ar¹² is a substituted or unsubstituted fused ring group having 10 to 30 ring atoms and Ar¹¹ is an unsubstituted phenyl group.

11. The organic electroluminescence device according to claim 6, wherein
Ar¹¹ and Ar¹² in the formula (20) are each independently a substituted or unsubstituted monocyclic group having 5 to 30 ring atoms.

12. The organic electroluminescence device according to claim 11, wherein
Ar¹¹ and Ar¹² in the formula (20) are each independently a substituted or unsubstituted phenyl group.

13. The organic electroluminescence device according to claim 12, wherein
in the formula (20), Ar¹¹ is an unsubstituted phenyl group and Ar¹² is a phenyl group having at least one of the monocyclic group and the fused ring group as a substituent.

14. The organic electroluminescence device according to claim 12, wherein
in the formula (20), Ar¹¹ and Ar¹² are each independently a phenyl group having at least one of the monocyclic group and the fused ring group as a substituent.

15. An organic electroluminescence device comprising:
a cathode;
an anode; and
an organic compound layer between the cathode and the anode, wherein
the organic compound layer comprises the aromatic amine derivative according to claim 2.

16. An organic electroluminescence device comprising:
a cathode;
an anode; and
an organic compound layer between the cathode and the anode, wherein
the organic compound layer comprises the aromatic amine derivative according to claim 3.
